(19) United States
(12) Patent Application Publication
(10) Pub. No.: US 2026/0231529 A1
(43) Pub. Date: Aug. 6, 2026

(54) SEMICONDUCTOR DEVICE AND METHOD FOR MANUFACTURING THE SAME

(71) Applicant: SEMICONDUCTOR ENERGY LABORATORY CO., LTD., Atsugi-shi, Kanagawa-ken (JP)

(72) Inventors: Shunpei YAMAZAKI, Setagaya, Tokyo (JP); Tsutomu MURAKAWA, Isehara, Kanagawa (JP); Motomu KURATA, Isehara, Kanagawa (JP); Hiromi SAWAI, Kawasaki, Kanagawa (JP)

(21) Appl. No.: 19/152,053

(22) PCT Filed: Feb. 5, 2024
(86) PCT No.: PCT/IB2024/051011

§ 371 Date: Jul. 30, 2025

(30) Foreign Application Priority Data
Feb. 10, 2023 (JP) 2023-019371
Feb. 10, 2023 (JP) 2023-019374

(51) Int. Cl. H10D 86/40; H10K 59/12; H10K 59/121

(52) U.S. Cl. CPC H10D 86/423; H10K 59/1201; H10K 59/1213

(57) ABSTRACT

A semiconductor device that occupies a small area is provided. In the semiconductor device, a transistor is provided to include a region positioned in an opening portion of a spacer. A source electrode and a drain electrode are provided to face each other with the opening portion therebetween in a plan view. A semiconductor layer is provided along a side surface and a lower surface of the opening portion. An end portion of a lower surface of the semiconductor layer outside the opening portion includes a region that is aligned or substantially aligned with an end portion of an upper surface of the source electrode and a region that is aligned or substantially aligned with an end portion of an upper surface of the drain electrode. Over the semiconductor layer, a gate insulating layer and a gate electrode are provided in this order to include a region positioned in the opening portion.

### TECHNICAL FIELD

One embodiment of the present invention relates to a semiconductor device and a manufacturing method thereof. One embodiment of the present invention relates to a transistor and a manufacturing method thereof. One embodiment of the present invention relates to a display device including a semiconductor device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), a method for driving any of them, and a method for manufacturing any of them.

In this specification and the like, a semiconductor device refers to a device that utilizes semiconductor characteristics, and means a circuit including a semiconductor element (a transistor, a diode, a photodiode, and the like), a device including the circuit, and the like. The semiconductor device also means any device that can function by utilizing semiconductor characteristics. For example, an integrated circuit, a chip including an integrated circuit, and an electronic component including a chip in a package are examples of the semiconductor device. Moreover, a memory device, a display device, a light-emitting apparatus, a lighting device, and an electronic device themselves are semiconductor devices and each of them includes a semiconductor device in some cases.

### BACKGROUND ART

Semiconductor devices including transistors are applied to a wide range of electronic devices. In addition, uses for a display device are diversified in recent years, and for example, the display device is used for a portable information terminal, a television device (also referred to as a television receiver), digital signage, a PID (Public Information Display), and the like. Examples of the display device include a display device including an organic EL (Electro Luminescence) element or a light-emitting diode (LED), a display device including a liquid crystal element, and electronic paper performing display by an electrophoretic method.

In a display device, for example, when the area occupied by transistors is reduced, the pixel size can be reduced and resolution can be increased. Furthermore, when the area occupied by transistors is reduced, the aperture ratio can be increased. Thus, minute transistors have been required.

As devices requiring high-resolution display devices, for example, devices for virtual reality (VR), augmented reality (AR), substitutional reality (SR), or mixed reality (MR) have been actively developed.

Patent Document 1 discloses a high-resolution display device using an organic EL element.

### REFERENCE

### Patent Document

[Patent Document 1] PCT International Publication No. 2016/038508

### SUMMARY OF THE INVENTION

### Problems to be Solved by the Invention

When a transistor is miniaturized to have a short channel length, the saturation characteristics of the transistor becomes poor. For example, when a driving transistor that controls current flowing through a light-emitting element (also referred to as a light-emitting device) in a pixel included in a display device is miniaturized to have a short channel length and accordingly has poor saturation characteristics, the current flowing through the light-emitting element becomes unstable and the emission luminance of the light-emitting element becomes unstable in some cases. For example, a time-related variation might be caused in the current flowing through the light-emitting element, leading to a time-related variation in emission luminance of the light-emitting element even in still image display.

In this specification and the like, a transistor having a small change in current (i.e., a gentle slope) in a saturation region of the Id-Vd characteristics is sometimes regarded as having “good saturation characteristics”.

An object of one embodiment of the present invention is to provide a transistor having a minute size. Another object is to provide a transistor having a long channel length. Another object is to provide a transistor having a long channel length and a transistor having a short channel length. Another object is to provide a transistor having good saturation characteristics. Another object is to provide a transistor having favorable electrical characteristics. Another object is to provide a small semiconductor device or display device. Another object is to provide a semiconductor device or a display device having low wiring resistance. Another object is to provide a semiconductor device or a display device that is driven at high speed. Another object is to provide an inexpensive semiconductor device or display device. Another object is to provide a semiconductor device or a display device having low power consumption. Another object is to provide a high-performance semiconductor device or display device. Another object is to provide a highly reliable transistor, semiconductor device, or display device. Another object is to provide a high-resolution display device. Another object is to provide a method for manufacturing a semiconductor device or a method for manufacturing a display device with high productivity. Another object is to provide a method for manufacturing a semiconductor device or a method for manufacturing a display device at a low manufacturing cost. Another object is to provide a novel transistor, semiconductor device, or display device and a manufacturing method thereof.

Note that the description of these objects does not preclude the existence of other objects. One embodiment of the present invention does not necessarily achieve all of these objects. Other objects can be derived from the description of the specification, the drawings, and the claims.

### Means for Solving the Problems

One embodiment of the present invention is a semiconductor device including a first insulating layer and a second insulating layer and a transistor over the first insulating layer. The transistor includes a first conductive layer, a second conductive layer, a third conductive layer, a semiconductor layer, and a third insulating layer. The second insulating layer includes a first opening portion reaching the first insulating layer. The first conductive layer and the second conductive layer are provided over the second insulating layer to face each other with the first opening portion therebetween in a plan view. The semiconductor layer is provided to include a region positioned in the first opening portion. An end portion of a lower surface of the semiconductor layer outside the first opening portion includes a region that is aligned or substantially aligned with an end portion of an upper surface of the first conductive layer and a region that is aligned or substantially aligned with an end portion of an upper surface of the second conductive layer. The third insulating layer is provided over the semiconductor layer to include a region positioned in the first opening portion. The third conductive layer is provided over the third insulating layer to include a region positioned in the first opening portion.

Alternatively, in the above embodiment, the semiconductor layer and the third insulating layer may include a second opening portion reaching the second conductive layer, and a plug may be provided to be embedded in the second opening portion.

Another embodiment of the present invention is a semiconductor device including a first insulating layer and a second insulating layer, a first transistor, and a second transistor over the first insulating layer. The first transistor includes a first conductive layer, a second conductive layer, a third conductive layer, a first semiconductor layer, and a third insulating layer. The second transistor includes a fourth conductive layer, a fifth conductive layer, a sixth conductive layer, a second semiconductor layer, and the third insulating layer. The fourth conductive layer is provided over the first insulating layer. The second insulating layer is provided over the fourth conductive layer. The second insulating layer includes a first opening portion reaching the first insulating layer and a second opening portion reaching the fourth conductive layer. The first conductive layer and the second conductive layer are provided over the second insulating layer to face each other with the first opening portion therebetween in a plan view. The fifth conductive layer is provided over the second insulating layer and includes a third opening portion including a region overlapping with the second opening portion. The first semiconductor layer is provided to include a region positioned in the first opening portion. An end portion of a lower surface of the first semiconductor layer outside the first opening portion includes a region that is aligned or substantially aligned with an end portion of an upper surface of the first conductive layer and a region that is aligned or substantially aligned with an end portion of an upper surface of the second conductive layer. The second semiconductor layer is provided to include a region positioned in the second opening portion and a region positioned in the third opening portion and to include a region in contact with the fourth conductive layer. An end portion of a lower surface of the second semiconductor layer outside the third opening portion includes a region that is aligned or substantially aligned with an end portion of an upper surface of the fifth conductive layer. The third insulating layer is provided over the first semiconductor layer and the second semiconductor layer to include a region positioned in the first opening portion, a region positioned in the second opening portion, and a region positioned in the third opening portion. The third conductive layer is provided over the third insulating layer to include a region positioned in the first opening portion. The sixth conductive layer is provided over the third insulating layer to include a region positioned in the second opening portion and a region positioned in the third opening portion.

Alternatively, in the above embodiment, the first semiconductor layer and the third insulating layer may include a fourth opening portion reaching the second conductive layer, and a plug may be provided to be embedded in the fourth opening portion.

Alternatively, in the above embodiment, the shortest value of a length of the first transistor in a channel length direction in a region of the first semiconductor layer that overlaps with the first opening portion in the plan view may be greater than or equal to a thickness of the second insulating layer.

Alternatively, in the above embodiment, an end portion of an upper surface of the second insulating layer in the first opening portion includes a region that is aligned or substantially aligned with an end portion of a lower surface of the first conductive layer that faces the first opening portion in the plan view and a region that is aligned or substantially aligned with an end portion of a lower surface of the second conductive layer that faces the first opening portion in the plan view.

In the above embodiment, the first semiconductor layer and the second semiconductor layer may each include a metal oxide. The metal oxide may include indium, an element M, and zinc. The element M may be one or more kinds selected from aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony.

Another embodiment of the present invention is a method for manufacturing a semiconductor device, including the following steps: forming a first insulating layer; forming a first conductive layer over the first insulating layer; forming a second insulating layer over the first insulating layer and the first conductive layer; forming a conductive film over the second insulating layer; forming, in the conductive film, a first opening portion and a second opening portion including a region overlapping with the first conductive layer; forming, in the second insulating layer, a third opening portion that includes a region overlapping with the first opening portion and reaches the first insulating layer and a fourth opening portion that includes a region overlapping with the second opening portion and reaches the first conductive layer; forming a semiconductor film covering the first to fourth opening portions; processing the semiconductor film, thereby forming a first semiconductor layer including a region in contact with the conductive film and a region positioned in the third opening portion and a second semiconductor layer including a region in contact with the first conductive layer, a region in contact with the conductive film, a region positioned in the second opening portion, and a region positioned in the fourth opening portion; processing the conductive film after the processing of the semiconductor film, thereby forming a second conductive layer and a third conductive layer facing each other with the third opening portion therebetween in a plan view and a fourth conductive layer including the second opening portion; forming a third insulating layer over the first semiconductor layer, the second semiconductor layer, and the second insulating layer to include regions positioned in the second to fourth opening portions; and forming, over the third insulating layer, a fifth conductive layer including a region positioned in the third opening portion and a sixth conductive layer including a region positioned in the second opening portion and a region positioned in the fourth opening portion.

Alternatively, in the above embodiment, a resist mask may be formed after the semiconductor film is formed. The semiconductor film and the conductive film may be processed after the resist mask is formed. The resist mask may be removed after the conductive film is processed.

Alternatively, in the above embodiment, a seventh conductive layer may be formed over the first insulating layer in the same step as formation of the first conductive layer. An eighth conductive layer over the second insulating layer and a third semiconductor layer over the eighth conductive layer may be formed by processing the semiconductor film and the conductive film. A ninth conductive layer may be formed over the third insulating layer in the same step as formation of the fifth conductive layer and the sixth conductive layer. A fourth insulating layer may be formed over the fifth to ninth conductive layers after the fifth conductive layer, the sixth conductive layer, and the ninth conductive layer are formed. Forming a fifth opening portion reaching the seventh conductive layer in the second to fourth insulating layers, forming a sixth opening portion reaching the eighth conductive layer in the fourth insulating layer, the third insulating layer, and the third semiconductor layer, and forming a seventh opening portion in the fourth insulating layer may be performed in parallel. A first plug embedded in the fifth opening portion, a second plug embedded in the sixth opening portion, and a third plug embedded in the seventh opening portion may be formed.

### Effect of the Invention

One embodiment of the present invention can provide a transistor having a minute size. Alternatively, a transistor having a long channel length can be provided. Alternatively, a transistor having a long channel length and a transistor having a short channel length can be provided. Alternatively, a transistor having good saturation characteristics can be provided. Alternatively, a transistor having favorable electrical characteristics can be provided. Alternatively, a small semiconductor device or display device can be provided. Alternatively, a semiconductor device or a display device having low wiring resistance can be provided. Alternatively, a semiconductor device or a display device that is driven at high speed can be provided. Alternatively, an inexpensive semiconductor device or display device can be provided. Alternatively, a semiconductor device or a display device or a display device having low power consumption can be provided. Alternatively, a high-performance semiconductor device or display device can be provided. Alternatively, a highly reliable transistor, semiconductor device, or display device can be provided. Alternatively, a high-resolution display device can be provided. Alternatively, a method for manufacturing a semiconductor device or a method for manufacturing a display device with high productivity can be provided. Alternatively, a method for manufacturing a semiconductor device or a method for manufacturing a display device at a low manufacturing cost can be provided. Alternatively, a novel transistor, semiconductor device, or display device and a manufacturing method thereof can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A and FIG. 1B are plan views illustrating a structure example of a semiconductor device.

FIG. 2A and FIG. 2B are plan views illustrating a structure example of a semiconductor device.

FIG. 3A to FIG. 3F are cross-sectional views illustrating a structure example of a semiconductor device.

FIG. 4A is a plan view illustrating a structure example of a semiconductor device. FIG. 4B and FIG. 4C are cross-sectional views illustrating the structure example of a semiconductor device.

FIG. 5A is a plan view illustrating a structure example of a semiconductor device. FIG. 5B is a cross-sectional view illustrating the structure example of a semiconductor device.

FIG. 6A and FIG. 6B are plan views illustrating a structure example of a semiconductor device.

FIG. 7A and FIG. 7B are plan views illustrating a structure example of a semiconductor device.

FIG. 8A to FIG. 8C are cross-sectional views illustrating a structure example of a semiconductor device.

FIG. 9A is a plan view illustrating a structure example of a semiconductor device. FIG. 9B and FIG. 9C are cross-sectional views illustrating the structure example of a semiconductor device.

FIG. 10A is a plan view illustrating a structure example of a semiconductor device. FIG. 10B is a cross-sectional view illustrating the structure example of a semiconductor device.

FIG. 11A to FIG. 11C are cross-sectional views illustrating structure examples of a semiconductor device.

FIG. 12A to FIG. 12F are cross-sectional views illustrating a structure example of a semiconductor device.

FIG. 13A is a plan view illustrating a structure example of a semiconductor device. FIG. 13B and FIG. 13C are cross-sectional views illustrating the structure example of a semiconductor device.

FIG. 14 is a plan view illustrating a structure example of a semiconductor device.

FIG. 15A to FIG. 15C are cross-sectional views illustrating a structure example of a semiconductor device.

FIG. 16A to FIG. 16C are cross-sectional views illustrating a structure example of a semiconductor device.

FIG. 17A is a plan view illustrating a structure example of a semiconductor device. FIG. 17B and FIG. 17C are cross-sectional views illustrating the structure example of a semiconductor device.

FIG. 18 is a plan view illustrating a structure example of a semiconductor device.

FIG. 19A to FIG. 19C are cross-sectional views illustrating a structure example of a semiconductor device.

FIG. 20A is a block diagram illustrating a structure example of a display device. FIG. 20B is a plan view illustrating a structure example of a pixel. FIG. 20C and FIG. 20D are circuit diagrams illustrating structure examples of a pixel.

FIG. 21A and FIG. 21B are plan views illustrating a structure example of a semiconductor device.

FIG. 22 is a cross-sectional view illustrating a structure example of a semiconductor device.

FIG. 23A and FIG. 23B are plan views illustrating a structure example of a semiconductor device.

FIG. 24 is a cross-sectional view illustrating a structure example of a semiconductor device.

FIG. 25A is a block diagram illustrating a structure example of a display device. FIG. 25B is a circuit diagram illustrating a structure example of a pixel.

FIG. 26 is a cross-sectional view illustrating a structure example of a semiconductor device.

FIG. 27A and FIG. 27B are plan views each illustrating a structure example of a semiconductor device.

FIG. 28A and FIG. 28B are plan views illustrating a structure example of a semiconductor device.

FIG. 28C is a cross-sectional view illustrating the structure example of a semiconductor device.

FIG. 29A is a plan view illustrating a structure example of a semiconductor device. FIG. 29B is a cross-sectional view illustrating the structure example of a semiconductor device.

FIG. 30 is a cross-sectional view illustrating a structure example of a semiconductor device.

FIG. 31A and FIG. 31B are plan views each illustrating a structure example of a semiconductor device.

FIG. 32A and FIG. 32B are plan views illustrating a structure example of a semiconductor device.

FIG. 32C is a cross-sectional view illustrating the structure example of a semiconductor device.

FIG. 33A is a plan view illustrating a structure example of a semiconductor device. FIG. 33B is a cross-sectional view illustrating the structure example of a semiconductor device.

FIG. 34A and FIG. 34B are cross-sectional views illustrating structure examples of a semiconductor device.

FIG. 35A and FIG. 35B are cross-sectional views illustrating structure examples of a semiconductor device.

FIG. 36A to FIG. 36C are cross-sectional views illustrating structure examples of a semiconductor device.

FIG. 37A to FIG. 37C are cross-sectional views illustrating a structure example of a semiconductor device.

FIG. 38A to FIG. 38C are cross-sectional views illustrating an example of a method for manufacturing a semiconductor device.

FIG. 39A and FIG. 39B are cross-sectional views illustrating an example of the method for manufacturing a semiconductor device.

FIG. 40A and FIG. 40B are cross-sectional views illustrating an example of the method for manufacturing a semiconductor device.

FIG. 41A and FIG. 41B are cross-sectional views illustrating an example of the method for manufacturing a semiconductor device.

FIG. 42A and FIG. 42B are cross-sectional views illustrating an example of the method for manufacturing a semiconductor device.

FIG. 43A to FIG. 43C are cross-sectional views illustrating an example of a method for manufacturing a semiconductor device.

FIG. 44A and FIG. 44B are cross-sectional views illustrating an example of the method for manufacturing a semiconductor device.

FIG. 45A and FIG. 45B are cross-sectional views illustrating an example of a method for manufacturing a semiconductor device.

FIG. 46A and FIG. 46B are cross-sectional views illustrating an example of a method for manufacturing a semiconductor device.

FIG. 47A and FIG. 47B are cross-sectional views illustrating an example of a method for manufacturing a semiconductor device.

FIG. 48A and FIG. 48B are perspective views illustrating a structure example of a display device.

FIG. 49 is a cross-sectional view illustrating a structure example of a display device.

FIG. 50 is a cross-sectional view illustrating a structure example of a display device.

FIG. 51 is a cross-sectional view illustrating a structure example of a display device.

FIG. 52 is a cross-sectional view illustrating a structure example of a display device.

FIG. 53 is a cross-sectional view illustrating a structure example of a display device.

FIG. 54 is a cross-sectional view illustrating a structure example of a display device.

FIG. 55A is a plan view illustrating a structure example of a display device. FIG. 55B and FIG. 55C are cross-sectional views illustrating the structure example of a display device.

FIG. 56A and FIG. 56B are cross-sectional views illustrating structure examples of a display device.

FIG. 57 is a cross-sectional view illustrating a structure example of a display device.

FIG. 58 is a cross-sectional view illustrating a structure example of a display device.

FIG. 59A to FIG. 59D are diagrams illustrating structure examples of electronic devices.

FIG. 60A to FIG. 60F are diagrams illustrating structure examples of electronic devices.

FIG. 61A to FIG. 61G are diagrams illustrating structure examples of electronic devices.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, or the like of each component illustrated in drawings does not represent the actual position, size, range, or the like in some cases for easy understanding. Therefore, the disclosed invention is not necessarily limited to the position, size, range, and the like disclosed in drawings.

Note that in this specification and the like, ordinal numbers such as “first” and “second” are used for convenience and do not limit the number of components or the order of components (e.g., the order of steps or the stacking order of layers). In some cases, an ordinal number used for a component in a certain part in this specification is not the same as an ordinal number used for the component in another part in this specification or claims.

In this specification and the like, terms for describing positioning, such as “over”, “under”, “above”, and “below”, are sometimes used for convenience to describe the positional relationship between components with reference to drawings. The positional relationship between components is changed as appropriate in accordance with the direction in which the components are described. Thus, the positional relationship is not limited to the terms described in this specification and the like, and can be described with another term as appropriate depending on the situation. For example, the expression “an insulating layer positioned over a conductive layer” can be replaced with the expression “an insulating layer positioned under a conductive layer” when the direction of a drawing illustrating these components is rotated by 180°.

Note that the term “layer” and the term “film” can sometimes be used interchangeably depending on the case or the circumstances. For example, the term “conductive layer” can be changed into the term “conductive film” in some cases. For another example, the term “insulating layer” can be changed into the term “insulating film” in some cases. For another example, the term “semiconductor layer” can be changed into the term “semiconductor film” in some cases.

A transistor is a kind of semiconductor element and can achieve a function of amplifying a current or a voltage, switching operation for controlling conduction or non-conduction, or the like. An IGFET (Insulated Gate Field Effect Transistor) and a thin film transistor (TFT) are in the category of a transistor in this specification and the like.

Functions of a “source” and a “drain” are sometimes interchanged with each other when a transistor of different polarity is used or when the direction of a current is changed in a circuit operation, for example. Thus, the terms “source” and “drain” can be used interchangeably in this specification and the like. Note that a source and a drain of a transistor can also be referred to as a source terminal and a drain terminal or a source electrode and a drain electrode, for example, as appropriate depending on circumstances.

A “gate” and a “back gate” can be interchanged with each other. Thus, the terms “gate” and “back gate” can be used interchangeably in this specification and the like. Note that a gate and a back gate of a transistor can also be referred to as a gate electrode and a back gate electrode, for example, as appropriate depending on circumstances.

In this specification and the like, the expression “electrically connected” includes the case where components are connected to each other through an “object having any electric action”. There is no particular limitation on an “object having any electric function” as long as electric signals can be transmitted and received between components that are connected through the object. Examples of the “object having any electric function” include a switching element such as a transistor, a resistor, a coil, and other elements with a variety of functions as well as an electrode or a wiring.

Unless otherwise specified, an off-state current in this specification and the like refers to a leakage current flowing between a source and a drain when a transistor is in an off state (also referred to as a non-conducting state or a cutoff state). Unless otherwise specified, an off state in an n-channel transistor refers to a state where a voltage between its gate and source is lower than a threshold voltage (in a p-channel transistor, higher than a threshold voltage).

A “voltage” usually refers to a potential difference between a given potential and a reference potential (e.g., a ground potential (GND potential) or a source potential). A “potential” is a relative value, and a potential supplied to a wiring or the like changes, for example, depending on the reference potential in some cases. Therefore, the terms “voltage” and “potential” can be replaced with each other in some cases.

In this specification and the like, the expression “having substantially the same planar shape” means that outlines of stacked layers at least partly overlap each other. For example, the case of processing an upper layer and a lower layer using the same mask pattern or mask patterns that are partly the same is included. However, in some cases, the outlines do not exactly overlap with each other and the upper layer is positioned inward from the lower layer or the upper layer is positioned outward from the lower layer; such a case is also represented by the expression “having substantially the same planar shape”. In the case where planar shapes are the same or substantially the same, it can be said that end portions are aligned with each other or substantially aligned with each other.

In this specification and the like, a planar shape of a component means the outline shape of the component in a plan view. A plan view means that the component is observed from a direction normal to a surface where the component is formed or a surface of a support (e.g., a substrate) where the component is formed.

In this specification and the like, a tapered shape refers to a shape such that at least part of a side surface of a component is inclined with respect to a substrate surface or a formation surface. For example, a tapered shape preferably includes a region where the angle between the inclined side surface and the substrate surface or the formation surface (such an angle is also referred to as a taper angle) is less than 90°. Note that the side surface, the substrate surface, and the formation surface of the component are not necessarily completely flat and may have a substantially planar shape with a small curvature or a substantially planar shape with slight unevenness.

In this specification and the like, a device manufactured using a metal mask or an FMM (fine metal mask, high-resolution metal mask) may be referred to as a device having an MM (metal mask) structure. In this specification and the like, a device formed without using a metal mask or an FMM may be referred to as a device having an MML (metal maskless) structure. Note that a device having the MML (metal maskless) structure can be manufactured without using a metal mask, and thus can break through the resolution limit due to alignment accuracy of the metal mask. Furthermore, the device having the MML structure can eliminate the need for the manufacturing facilities for metal masks and the washing process for metal masks. In addition, the device having the MML structure can be manufactured at low cost, and thus is suitable for mass production.

In this specification and the like, a structure where at least light-emitting layers are separately formed for light-emitting elements with different emission wavelengths is referred to as a side-by-side (SBS) structure in some cases. The SBS structure can optimize materials and structures of light-emitting elements and thus can extend freedom of choice of materials and structures, whereby the luminance and the reliability can be easily improved.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other in some cases depending on the cross-sectional shape, the characteristics, or the like. One layer may have two or three functions of the carrier-injection layer, the carrier-transport layer, and the carrier-blocking layer in some cases.

In this specification and the like, the light-emitting element includes an EL layer between a pair of electrodes. The EL layer includes at least a light-emitting layer. Examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, a light-receiving element (also referred to as a light-receiving device) includes at least an active layer functioning as a photoelectric conversion layer between a pair of electrodes. In this specification and the like, one of the pair of electrodes may be referred to as a pixel electrode and the other may be referred to as a common electrode.

In this specification and the like, a sacrificial layer (which may be referred to as a mask layer) is positioned above at least a light-emitting layer (specifically, a layer processed into an island shape among layers included in an EL layer) and has a function of protecting the light-emitting layer in the manufacturing process.

In this specification and the like, an island shape refers to a state where two or more layers formed using the same material in the same step are physically separated from each other. For example, an island-shaped light-emitting layer refers to a state where the light-emitting layer and its adjacent light-emitting layer are physically separated from each other.

In this specification and the like, step disconnection refers to a phenomenon in which a layer, a film, or an electrode is divided because of the shape of the formation surface (e.g., a step).

### Embodiment 1

In this embodiment, structure examples of a semiconductor device of one embodiment of the present invention are described. Here, a structure including a transistor will be described specifically.

In the semiconductor device of one embodiment of the present invention, an insulating layer functioning as a spacer is provided over a base insulating layer. Note that in the following description, an insulating layer functioning as a spacer is simply referred to as a spacer in some cases, and the spacer may be read as an insulating layer. The spacer includes a first opening portion reaching the base insulating layer. A first transistor is provided to include a region positioned in the first opening portion.

A source electrode (a first source electrode) and a drain electrode (a first drain electrode) of the first transistor are provided over the spacer. The first source electrode and the first drain electrode are provided to face each other with the first opening portion interposed therebetween in a plan view.

A first semiconductor layer is provided to include a region positioned in the first opening portion. A channel formation region of the first transistor is provided in the first semiconductor layer. The first semiconductor layer can be provided along a bottom surface and a side surface of the first opening portion. The first semiconductor layer can include, for example, a region in contact with an upper surface of the first source electrode, a region in contact with a side surface of the first source electrode, a region in contact with an upper surface of the first drain electrode, and a region in contact with a side surface of the first drain electrode. A gate insulating layer and a gate electrode (a first gate electrode) of the first transistor are provided in this order over the first semiconductor layer to include a region positioned in the first opening portion. The first gate electrode is provided to include a region overlapping with the first semiconductor layer with the gate insulating layer therebetween in the first opening portion. The first gate electrode is provided to include a region facing the first semiconductor layer with the gate insulating layer therebetween in the first opening portion.

In this specification and the like, in the case where B includes an opening portion reaching A, the upper surface of A exposed in the opening portion is referred to as the bottom surface of the opening portion. The side surface of B exposed in the opening portion is referred to as the side surface of the opening portion.

Thus, in the first transistor, the channel length can be not only in the direction along the bottom surface of the first opening portion (also referred to as the lateral direction) but also in the direction along the side surface of the first opening portion (also referred to as the vertical direction). Thus, the first transistor can have a longer channel length than a planar transistor not provided with the first opening portion, for example, without an increase in the area occupied by the first transistor, specifically, the area occupied by the first semiconductor layer. Accordingly, a transistor having a minute size and good saturation characteristics can be achieved. Thus, in the case where the semiconductor device of one embodiment of the present invention is used for a display device including a light-emitting element, for example, the saturation characteristics of a driving transistor that controls current flowing through the light-emitting element can be improved while a pixel is miniaturized. Therefore, current flowing through the light-emitting element can be stabilized, and the emission luminance of the light-emitting element can be stabilized. For example, in the case where a still image is displayed on the display device, generation of a time-related variation in current flowing through the light-emitting element can be inhibited, and generation of a time-related variation in emission luminance of the light-emitting element can be inhibited. Accordingly, the use of the semiconductor device of one embodiment of the present invention for a display device enables the display device to have high resolution and high reliability.

Here, in addition to the first transistor, a second transistor having a structure different from that of the first transistor can be provided over the base insulating layer. The first transistor and the second transistor can be formed while sharing some formation steps.

In the case where the second transistor is provided in the semiconductor device of one embodiment of the present invention, a first conductive layer functioning as one of a source electrode (a second source electrode) and a drain electrode (a second drain electrode) of the second transistor is provided over the base insulating layer.

The spacer is provided over the first conductive layer. The spacer includes a second opening portion reaching the first conductive layer. The second opening portion can be formed in the same step as the first opening portion. The second transistor is provided to include a region positioned in the second opening portion.

A second conductive layer functioning as the other of the second source electrode and the second drain electrode is provided over the spacer. The second conductive layer includes a third opening portion including a region overlapping with the second opening portion. The second conductive layer can be formed using the same material in the same step as the first source electrode and the first drain electrode. For example, the first source electrode, the first drain electrode, and the second conductive layer can be formed by processing the same conductive film.

A second semiconductor layer is provided to include a region positioned in the second opening portion and a region positioned in the third opening portion. A channel formation region of the second transistor is provided in the second semiconductor layer. The second semiconductor layer can be provided along a side surface of the spacer in the second opening portion and a side surface of the second conductive layer in the third opening portion. The second semiconductor layer can include a region in contact with the upper surface of the first conductive layer, the side surface of the second conductive layer, and the upper surface of the second conductive layer, for example. The second semiconductor layer can be formed using the same material in the same step as the first semiconductor layer. For example, the first semiconductor layer and the second semiconductor layer can be formed by processing the same semiconductor film.

A gate insulating layer and a gate electrode (a second gate electrode) of the second transistor are provided in this order over the second semiconductor layer to include a region positioned in the second opening portion. The second gate electrode is provided to include a region facing the second semiconductor layer with the gate insulating layer therebetween in the second opening portion. Here, the gate insulating layer of the second transistor can be common to the gate insulating layer of the first transistor. The second gate electrode can be formed using the same material in the same step as the first gate electrode. For example, the first gate electrode and the second gate electrode can be formed by processing the same conductive film.

In the second transistor, the channel length is in a direction along the side surface of the second opening portion of the spacer (also referred to as the vertical direction), but not in a direction parallel to the upper surface of the base insulating layer. Thus, the channel length of the second transistor is shorter than the channel length of the first transistor. Accordingly, the second transistor can have a higher on-state current than the first transistor. Thus, when the second transistor is used as a selection transistor provided in the above-described pixel and having a function of selecting a pixel to which image data is to be written, for example, the display device of one embodiment of the present invention can be driven at high speed.

In this specification and the like, “parallel” indicates a state where two straight lines are placed at an angle greater than or equal to −10° and less than or equal to 10°. Thus, the case where the angle is greater than or equal to −5° and less than or equal to 5° is also included. In addition, “approximately parallel” or “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Thus, the case where the angle is greater than or equal to 85° and less than or equal to 95° is also included. Furthermore, “approximately perpendicular” or “substantially perpendicular” indicates a state where two straight lines are placed at an angle greater than or equal to 60° and less than or equal to 120°.

As described above, in the semiconductor device of one embodiment of the present invention, a plurality of transistors having different electrical characteristics can be formed while sharing some steps. Thus, a circuit having desired performance can be easily achieved with reduced manufacturing cost, for example. Accordingly, an inexpensive semiconductor device having high performance can be achieved. For example, in the case where the semiconductor device of one embodiment of the present invention is used for a display device, the display device can be inexpensive and can have high resolution, high reliability, and high driving speed.

Here, in the semiconductor device of one embodiment of the present invention, the first source electrode, the first drain electrode, and the second conductive layer can be formed using the same mask pattern as the first semiconductor layer and the second semiconductor layer. For example, a conductive film is formed over the spacer, and the third opening portion and a fourth opening portion, which reach the spacer, are formed in the conductive film. Next, the first opening portion that includes a region overlapping with the fourth opening portion and reaches the base insulating layer and the second opening portion that includes a region overlapping with the third opening portion and reaches the first conductive layer are formed in the spacer. Then, the semiconductor film is formed to cover the first to fourth opening portions. Next, a resist mask reflecting a mask pattern is formed by a photolithography method, and the semiconductor film is processed on the basis of the mask pattern, so that the first semiconductor layer and the second semiconductor layer are formed. After that, the conductive film is processed on the basis of the same mask pattern, whereby the first source electrode, the first drain electrode, and the second conductive layer can be formed. The semiconductor film and the conductive film can be processed by an etching method, for example.

Thus, the number of manufacturing steps of the first transistor and the second transistor can be smaller than that in the case where, between the formation of the above conductive film and the formation of the semiconductor film, the above conductive film is processed to form the first source electrode, the first drain electrode, and the second conductive layer and then the semiconductor film is formed and processed to form the first semiconductor layer and the second semiconductor layer, for example. Accordingly, the manufacturing cost of the semiconductor device of one embodiment of the present invention can be reduced. The semiconductor device of one embodiment of the present invention can thus be an inexpensive semiconductor device.

In the semiconductor device manufactured by the above method, an end portion of the first semiconductor layer, specifically, an end portion of a lower surface thereof outside the first opening portion can include a region that is aligned or substantially aligned with an end portion of the first source electrode, specifically, an end portion of an upper surface thereof and a region that is aligned or substantially aligned with an end portion of the first drain electrode, specifically, an end portion of an upper surface thereof. An end portion of the second semiconductor layer, specifically, an end portion of a lower surface thereof outside the third opening portion can include a region that is aligned or substantially aligned with an end portion of the second conductive layer, specifically, an end portion of an upper surface thereof.

When the above semiconductor film and the above conductive film have different etching rates, for example, in the direction horizontal to the upper surface of the base insulating layer, even though the above semiconductor film and the above conductive film are processed with the same mask pattern, the end portion of the lower surface of the first semiconductor layer outside the first opening portion is not aligned with the end portion of the upper surface of the first source electrode and the end portion of the upper surface of the first drain electrode in some cases. In addition, the end portion of the lower surface of the second semiconductor layer outside the third opening portion is not aligned with the end portion of the upper surface of the second conductive layer in some cases. Even in such a case, the end portion of the lower surface of the first semiconductor layer outside the first opening portion can be regarded as being substantially aligned with the end portion of the upper surface of the first source electrode and the end portion of the upper surface of the first drain electrode. In addition, the end portion of the lower surface of the second semiconductor layer outside the third opening portion can be regarded as being substantially aligned with the end portion of the upper surface of the second conductive layer.

### Structure Example 1 of Semiconductor Device

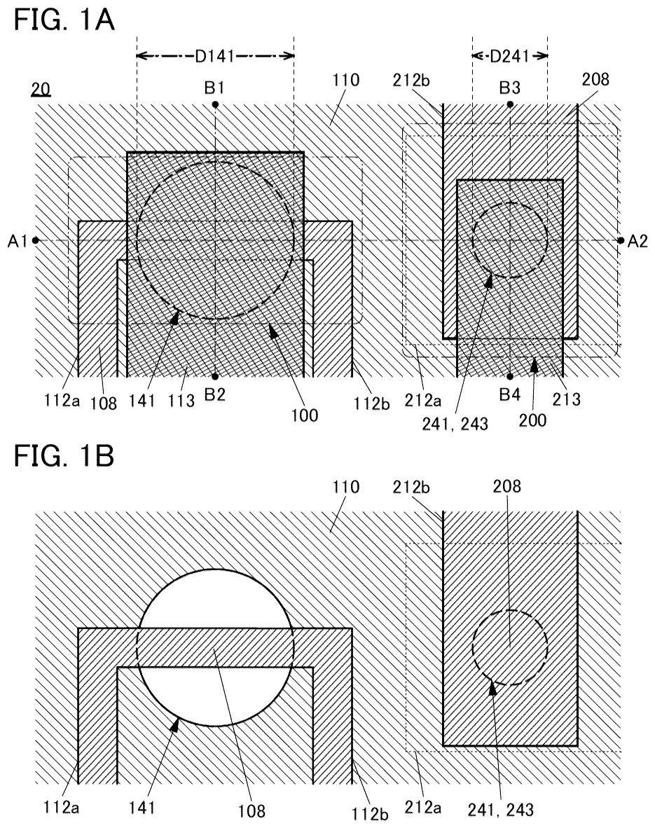

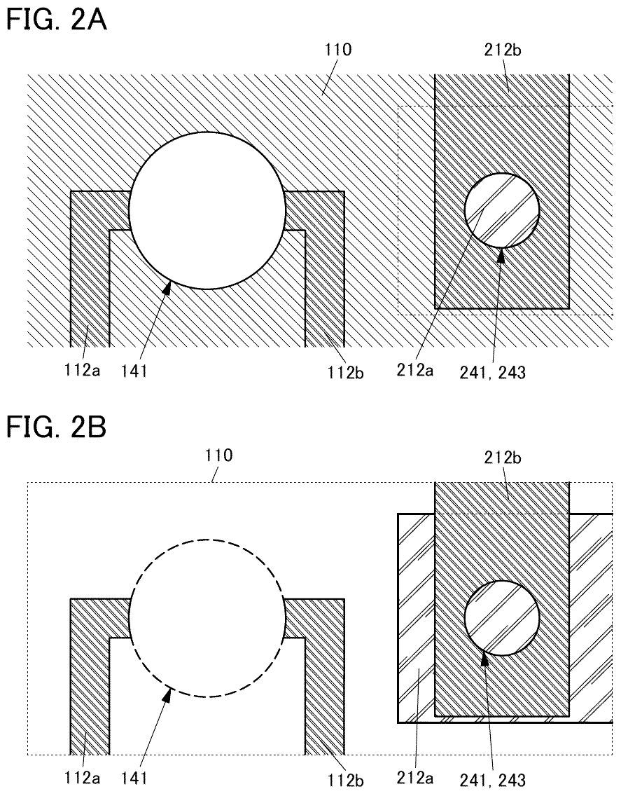

FIG. 1A is a plan view illustrating a structure example of a semiconductor device 20, which is the semiconductor device of one embodiment of the present invention. In FIG. 1A, some components, e.g., some insulating layers, of the semiconductor device 20 are omitted. As in FIG. 1A, some components are omitted in plan views illustrating structure examples of semiconductor devices in the subsequent plan views. FIG. 1B is a plan view in which some components in FIG. 1A are omitted. FIG. 2A is a plan view in which some components in FIG. 1B are omitted. FIG. 2B is a plan view in which the insulating layer illustrated in FIG. 2A is indicated by a dotted line.

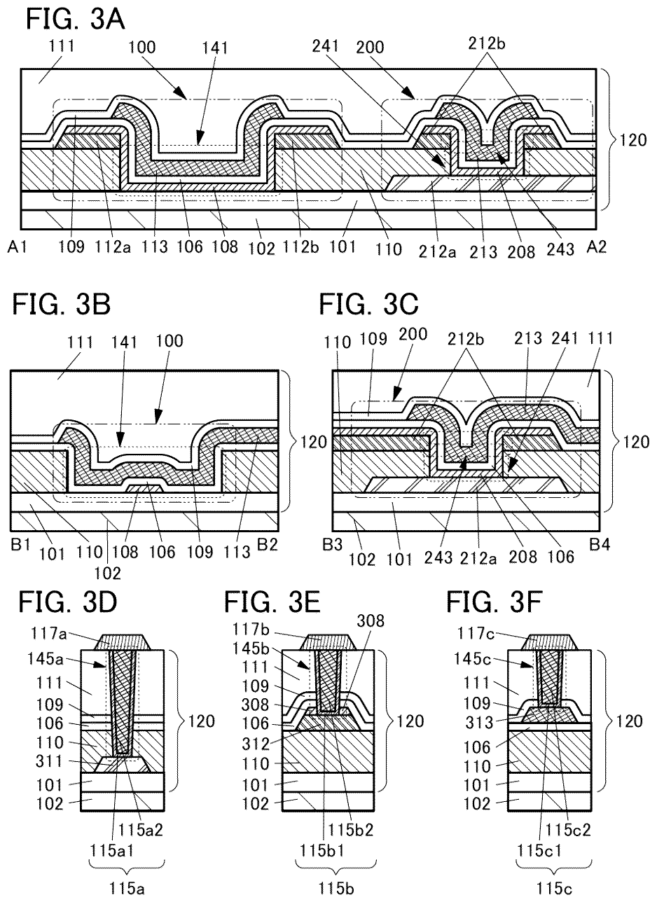

FIG. 3A is a cross-sectional view of a cut plane along the dashed-dotted line A1-A2 in FIG. 1A. FIG. 3B is a cross-sectional view of a cut plane along the dashed-dotted line B1-B2 in FIG. 1A. FIG. 3C is a cross-sectional view of a cut plane along the dashed-dotted line B3-B4 in FIG. 1A.

In the semiconductor device 20, an insulating layer 101 is provided over a substrate 102, and an insulating layer 110, a transistor 100, and a transistor 200 are provided over the insulating layer 101. The insulating layer 101 functions as a base insulating layer. The insulating layer 110 functions as a spacer. Note that at least one of an electrode, a wiring, a transistor, a capacitor, a resistor, and the like may be provided between the substrate 102 and the insulating layer 101. For example, a base insulating layer may be provided over the substrate 102, a layer provided with a wiring (also referred to as a wiring layer) may be provided over the base insulating layer, and the insulating layer 101 may be provided over the wiring layer.

The transistor 100 includes a conductive layer 113, a conductive layer 112a, a conductive layer 112b, an insulating layer 106, and a semiconductor layer 108. In the transistor 100, the conductive layer 113 functions as a gate electrode, and part of the insulating layer 106 functions as a gate insulating layer. The conductive layer 112a functions as one of a source electrode and a drain electrode and the conductive layer 112b functions as the other of the source electrode and the drain electrode. The layers included in the transistor 100 may each have a single-layer structure or a stacked-layer structure.

The insulating layer 110 includes an opening portion 141 reaching the insulating layer 101. The transistor 100 is provided to include a region positioned in the opening portion 141.

The conductive layer 112a and the conductive layer 112b are provided over the insulating layer 110. In other words, two conductive layers 112 are provided in one transistor 100 over the insulating layer 110. In the following description, the conductive layers denoted by the reference numeral “112” with an alphabet are collectively referred to as a conductive layer 112 in some cases.

An end portion of part of each of the conductive layer 112a and the conductive layer 112b is preferably aligned or substantially aligned with an end portion of the insulating layer 110 in the opening portion 141. Specifically, an end portion of an upper surface of the insulating layer 110 in the opening portion 141 preferably includes a region aligned or substantially aligned with an end portion of a lower surface of the conductive layer 112a that faces the opening portion 141 in a plan view and a region aligned or substantially aligned with an end portion of a lower surface of the conductive layer 112b that faces the opening portion 141 in the plan view. In this case, for example, the channel length of the transistor 100 can be easily controlled, and the transistor 100 can easily have desired electrical characteristics.

The conductive layer 112a and the conductive layer 112b can be formed using the same material. In addition, the conductive layer 112a and the conductive layer 112b can be formed in the same step. For example, a conductive film to be the conductive layer 112a and the conductive layer 112b is formed and then the conductive film is processed, whereby the conductive layer 112a and the conductive layer 112b can be formed.

The semiconductor layer 108 includes a region positioned in the opening portion 141. The semiconductor layer 108 can be provided along a bottom surface and a side surface of the opening portion 141. The semiconductor layer 108 can include, for example, a region in contact with the upper surface of the conductive layer 112a, a region in contact with the side surface of the conductive layer 112a, a region in contact with the upper surface of the conductive layer 112b, and a region in contact with the side surface of the conductive layer 112b. Furthermore, the semiconductor layer 108 can include a region in contact with the upper surface of the insulating layer 101 and a region in contact with the side surface of the insulating layer 110.

In the semiconductor layer 108, the region in contact with the conductive layer 112a functions as one of a source region and a drain region, and the region in contact with the conductive layer 112b functions as the other of the source region and the drain region. In the semiconductor layer 108, the channel formation region is provided between the source region and the drain region.

FIG. 1B is a diagram in which the conductive layer 113 in FIG. 1A is omitted. As illustrated in FIG. 1B and FIG. 3A, an end portion of the semiconductor layer 108, specifically, an end portion of a lower surface thereof outside the opening portion 141 includes a region aligned or substantially aligned with an end portion of the conductive layer 112a, specifically, an end portion of an end portion of an upper surface thereof and a region aligned or substantially aligned with an end portion of the conductive layer 112b, specifically, an end portion of an upper surface thereof. For example, when the conductive layer 112a and the conductive layer 112b are formed with the same mask pattern as the semiconductor layer 108, the end portion of the lower surface of the semiconductor layer 108 can include a region that is aligned or substantially aligned with the end portion of the upper surface of the conductive layer 112a and a region that is aligned or substantially aligned with the end portion of the upper surface of the conductive layer 112b.

For example, a conductive film is formed over the insulating layer 110, and an opening portion reaching the insulating layer 110 is formed in the conductive film. Then, the opening portion 141 that includes a region overlapping with the opening portion and reaches the insulating layer 101 is formed in the insulating layer 110. Next, a semiconductor film is formed to cover the opening portion 141. Then, a resist mask reflecting a mask pattern is formed by a photolithography method, and the semiconductor film is processed on the basis of the mask pattern, whereby the semiconductor layer 108 is formed. After that, the conductive film is processed on the basis of the same mask pattern, so that the conductive layer 112a and the conductive layer 112b can be formed. The semiconductor film and the conductive film can be processed by an etching method, for example.

Thus, the number of manufacturing steps of the transistor 100 can be smaller than that in the case where, between the formation of the above conductive film and the formation of the semiconductor film, the conductive film is processed to form the conductive layer 112a and the conductive layer 112b and then the semiconductor film is formed and processed to form the semiconductor layer 108, for example. Accordingly, the manufacturing cost of the semiconductor device 20 can be reduced. The semiconductor device 20 can thus be an inexpensive semiconductor device.

When the above semiconductor film and the above conductive film have different etching rates, for example, in the direction horizontal to the upper surface of the insulating layer 101 even though processed with the same mask pattern, the end portion of the lower surface of the semiconductor layer 108 outside the opening portion 141 is not aligned with the end portion of the upper surface of the conductive layer 112a and the end portion of the upper surface of conductive layer 112b in some cases. Even in such a case, the end portion of the lower surface of the semiconductor layer 108 outside the opening portion 141 can be regarded as being substantially aligned with the end portion of the upper surface of the conductive layer 112a and the end portion of the upper surface of conductive layer 112b.

FIG. 2A is a diagram in which the semiconductor layer 108 in FIG. 1B is omitted. FIG. 2B is a diagram in which the insulating layer 110 illustrated in FIG. 2A is indicated by a dotted line. As illustrated in FIG. 2A and FIG. 2B, the conductive layer 112a and the conductive layer 112b are provided to face each other with the opening portion 141 therebetween in the plan view.

As illustrated in FIG. 3(A) and FIG. 3(B), the insulating layer 106 is provided to include a region positioned in the opening portion 141, specifically, provided to cover the opening portion 141. The insulating layer 106 is provided over the semiconductor layer 108, the insulating layer 110, and the insulating layer 101. The insulating layer 106 has a shape along the upper surface and the side surface of the semiconductor layer 108, the side surfaces of the conductive layer 112a and the conductive layer 112b, the upper surface and the side surface of the insulating layer 110, and the upper surface of the insulating layer 101. The insulating layer 106 can include a region in contact with the upper surface of the semiconductor layer 108, a region in contact with the side surface of the semiconductor layer 108, a region in contact with the side surface of the conductive layer 112a, a region in contact with the side surface of the conductive layer 112b, a region in contact with the upper surface of the insulating layer 110, a region in contact with the side surface of the insulating layer 110, and a region in contact with the upper surface of the insulating layer 101.

The conductive layer 113 is provided over the insulating layer 106 to include a region positioned in the opening portion 141. The conductive layer 113 can include a first region positioned outside the opening portion 141 and a second region overlapping with the opening portion 141. The conductive layer 113 is provided so that the second region includes a region overlapping with the semiconductor layer 108 with the insulating layer 106 therebetween. The conductive layer 113 is provided to include a region facing the semiconductor layer 108 with the insulating layer 106 therebetween in the opening portion 141. The conductive layer 113 has a shape along the insulating layer 106; specifically, the conductive layer 113 can have a shape along an upper surface of the insulating layer 106 and a side surface of the insulating layer 106 in the opening portion 141. The conductive layer 113 can include a region in contact with the upper surface of the insulating layer 106 and a region in contact with the side surface of the insulating layer 106 in the opening portion 141.

The transistor 200 includes a conductive layer 213, a conductive layer 212a, a conductive layer 212b, the insulating layer 106, and a semiconductor layer 208. In the transistor 200, the conductive layer 213 functions as a gate electrode, and part of the insulating layer 106 functions as a gate insulating layer. The conductive layer 212a functions as one of a source electrode and a drain electrode and the conductive layer 212b functions as the other of the source electrode and the drain electrode. The layers included in the transistor 200 may each have a single-layer structure or a stacked-layer structure.

In FIG. 1B, the conductive layer 213 in FIG. 1A is omitted. In FIG. 2A, the semiconductor layer 208 in FIG. 1B is further omitted.

The conductive layer 212a is provided over the insulating layer 101. The insulating layer 110 is provided over the conductive layer 212a. The insulating layer 110 is provided to cover an upper surface and a side surface of the conductive layer 212a. The insulating layer 110 includes an opening portion 241 reaching the conductive layer 212a. The transistor 200 is provided to include a region positioned in the opening portion 241. Although FIG. 3A and FIG. 3C illustrate an example where the insulating layer 110 is planarized, the insulating layer 110 is not necessarily planarized.

The conductive layer 212b is provided over the insulating layer 110. The conductive layer 212b includes an opening portion 243 including a region overlapping with the opening portion 241. The planar shapes of the opening portion 241 and the opening portion 243 can each be a shape similar to the planar shape that the opening portion 141 can have. Here, the planar shape of the opening portion 241 and the planar shape of the opening portion 243 can be the same or substantially the same. In that case, an end portion of a lower surface of the conductive layer 212b in the opening portion 243 is preferably the same or substantially the same as an end portion of an upper surface of the insulating layer 110 in the opening portion 241.

Note that the planar shape of the opening portion 241 and the planar shape of the opening portion 243 are not necessarily the same. In the case where the planar shapes of the opening portion 241 and the opening portion 243 are circles, the opening portion 241 and the opening portion 243 may be concentrically arranged, but are not necessarily concentrically arranged.

The conductive layer 212b can be formed using the same material as the conductive layer 112a and the conductive layer 112b. In addition, the conductive layer 212b can be formed in the same step as the conductive layer 112a and the conductive layer 112b. For example, a film to be the conductive layer 112a, the conductive layer 112b, and the conductive layer 212b is formed and then the conductive film is processed, whereby the conductive layer 112a, the conductive layer 112b, and the conductive layer 212b can be formed.

The semiconductor layer 208 includes a region positioned in the opening portion 241 and a region positioned in the opening portion 243. The semiconductor layer 208 can be provided along a bottom surface and a side surface of the opening portion 241 and the side surface of the opening portion 243. The semiconductor layer 208 can include, for example, a region in contact with an upper surface of the conductive layer 212a, a region in contact with the side surface of the conductive layer 212b, and a region in contact with an upper surface of the conductive layer 212b. The semiconductor layer 208 can include a region in contact with the side surface of the insulating layer 110.

In the semiconductor layer 208, a region in contact with the conductive layer 212a functions as one of a source region and a drain region, and a region in contact with the conductive layer 212b functions as the other of the source region and the drain region. In the semiconductor layer 208, the channel formation region is provided between the source region and the drain region.

The semiconductor layer 208 can be formed using the same material as the semiconductor layer 108. In addition, the semiconductor layer 208 can be formed in the same step as the semiconductor layer 108. For example, a semiconductor film to be the semiconductor layer 108 and the semiconductor layer 208 is formed and then the semiconductor film is processed, whereby the semiconductor layer 108 and the semiconductor layer 208 can be formed.

As illustrated in FIG. 1B, FIG. 3A, and FIG. 3C, an end portion of the semiconductor layer 208, specifically, an end portion of a lower surface thereof outside the opening portion 243 includes a region that is aligned or substantially aligned with an end portion of the conductive layer 212b, specifically an end portion of an upper surface thereof. For example, when the conductive layer 212b and the semiconductor layer 208 are formed with the same mask pattern, the end portion of the lower surface of the semiconductor layer 208 can include a region that is aligned or substantially aligned with the end portion of the upper surface of the conductive layer 212b.

For example, a conductive film is formed over the insulating layer 110, and the opening portion 243 reaching the conductive layer 212a as well as the opening portion reaching the insulating layer 110 is formed in the conductive film. Then, the opening portion 241 that includes a region overlapping with the opening portion 243 and reaches the conductive layer 212a is formed in the insulating layer 110. The opening portion 241 can be formed in the same step as the opening portion 141.

Then, a semiconductor film is formed to cover the opening portion 241 and the opening portion 243 in addition to the opening portion 141. Next, a resist mask reflecting the mask pattern is formed by a photolithography method, and the semiconductor film is processed on the basis of the mask pattern, whereby the semiconductor layer 208 as well as the semiconductor layer 108 is formed. After that, the conductive film is processed on the basis of the same mask pattern, so that the conductive layer 212b as well as the conductive layer 112a and the conductive layer 112b can be formed. As described above, the semiconductor film and the conductive film can be processed by an etching method, for example.

Thus, the number of manufacturing steps of the transistor 200 can be smaller than that in the case where, between the formation of the above conductive film and the formation of the semiconductor film, the conductive film is processed to form the conductive layer 212b and then the semiconductor film is formed and processed to form the semiconductor layer 208, for example. When the number of manufacturing steps of the transistor 100 and the transistor 200 is reduced, the manufacturing cost of the semiconductor device 20 can be reduced as described above. The semiconductor device 20 can thus be an inexpensive semiconductor device.

The above semiconductor film and the above conductive film may have different etching rates, for example, in the direction horizontal to the upper surface of the insulating layer 101. In this case, even when the above semiconductor film and the above conductive film are processed with the same mask pattern, the end portion of the lower surface of the semiconductor layer 208 outside the opening portion 243 is sometimes not aligned with the end portion of the upper surface of the conductive layer 212b. Even in such a case, the end portion of the lower surface of the semiconductor layer 208 outside the opening portion 243 can be regarded as being substantially aligned with the end portion of the upper surface of the conductive layer 212b.

The insulating layer 106 is provided to include a region positioned in the opening portion 241 and a region positioned in the opening portion 243, specifically, provided to cover the opening portion 241 and the opening portion 243. The insulating layer 106 is provided over the semiconductor layer 208. The insulating layer 106 has a shape along the upper surface and the side surface of the semiconductor layer 208 and the side surface of the conductive layer 212b. The insulating layer 106 can include a region in contact with the upper surface of the semiconductor layer 208, a region in contact with the side surface of the semiconductor layer 208, and a region in contact with the side surface of the conductive layer 212b.

The conductive layer 213 is provided over the insulating layer 106 to include a region positioned in the opening portion 241 and a region positioned in the opening portion 243. The conductive layer 213 can include a third region positioned outside the opening portion 241 and a fourth region overlapping with the opening portion 241. The third region can be a region positioned outside the opening portion 243, and the fourth region can be a region overlapping with the opening portion 243, for example.

The conductive layer 213 is provided to include a region facing the semiconductor layer 208 with the insulating layer 106 therebetween in the opening portion 241. The conductive layer 213 has a shape along the insulating layer 106, and specifically can have a shape along the upper surface of the insulating layer 106 and the side surface of the insulating layer 106 in the opening portion 241 and the opening portion 243. The conductive layer 213 can include a region in contact with the upper surface of the insulating layer 106 and a region in contact with the side surface of the insulating layer 106 in the opening portion 241 and the opening portion 243.

For the conductive layer 213, the same material as the conductive layer 113 can be used. The conductive layer 213 can be formed in the same step as the conductive layer 113. For example, a conductive film to be the conductive layer 113 and the conductive layer 213 is formed and then the conductive film is processed, whereby the conductive layer 113 and the conductive layer 213 can be formed.

The transistor 200 is what is called a top-gate transistor including the gate electrode above the semiconductor layer 208. Furthermore, since a lower surface of the layer 208 is in contact with the conductive layer 212a and the conductive layer 212b functioning as the source electrode and the drain electrode, the transistor 200 can be referred to as a TGBC (Top Gate Bottom Contact) transistor.

In the transistor 200, since the source electrode, the layer including the channel formation region, and the drain electrode can be provided to overlap with each other, the area occupied by the transistor can be significantly reduced as compared with what is called a planar transistor in which a layer including a channel formation region is provided in a planar shape.

The conductive layer 212a, the conductive layer 212b, and the conductive layer 213 can function as wirings, and the transistor 200 can be provided in a region where these wirings overlap with each other. That is, the area occupied by the transistor 200 and the wirings can be reduced in the circuit including the transistor 200 and the wirings. Accordingly, the area occupied by the circuit can be reduced, so that a small semiconductor device can be obtained. Note that the conductive layer 112a, the conductive layer 112b, and the conductive layer 113 included in the transistor 100 can also each function as a wiring.

Meanwhile, the conductive layer 112a functioning as one of the source electrode and the drain electrode of the transistor 100 and the conductive layer 112b functioning as the other of the source electrode and the drain electrode of the transistor 100 are formed over the same surface. Specifically, the conductive layer 112a and the conductive layer 112b are provided over the insulating layer 110. By contrast, the conductive layer 212a functioning as one of the source electrode and the drain electrode of the transistor 200 and the conductive layer 212b functioning as the other of the source electrode and the drain electrode of the transistor 200 are provided over different surfaces. Specifically, the conductive layer 212a is provided over the insulating layer 101, the conductive layer 212b is provided over the insulating layer 110, and the insulating layer 110 is interposed between the conductive layer 212a and the conductive layer 212b. In other words, one of the source electrode and the drain electrode of the transistor 200 is provided over a surface different from that provided with the source electrode and the drain electrode of the transistor 100, and the other of the source electrode and the drain electrode of the transistor 200 is provided over the same surface as the source electrode and the drain electrode of the transistor 100.

In the case where the semiconductor device of one embodiment of the present invention is used for a pixel circuit of a display device, for example, the area occupied by the pixel circuit can be reduced and the display device can have high resolution. In the case where the semiconductor device of one embodiment of the present invention is used for a driver circuit (e.g., one or both of a scan line driver circuit and a signal line driver circuit) of a display device, for example, the area occupied by the driver circuit can be reduced and the display device can have a narrow bezel.

An insulating layer 109 is provided to cover the transistor 100 and the transistor 200. The insulating layer 109 is provided over the conductive layer 113, the conductive layer 213, and the insulating layer 106. The insulating layer 109 functions as a protective layer of the transistor 100 and the transistor 200.

An insulating layer 111 is provided over the insulating layer 109. The insulating layer 111 functions as an interlayer insulating layer. Although FIG. 3A, FIG. 3B, and FIG. 3C illustrate an example where the insulating layer 111 is planarized, the insulating layer 111 is not necessarily planarized. The insulating layer 109 may be planarized. Here, the insulating layer 101 to the insulating layer 111 are collectively referred to as a layer 120. The transistor 100 and the transistor 200 are provided in the layer 120.

FIG. 3D is a cross-sectional view illustrating a conductive layer 311 which is provided in the same layer as the conductive layer 212a, a conductive layer 117a which is provided over the insulating layer 111 and functions as a wiring, and a plug 115a which electrically connects these layers. In the example illustrated in FIG. 3D, the conductive layer 311 is provided over the insulating layer 101, and the insulating layer 110 is provided over the insulating layer 101 and the conductive layer 311.

The conductive layer 311 can be the conductive layer 212a itself. The conductive layer 311 can be a wiring that is formed using the same material in the same step as the conductive layer 212a and is different from the conductive layer 212a.

The insulating layer 110, the insulating layer 106, the insulating layer 109, and the insulating layer 111 include an opening portion 145a reaching the conductive layer 311, and the plug 115a is provided to be embedded in the opening portion 145a. The conductive layer 311 and the conductive layer 117a are electrically connected to each other through the plug 115a. Here, the plug 115a preferably includes a conductive layer 115al, which is provided along a side surface and a bottom surface of the opening portion 145a, and a conductive layer 115a2, which is positioned more on the inner side of the opening portion 145a than the conductive layer 115al and provided to be embedded in the opening portion 145a. Since the insulating layer 110, the insulating layer 106, the insulating layer 109, and the insulating layer 111 are provided in the layer 120, the plug 115a is also provided in the layer 120.

In this case, a conductive material through which hydrogen and oxygen are less likely to diffuse is preferably used for the conductive layer 115a1. For example, tantalum, tantalum nitride, titanium, titanium nitride, ruthenium, ruthenium oxide, or the like is preferably used. The conductive material having a function of inhibiting passage of impurities such as water and hydrogen may be used as a single layer or stacked layers. Such a structure can inhibit entry of impurities such as water and hydrogen into the semiconductor layer 108 and the semiconductor layer 208 through the plug 115a.

A conductive material with high conductivity is preferably used for the conductive layer 115a2, in which case the electric resistance of the plug 115a can be reduced. For example, a conductive material containing tungsten, copper, aluminum, or the like as its main component is used for the conductive layer 115a2.

FIG. 3E is a cross-sectional view illustrating a conductive layer 312 which is provided in the same layer as the conductive layer 112a, the conductive layer 112b, and the conductive layer 212b; a semiconductor layer 308 which is provided in the same layer as the semiconductor layer 108 and the semiconductor layer 208; a conductive layer 117b which is provided over the insulating layer 111 and functions as a wiring; and a plug 115b which electrically connects the conductive layer 312 and the conductive layer 117b. In the example illustrated in FIG. 3E, the conductive layer 312 is provided over the insulating layer 110, the semiconductor layer 308 is provided over the conductive layer 312, and the insulating layer 106 is provided over the insulating layer 110 and the semiconductor layer 308.

The conductive layer 312 can be the conductive layer 112a itself, the conductive layer 112b itself, or the conductive layer 212b itself, and the semiconductor layer 308 can be the semiconductor layer 108 itself or the semiconductor layer 208 itself. The conductive layer 312 can be a wiring that is formed using the same material in the same step as the conductive layer 112a, the conductive layer 112b, and the conductive layer 212b and is different from the conductive layer 112a, the conductive layer 112b, and the conductive layer 212b. Furthermore, the semiconductor layer 308 can be a semiconductor layer that is formed using the same material in the same step as the semiconductor layer 108 and the semiconductor layer 208 and is different from the semiconductor layer 108 and the semiconductor layer 208.

As described above, the conductive layer 112a, the conductive layer 112b, and the conductive layer 212b can be formed with the same mask pattern as the semiconductor layer 108 and the semiconductor layer 208. Thus, the conductive layer 312 and the semiconductor layer 308 can also be formed with the same mask pattern. Accordingly, an end portion of the semiconductor layer 308, specifically, an end portion of a lower surface thereof can include a region that is aligned or substantially aligned with an end portion of the conductive layer 312, specifically, an end portion of an upper surface thereof.

The semiconductor layer 308, the insulating layer 106, the insulating layer 109, and the insulating layer 111 include an opening portion 145b reaching the conductive layer 312, and the plug 115b is provided to be embedded in the opening portion 145b. The conductive layer 312 and the conductive layer 117b are electrically connected to each other through the plug 115b. Here, the plug 115b preferably includes a conductive layer 115b1, which is provided along a side surface and a lower surface of the opening portion 145b, and a conductive layer 115b2, which is positioned more on the inner side of the opening portion 145b than the conductive layer 115b1 and provided to be embedded in the opening portion 145b. For the conductive layer 115b1, a material similar to the material that can be used for the conductive layer 115al can be used. For the conductive layer 115b2, a material similar to the material that can be used for the conductive layer 115a2 can be used. Since the semiconductor layer 308, the insulating layer 106, the insulating layer 109, and the insulating layer 111 are provided in the layer 120, the plug 115b is also provided in the layer 120.

FIG. 3F is a cross-sectional view illustrating a conductive layer 313 provided in the same layer as the conductive layer 113 and the conductive layer 213, a conductive layer 117c which is provided over the insulating layer 111 and functions as a wiring, and a plug 115c electrically connecting these layers. In the example illustrated in FIG. 3F, the conductive layer 313 is provided over the insulating layer 106, and the insulating layer 109 is provided over the insulating layer 106 and the conductive layer 313.

The conductive layer 313 can be the conductive layer 113 itself or the conductive layer 213 itself. The conductive layer 313 can be a wiring that is formed using the same material in the same step as the conductive layer 113 and the conductive layer 213 and is different from the conductive layer 113 and the conductive layer 213.

The insulating layer 109 and the insulating layer 111 have an opening portion 145c reaching the conductive layer 313, and the plug 115c is provided to be embedded in the opening portion 145c. The conductive layer 313 and the conductive layer 117c are electrically connected to each other through the plug 115c. Here, the plug 115c preferably includes a conductive layer 115cl, which is provided along a side surface and a bottom surface of the opening portion 145c, and a conductive layer 115c2, which is positioned more on the inner side of the opening portion 145c than the conductive layer 115cl and provided to be embedded in the opening portion 145c. For the conductive layer 115cl, a material similar to the material that can be used for the conductive layer 115al can be used. For the conductive layer 115c2, a material similar to the material that can be used for the conductive layer 115a2 can be used. Since the insulating layer 109 and the insulating layer 111 are provided in the layer 120, the plug 115c is also provided in the layer 120.

In the following description of matters common to the plug 115a, the plug 115b, and the plug 115c, the alphabets added to the reference numerals are omitted and the term “plug 115” is used in some cases. Similarly, the conductive layer 117a, the conductive layer 117b, and the conductive layer 117c are described using the term “conductive layer 117” in some cases. Furthermore, the opening portion 145a, the opening portion 145b, and the opening portion 145c are described using the term “opening portion 145” in some cases.

For the conductive layer 117, a single layer or stacked layers of a material that can be used for at least one of the conductive layer 311, the conductive layer 312, the conductive layer 313, and the plug 115 can be used. For example, the conductive layer 117 can have a five-layer stacked structure in which a layer using titanium, a layer using titanium nitride, a layer using aluminum, a layer using titanium, and a layer using titanium nitride are stacked in this order.

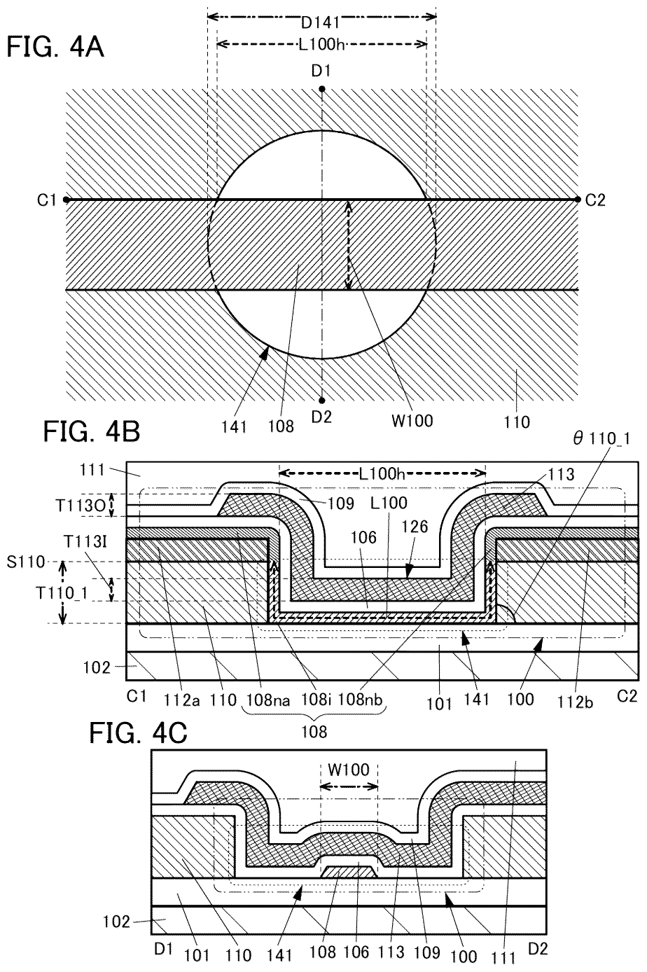

FIG. 4A is an enlarged view of the opening portion 141 illustrated in FIG. 1B and a region in the vicinity thereof. FIG. 4B is a cross-sectional view taken along the dashed-dotted line C1-C2 in FIG. 4A. FIG. 4C is a cross-sectional view taken along the dashed-dotted line D1-D2 in FIG. 4A. The channel length, the channel width, and the like of the transistor 100 are described with reference to FIG. 4A to FIG. 4C.

In FIG. 4A, FIG. 4B, and FIG. 4C, the channel length of the transistor 100 is denoted as a length L100, the channel width of the transistor 100 is denoted as a width W100, the width of the opening portion 141 is denoted as a width D141, the thickness of the insulating layer 110 is denoted as a thickness T110_1, and an angle formed by the side surface of the insulating layer 110 in the opening portion 141 and the upper surface of the insulating layer 101 is denoted as an angle θ110_1. In FIG. 4A, FIG. 4B, and FIG. 4C, the length L100, the width W100, the width D141, and the thickness T110_1 are indicated by double-headed arrows. Similar representations are shown in other drawings. Here, the thickness T110_1 can be the shortest distance between the formation surface of the insulating layer 110 (the upper surface of the insulating layer 101 here) and the lower surface of the conductive layer 112a or the conductive layer 112b in the cross-sectional view, as illustrated in FIG. 4B.

FIG. 4B illustrates a region 108i, a region 108na, and a region 108nb as regions of the semiconductor layer 108. The region 108i is provided between the region 108na and the region 108nb.

At least part of the region 108i functions as the channel formation region of the transistor 100. The region 108na corresponds to a region of the semiconductor layer 108 that is in contact with the conductive layer 112a and the vicinity of the region. At least part of the region 108na functions as one of the source region and the drain region of the transistor 100. The region 108nb corresponds to a region of the semiconductor layer 108 that is in contact with the conductive layer 112b and the vicinity of the region. At least part of the region 108nb functions as the other of the source region and the drain region of the transistor 100. At least part of the region 108na and at least part of the region 108nb can be a region having lower electric resistance than at least part of the region 108i (hereinafter also referred to as a low-resistance region). For example, at least part of the region 108na and at least part of the region 108nb can be a region having a higher carrier concentration or a higher oxygen defect density than at least part of the region 108i. Although FIG. 4B illustrates an example where the boundary between the region 108i and the region 108na is level with or substantially level with the boundary between the insulating layer 110 and the conductive layer 112a and the boundary between the region 108i and the region 108nb is level with or substantially level with the boundary between the insulating layer 110 and the conductive layer 112b, these boundaries are not necessarily level with or substantially level with each other.

In this specification and the like, the expression “level or substantially level” indicates having the same level from a reference surface (e.g., a flat surface such as a substrate surface) in a cross-sectional view. For example, in a manufacturing process of a semiconductor device, planarization treatment sometimes causes exposure of the surface(s) of a single layer or a plurality of layers. In that case, the surfaces on which the planarization treatment has been performed are at the same level as a reference surface. Note that the plurality of layers having the surfaces on which the planarization treatment has been performed are not level with each other in the strict sense in some cases, depending on a treatment apparatus, a treatment method, or a material of the surfaces on which the planarization treatment is performed. This case is also described with the expression “level or substantially level” in this specification and the like. For example, the expression “level or substantially level” also includes the case where two layers (here, given as a first layer and a second layer) whose levels with respect to the reference surface are different from each other are provided and the difference between the top-surface level of the first layer and the top-surface level of the second layer is less than or equal to 20 nm.

The length L100, which is the channel length of the transistor 100, corresponds to the sum of the two lengths: twice the length of the side surface of the insulating layer 110 in the opening portion 141 in the cross-sectional view; and a length L100h, which is the shortest value of the length in the direction along a bottom surface of the opening portion 141, among the length components in the channel length direction of the transistor 100 in a region of the semiconductor layer 108 that overlaps with the opening portion 141. The length L100h can be referred to as the shortest value of the length of the transistor 100 in the channel length direction in the plan view. The length of the side surface of the insulating layer 110 in the opening portion 141 in the cross-sectional view can be determined by the thickness T110_1 and the angle θ110_1. For example, when the angle θ110_1 is 90°, “L100=2×T110_1+L100h” can be satisfied. Here, the level of the opening portion 141 can be the thickness T110_1. Note that in FIG. 4A and FIG. 4B, the length L100h is indicated by a double-headed arrow.

As described above, in the semiconductor layer 108 of the transistor 100, the channel length can be not only in the direction along the bottom surface of the opening portion 141 (also referred to as the lateral direction) but also in the direction along the side surface of the opening portion 141 (also referred to as the vertical direction). Thus, the transistor 100 can have a longer channel length than a planar transistor not provided with the opening portion 141 without an increase in the area occupied by the transistor 100, specifically, the area occupied by the semiconductor layer 108. Accordingly, a transistor having a minute size and good saturation characteristics can be achieved. Accordingly, in the case where the semiconductor device 20 is used for a display device including a light-emitting element, for example, the saturation characteristics of a driving transistor that controls current flowing through the light-emitting element can be improved while a pixel is miniaturized. Therefore, current flowing through the light-emitting element can be stabilized, and the emission luminance of the light-emitting element can be stabilized. For example, in the case where a still image is displayed on the display device, generation of a time-related variation in current flowing through the light-emitting element can be inhibited, and generation of a time-related variation in emission luminance of the light-emitting element can be inhibited. Accordingly, the use of the semiconductor device 20 for a display device enables the display device to have high resolution and high reliability. Note that the transistor 100 has a structure where current flows in both the vertical direction and the lateral direction, and thus can be referred to as a VLFET (Vertical Lateral Field Effect Transistor).

As described above, the length L100, which is the channel length of the transistor 100, includes the component along the bottom surface of the opening portion 141 and a component along the side surface of the opening portion 141. Here, when the length of the component of the length L100 along the bottom surface of the opening portion 141 is longer than the length of the component along the side surface of the opening portion 141, contribution of the component along the bottom surface of the opening portion 141 to the length L100 can be larger than contribution of the component along the side surface of the opening portion 141 to the length L100. In the case where a plurality of transistors 100 are provided in the semiconductor device 20, the width D141 of the opening portion 141 can differ between the transistors 100, for example. Meanwhile, the thickness T110_1 that can be regarded as the level of the opening portion 141 is equal or substantially equal in the plurality of transistors 100. Thus, when the contribution of the component along the bottom surface of the opening portion 141 to the length L100 is increased, the lengths L100 of the plurality of transistors 100 can be easily controlled, specifically, the lengths L100 can be easily made different from each other. Accordingly, a plurality of transistors 100 having different electrical characteristics are easily formed separately in the circuit included in the semiconductor device 20, for example. Thus, a circuit having desired performance can be easily achieved, for example. Accordingly, a semiconductor device having high performance can be achieved.

The length of the component of the channel length of the transistor 100 along the bottom surface of the opening portion 141 is preferably longer than or equal to the length of the component of the channel length of the transistor 100 along the side surface of the opening portion 141, for example. Alternatively, the width D141 is preferably greater than or equal to the thickness T110_1.

In the length L100, the length of the component along the bottom surface of the opening portion 141 may be shorter than the length of the component along the side surface of the opening portion 141. For example, the width D141 may be smaller than twice the thickness T110_1. In such a case, the channel length of the transistor 100 can be increased while the width D141 is reduced. Thus, the transistor 100 can have a minute size and good saturation characteristics.

The thickness T110_1 can be, for example, greater than or equal to 0.1 nm and less than 3 μm, greater than or equal to 0.1 nm and less than or equal to 2.5 μm, greater than or equal to 1 nm and less than or equal to 2 μm, greater than or equal to 1 nm and less than or equal to 1.5 μm, greater than or equal to 5 nm and less than or equal to 1.2 μm, greater than or equal to 5 nm and less than or equal to 1 μm, greater than or equal to 7 nm and less than or equal to 500 nm, greater than or equal to 7 nm and less than or equal to 300 nm, greater than or equal to 10 nm and less than or equal to 200 nm, greater than or equal to 10 nm and less than or equal to 100 nm, or greater than or equal to 10 nm and less than or equal to 50 nm.

In the case where the opening portion 141 is formed by a photolithography method, the width D141 of the opening portion 141 is larger than or equal to the resolution limit of a light-exposure apparatus. The width D141 can be, for example, greater than or equal to 200 nm and less than 5 μm, greater than or equal to 200 nm and less than or equal to 4.5 μm, greater than or equal to 200 nm and less than or equal to 4 μm, greater than or equal to 300 nm and less than or equal to 3.5 μm, greater than or equal to 300 nm and less than or equal to 3 μm, greater than or equal to 400 nm and less than or equal to 2.5 μm, greater than or equal to 400 nm and less than or equal to 2 μm, greater than or equal to 500 nm and less than or equal to 1.5 μm, or greater than or equal to 500 nm and less than or equal to 1 μm.

FIG. 1A to FIG. 2B and FIG. 4A illustrate an example where the planar shape of the opening portion 141 is a circle. In that case, the width D141 can correspond to the diameter of the circle. Note that in this specification and the like, a circle is not necessarily a perfect circle.

There is no limitation on the planar shape of the opening portion 141, and the shape can be a circle; an ellipse; a polygon such as a triangle, a tetragon (including a rectangle, a rhombus, and a square), or a pentagon; or any of these polygons whose corners are rounded, for example. Note that the polygon may be a concave polygon (a polygon at least one of the interior angles of which is greater than 180°) or a convex polygon (a polygon all the interior angles of which are less than or equal to 180°).

In this specification and the like, the planar shape of an opening portion in an insulating layer refers to the shape of an end portion of an upper surface or an end portion of a lower surface of the insulating layer in the opening portion. For example, the planar shape of the opening portion 141 refers to the shape of the end portion of the upper surface or the end portion of the lower surface of the insulating layer 110 in the opening portion 141.

The side surface of the insulating layer 110 in the opening portion 141 preferably has a vertical shape, specifically, is preferably perpendicular to the upper surface of the insulating layer 101, for example. That is, the angle θ0110_1 is preferably greater than or equal to 80° and less than or equal to 100°, further preferably greater than or equal to 85° and less than or equal to 95°. Thus, the transistor 100 can be a transistor having a minute size. Accordingly, the area occupied by the circuit provided in the semiconductor device 20 can be reduced, so that the semiconductor device 20 can be a small semiconductor device. Note that the side surface of the insulating layer 110 in the opening portion 141 may have a tapered shape. For example, the angle θ110_1 may be less than 90° or less than 80°. In that case, the coverage with a layer (e.g., the semiconductor layer 108) formed over the insulating layer 110 can be improved. The smaller the angle θ110_1 is, the longer the length L100 can be, and the larger the angle θ110_1 is, the shorter the length L100 can be.

Although FIG. 3A to FIG. 3C, for example, illustrate the structure where the side surface of the insulating layer 110 in the opening portion 141 has a linear shape in the cross-sectional view, one embodiment of the present invention is not limited thereto. In the cross-sectional view, the side surface of the insulating layer 110 in the opening portion 141 may have a curved shape, or the side surface may include both a region with a linear shape and a region with a curved shape.

The width W100, which is the channel width of the transistor 100, corresponds to the length of the semiconductor layer 108 in the direction perpendicular to the component of the length L100 along the bottom surface of the opening portion 141. Note that in this specification and the like, the length of the semiconductor layer 108 in the direction perpendicular to the component of the length L100 along the bottom surface of the opening portion 141 is referred to as the width of the semiconductor layer 108. That is, the width W100 can be the width of the semiconductor layer 108.

For example, in the case of the circular planar shape of the opening portion 141, when the width of the semiconductor layer 108 is small compared with the width D141, the difference between the length L100h and the width D141 can be small. Accordingly, the length L100h can be increased while an increase in width D141 is inhibited. Thus, the transistor 100 can have a minute size and good saturation characteristics.

In the example illustrated in FIG. 4B, an upper surface of the second region of the conductive layer 113, which overlaps with the opening portion 141, is referred to as an upper surface 126. The upper surface of the insulating layer 110 is referred to as an upper surface S110. The same may be applicable to subsequent drawings.

The upper surface 126 can be provided in the opening portion 141, for example. The upper surface 126 can be provided, for example, between the upper surface of the insulating layer 101 and the upper surface S110 in the cross-sectional view. The upper surface 126 may be provided between the upper surface S110 and the upper surface of the conductive layer 112a, or may be provided between the upper surface S110 and the upper surface of the conductive layer 112b in the cross-sectional view. The upper surface 126 can include a flat portion.

In the example illustrated in FIG. 4B, the thickness of the first region in the conductive layer 113, which is the region positioned outside the opening portion 141, is denoted by a thickness T113O, and the thickness of the second region in the conductive layer 113 is denoted by a thickness T113I. The thickness T113O can be the shortest distance between the formation surface of the conductive layer 113 outside the opening portion 141 (here, the upper surface of the insulating layer 106 over the conductive layer 112a or the conductive layer 112b) and the upper surface of the conductive layer 113 in the cross-sectional view. The thickness T113I can be the shortest distance between the upper surface 126 and the formation surface of the conductive layer 113 that is positioned in the opening portion 141 (here, the upper surface of the insulating layer 106 in the opening portion 141). In FIG. 4B, the thickness T113O and the thickness T113I are indicated by double-headed arrows.

The thickness T113O and the thickness T113I can be the same or substantially the same. The thickness T113O and the thickness T113I can be the same or substantially the same in the case where the conductive layer 113 favorably covers the opening portion 141, for example.

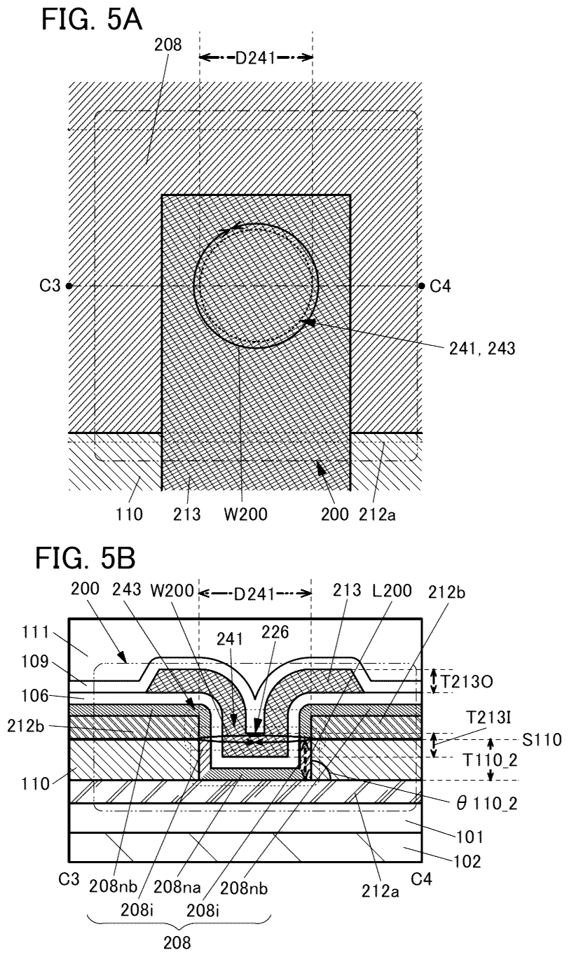

FIG. 5A is an enlarged view of the transistor 200 illustrated in FIG. 1A. FIG. 5B is a cross-sectional view of a cut plane along the dashed-dotted line C3-C4 in FIG. 5A. The channel length, the channel width, and the like of the transistor 200 are described with reference to FIG. 5A and FIG. 5B.

In FIG. 5A and FIG. 5B, the channel length of the transistor 200 is denoted by a length L200, its channel width is denoted by a width W200, the width of the opening portion 241 is denoted by a width D241, and the thickness of a region in the insulating layer 110 that overlaps with the conductive layer 212a is denoted by a thickness T110_2. In FIG. 5A and FIG. 5B, the length L200, the width W200, the width D241, and the thickness T110_2 are indicated by double-headed arrows. Similar representations are shown in other drawings. Here, the thickness T110_2 can be the shortest distance between the formation surface of the conductive layer 212a (the upper surface of the conductive layer 212a here) and the lower surface of the insulating layer 212b in the cross-sectional view, as illustrated in FIG. 5B.

FIG. 5B illustrates a region 208i, a region 208na, and a region 208nb as regions of the semiconductor layer 208. The region 208i is provided between the region 208na and the region 208nb.

At least part of the region 208i functions as the channel formation region of the transistor 200. The region 208na corresponds to a region of the semiconductor layer 208 that is in contact with the conductive layer 212a and the vicinity of the region. At least part of the region 208na functions as one of the source region and the drain region of the transistor 200. The region 208nb corresponds to a region of the semiconductor layer 208 that is in contact with the conductive layer 212b and the vicinity of the region. At least part of the region 208nb functions as the other of the source region and the drain region of the transistor 200. At least part of each of the region 208na and the region 208nb can be a region having lower electric resistance than at least part of the region 208i (hereinafter also referred to as a low-resistance region). For example, at least part of each of the region 208na and the region 208nb can be a region having a higher carrier concentration or a higher oxygen defect density than at least part of the region 208i. Although FIG. 5B illustrates an example where the boundary between the region 208i and the region 208nb is level with or substantially level with the boundary between the insulating layer 110 and the conductive layer 212b, these boundaries are not necessarily level with or substantially level with each other.

The length L200, which is the channel length of the transistor 200, corresponds to the length of the side surface of the insulating layer 110 in the opening portion 241 in the cross-sectional view. Accordingly, the transistor 200 can be referred to as a vertical-channel transistor or a VFET (Vertical Field Effect Transistor).

The length L200 depends on the thickness T110_2 of the insulating layer 110 and the angle θ110_2 formed by the side surface of the insulating layer 110 in the opening portion 241 and the formation surface of the insulating layer 110 (here, the upper surface of the conductive layer 212a). Thus, the length L200 can be a value smaller than the resolution limit of the light-exposure apparatus, so that a miniaturized transistor can be achieved. Specifically, it is possible to obtain a transistor with an extremely short channel length that could not be obtained with the use of a conventional light-exposure apparatus for mass production of flat panel displays (the minimum line width: approximately 2 μm or approximately 1.5 μm, for example). Moreover, a transistor with a channel length less than 10 nm can also be achieved without using an extremely expensive light-exposure apparatus used in the latest LSI technology.

The length L200 can be, for example, greater than or equal to 0.1 nm and less than 3 μm, greater than or equal to 0.1 nm and less than or equal to 2.5 μm, greater than or equal to 1 nm and less than or equal to 2 μm, greater than or equal to 1 nm and less than or equal to 1.5 μm, greater than or equal to 5 nm and less than or equal to 1.2 μm, greater than or equal to 5 nm and less than or equal to 1 μm, greater than or equal to 7 nm and less than or equal to 500 nm, greater than or equal to 7 nm and less than or equal to 300 nm, greater than or equal to 10 nm and less than or equal to 200 nm, greater than or equal to 10 nm and less than or equal to 100 nm, or greater than or equal to 10 nm and less than or equal to 50 nm.

The reduction in the length L200 can increase the on-state current of the transistor 200. With the use of the transistor 200, a circuit capable of high-speed operation can be manufactured. Furthermore, the area occupied by the circuit can be reduced. Thus, a small semiconductor device can be obtained. For example, when the semiconductor device of one embodiment of the present invention is used in a large display device or a high-resolution display device, signal delay in wirings can be reduced and display unevenness can be inhibited even when the number of wirings is increased. In addition, since the area occupied by the circuit can be reduced, the bezel of the display device can be narrowed.

By adjusting the thickness T110_2 of the insulating layer 110 and the angle θ110_2, the length L200 can be controlled.

The side surface of the insulating layer 110 in the opening portion 241, like the side surface thereof in the opening portion 141, preferably has a vertical shape, and is preferably perpendicular to the insulating layer 101, for example. Note that the side surface of the insulating layer 110 in the opening portion 241 may have a tapered shape. The side surface of the insulating layer 110 in the opening portion 241 in the cross-sectional view, like the side surface thereof in the opening portion 141, may have a linear shape or a curved shape, or the side surface may include both a region with a linear shape and a region with a curved shape.

It is preferable that the conductive layer 212b not be provided in the opening portion 241. Specifically, it is preferable that the conductive layer 212b not include a region in contact with the side surface of the insulating layer 110 in the opening portion 241. In the case where the conductive layer 212b is also provided inside the opening portion 241, the length L200 of the transistor 200 is shorter than the length of the side surface of the insulating layer 110 and the length L200 is difficult to control in some cases. Accordingly, it is preferable that the planar shape of the opening portion 243 be the same as the planar shape of the opening portion 241 or the opening portion 243 cover the opening portion 241 completely in the top view.

FIG. 1A to FIG. 2B, and FIG. 5A illustrate an example where the planar shape of the opening portion 241 is a circle. In this case, the width D241 corresponds to the diameter of the circle, and the width W200, which is the channel width of the transistor 200, is the length of the circumference of the circle. That is, the width W200 is π×D141. As described above, in the case where the planar shape of the opening portion 241 is a circle, the width W200 of the transistor can be small as compared with the case where the planar shape is any other shape.

The width D241 of the opening portion 241 sometimes varies in the depth direction. As the width D241 of the opening portion 241, for example, the average value of the following three diameters can be used: the diameter at the highest level of the insulating layer 110 in a cross-sectional view, the diameter at the lowest level of the insulating layer 110 in a cross-sectional view, and the diameter at the midpoint between these levels. For another example, any of the diameter at the highest level of the insulating layer 110 in a cross-sectional view, the diameter at the lowest level of the insulating layer 110 in a cross-sectional view, and the diameter at the midpoint between these levels can be used as the diameter of the opening portion 241.

In the case where the opening portion 241 is formed by a photolithography method, the width D241 of the opening portion 241 is larger than or equal to the resolution limit of a light-exposure apparatus. The width D241 can be, for example, greater than or equal to 200 nm and less than 5 μm, greater than or equal to 200 nm and less than or equal to 4.5 μm, greater than or equal to 300 nm and less than or equal to 4 μm, greater than or equal to 300 nm and less than or equal to 3.5 μm, greater than or equal to 400 nm and less than or equal to 3 μm, greater than or equal to 400 nm and less than or equal to 2.5 μm, greater than or equal to 500 nm and less than or equal to 2 μm, greater than or equal to 500 nm and less than or equal to 1.5 μm, or greater than or equal to 500 nm and less than or equal to 1 μm.

The width D241 is preferably small, and for example, is preferably smaller than or equal to the width D141 of the opening portion 141 provided with the transistor 100, which preferably has a long channel length, as illustrated in FIG. 1A. Thus, the transistor 200 can be a transistor having a minute size. Since the channel length of the transistor 100 depends on the width D141, when the width D141 is larger than the width D241, the transistor 200 can be a transistor having a minute size while the channel length of the transistor 100 is ensured.

For example, although FIG. 5B and the like illustrate an example where the semiconductor layer 208, the insulating layer 106, and the conductive layer 213 cover the opening portion 241 and the opening portion 243 in the transistor 200, one embodiment of the present invention is not limited thereto. A step may be formed between the insulating layer 110 and the conductive layer 212a, and the semiconductor layer 208, the insulating layer 106, and the conductive layer 213 may be provided along the step.

The transistor 100 with a long channel length and the transistor 200 with a short channel length can be formed over the insulating layer 101 while sharing some formation steps. For example, the transistor 100 is used as the transistor required to have good saturation characteristics and the transistor 200 is used as the transistor required to have a high on-state current, thereby providing a high-performance semiconductor device. As described above, the semiconductor device of one embodiment of the present invention has an excellent effect that the transistors with different channel lengths over the same substrate can be freely designed by the thickness of the insulating layer and patterning. Note that one of the transistor 100 and the transistor 200 is not necessarily provided in the semiconductor device of one embodiment of the present invention. For example, the transistor 100 can be referred to as the semiconductor device of one embodiment of the present invention; alternatively, the transistor 200 can be referred to as the semiconductor device of one embodiment of the present invention.

In the example illustrated in FIG. 5B, an upper surface of the fourth region of the conductive layer 213, which overlaps with the opening portion 241, is referred to as an upper surface 226. The upper surface 226 can be provided in the opening portion 241 or the opening portion 243, for example. The upper surface 226 can be provided, for example, between the upper surface of the insulating layer 101 and the upper surface S110 or between the upper surface S110 and the upper surface of the conductive layer 212b in the cross-sectional view. FIG. 5B illustrates an example in which, in the cross-sectional view, the upper surface 226 is provided between the upper surface S110 and the upper surface of the conductive layer 212b, that is, the upper surface 226 is provided in the opening portion 243. The upper surface 226 can include a flat portion.

In the example illustrated in FIG. 5B, the thickness of the third region in the conductive layer 213, which is the region positioned outside the opening portion 241, is denoted by a thickness T213O, and the thickness of the fourth region in the conductive layer 213 is denoted by a thickness T213I. The thickness T213O can be the shortest distance between the formation surface of the conductive layer 213 outside the opening portion 241 (here, the upper surface of the insulating layer 106 over the conductive layer 212b) and the upper surface of the conductive layer 213 in the cross-sectional view. The thickness T213I can be the shortest distance between the upper surface 226 and the formation surface of the conductive layer 213 that is positioned in the opening portion 241 (here, the upper surface of the insulating layer 106 in the opening portion 241) in the cross-sectional view. In FIG. 5B, the thickness T213O and the thickness T213I are indicated by double-headed arrows.

The thickness T213O and the thickness T213I can be the same or substantially the same. The thickness T213O and the thickness T213I can be the same or substantially the same in the case where the conductive layer 213 favorably covers the opening portion 241 and the opening portion 243, for example.

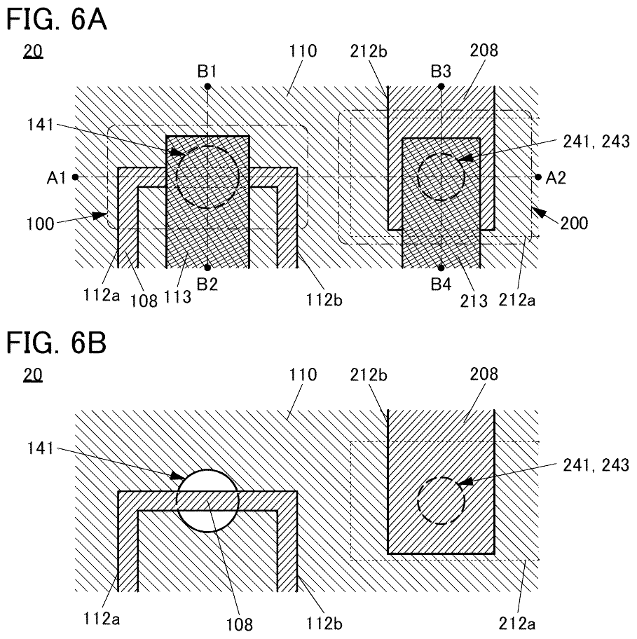

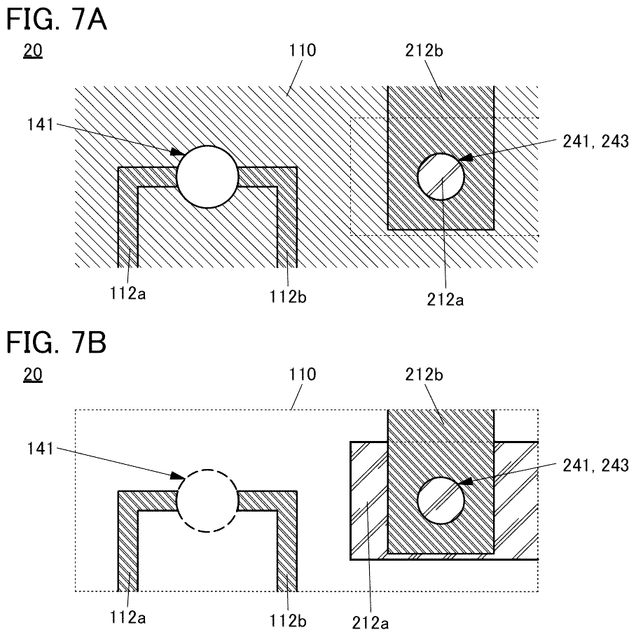

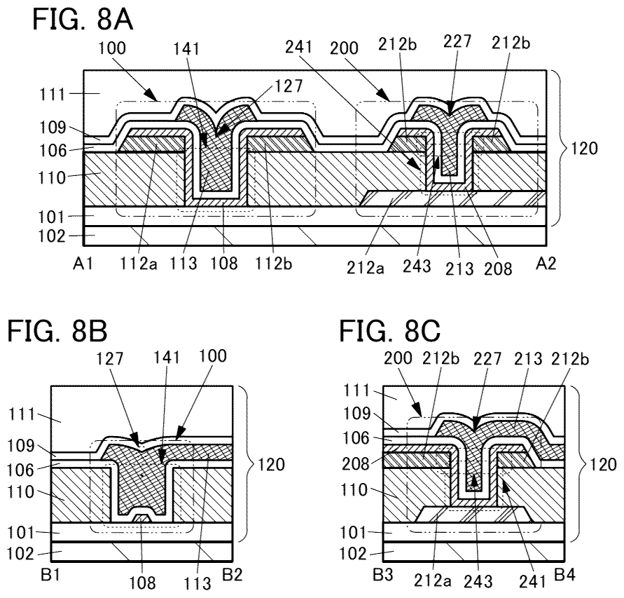

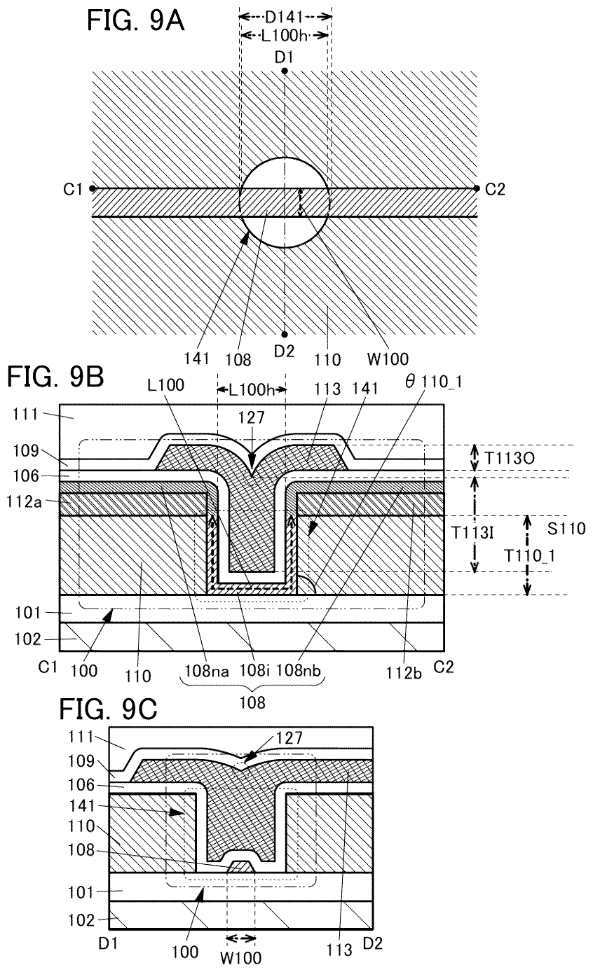

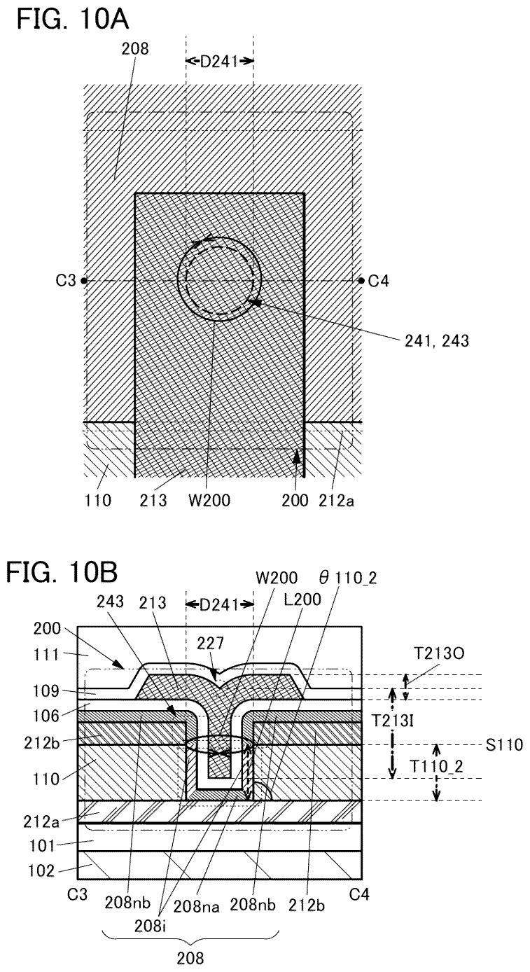

FIG. 6A, FIG. 6B, FIG. 7A, FIG. 7B, FIG. 8A, FIG. 8B, FIG. 8C, FIG. 9A, FIG. 9B, FIG. 9C, FIG. 10A, and FIG. 10B illustrate a modification example of the structure illustrated in FIG. 1A, FIG. 1B, FIG. 2A, FIG. 2B, FIG. 3A, FIG. 3B, FIG. 3C, FIG. 4A, FIG. 4B, FIG. 4C, FIG. 5A, and FIG. 5B. In the example illustrated in FIG. 6A to FIG. 10B, the conductive layer 113 is provided over the insulating layer 106 to be embedded in the opening portion 141. The conductive layer 113 can include the first region positioned outside the opening portion 141 and the second region overlapping with the opening portion 141. The conductive layer 113 is provided so that the second region includes a region overlapping with the semiconductor layer 108 with the insulating layer 106 therebetween.

The second region in the conductive layer 113 includes a portion 127. The portion 127 is the part of the upper surface of the second region in the conductive layer 113 that is the lowest in level. The portion 127 is also referred to as a minimum portion or a depressed portion. The level of the portion 127 can be based on, for example, the upper surface of the substrate 102 or the upper surface of the insulating layer 101 functioning as a base insulating layer.

The conductive layer 213 is provided over the insulating layer 106 to be embedded in the opening portion 241 and the opening portion 243. The conductive layer 213 can include a third region positioned outside the opening portion 241 and a fourth region overlapping with the opening portion 241. The third region can be a region positioned outside the opening portion 243, and the fourth region can be a region overlapping with the opening portion 243, for example.

The fourth region in the conductive layer 213 includes a portion 227. The portion 227 is the part of the upper surface of the fourth region in the conductive layer 213 that is the lowest in level. The portion 227 is also referred to as a minimum portion or a depressed portion. The level of the portion 127 can be based on, for example, the upper surface of the substrate 102 or the upper surface of the insulating layer 101 functioning as a base insulating layer.

As described above, the conductive layer 113 is provided to be embedded in the opening portion 141. The conductive layer 113 can include the first region positioned outside the opening portion 141 and the second region overlapping with the opening portion 141. The second region in the conductive layer 113 can include the portion 127. As described above, the portion 127 is the part of the upper surface of the second region in the conductive layer 113 that is the lowest in level.

The portion 127 is formed due to the opening portion 141. The portion 127 is formed in, for example, the center of the opening portion 141 or the vicinity thereof in the plan view. For example, in the case where the opening portion 141 has a circular planar shape, the portion 127 is sometimes formed in the center of the circle or in the vicinity thereof.

The portion 127 can be provided at a higher position than the upper surface S110 of the insulating layer 110. The portion 127 may be provided between the upper surface S110 and the upper surface of the conductive layer 112a, or may be provided between the upper surface S110 and the upper surface of the conductive layer 112b in the cross-sectional view. The portion 127 may be provided between the upper surface of the semiconductor layer 108 and the upper surface of the insulating layer 106 over the conductive layer 112a or the conductive layer 112b in the cross-sectional view. The portion 127 may be provided between the upper surface of the insulating layer 106 and the upper surface of the insulating layer 109 over the conductive layer 112a or the conductive layer 112b in the cross-sectional view. The portion 127 may be provided between the upper surface of the insulating layer 109 and the upper surface of the insulating layer 111 over the conductive layer 112a or the conductive layer 112b in the cross-sectional view. The portion 127 is provided between the upper surface of the insulating layer 101 and the upper surface S110 in the cross-sectional view in some cases. That is, the portion 127 may be positioned in the opening portion 141.

In FIG. 9B, the thickness T113I of the conductive layer 113 in the portion 127 and the thickness T113O of the conductive layer 113 in the first region are indicated by double-headed arrows. The thickness T113I can be larger than the thickness T113O. The thickness T113I can be the shortest distance between the portion 127 and the formation surface of the conductive layer 113 that is positioned in the opening portion 141 (here, the upper surface of the insulating layer 106 in the opening portion 141) in the cross-sectional view. The thickness T113O can be the shortest distance between the formation surface of the conductive layer 113 outside the opening portion 141 (here, the upper surface of the insulating layer 106 over the conductive layer 112a or the conductive layer 112b) and the upper surface of the conductive layer 113 in the cross-sectional view.

As described above, the width D241 is preferably small, and is preferably smaller than or equal to the width D141, for example. In the case where the width D141 is larger than the width D241, the portion 127 is provided at a lower position than the portion 227 in some cases. For example, the portion 127 is provided at a lower position than the portion 227 in some cases. The portion 127 is provided at a lower position than the portion 227 in some cases.

As described above, the conductive layer 213 is provided to be embedded in the opening portion 241 and the opening portion 243. The conductive layer 213 can include the third region positioned outside the opening portion 241 and the fourth region overlapping with the opening portion 241. The fourth region in the conductive layer 213 can include the portion 227. As described above, the portion 227 is the part of the upper surface of the fourth region in the conductive layer 213 that is the lowest in level.

Formation of the portion 227 is caused by the opening portion 241 and the opening portion 243. The portion 227 is formed in, for example, the center of the opening portion 241 or the vicinity thereof in the plan view. For example, in the case where the opening portion 241 has a circular planar shape, the portion 227 is sometimes formed in the center of the circle or in the vicinity thereof.

The portion 227 can be provided at a higher position than the upper surface S110 of the insulating layer 110. The portion 227 can be provided at a higher position than the upper surface S110, for example. Note that the portion 227 may be provided between the upper surface S110 and the upper surface of the conductive layer 212b in the cross-sectional view. That is, the portion 227 may be positioned in the opening portion 243. In this case, the conductive layer 213 can be expressed as including a region positioned in the opening portion 243 but not being embedded in the opening portion 243. However, the conductive layer 213 may be expressed as being provided to be embedded in the opening portion 243 even in the case where the portion 227 is positioned in the opening portion 243.

The portion 227 may be provided between the upper surface of the semiconductor layer 208 and the upper surface of the insulating layer 106 over the conductive layer 212b in the cross-sectional view. Alternatively, the portion 227 may be provided between the upper surface of the insulating layer 106 and the upper surface of the insulating layer 109 over the conductive layer 212b in the cross-sectional view. Alternatively, the portion 227 may be provided between the upper surface of the insulating layer 109 and the upper surface of the insulating layer 111 over the conductive layer 212b in the cross-sectional view. Note that the portion 227 is provided between the upper surface of the conductive layer 212a and the upper surface S110 in the cross-sectional view in some cases. That is, the portion 227 may be positioned in the opening portion 241.

In FIG. 10B, the thickness T213I of the conductive layer 213 in the portion 227 and the thickness T213O of the conductive layer 213 in the third region are indicated by double-headed arrows. The thickness T213I can be larger than the thickness T213O. The thickness T213I can be the shortest distance between the portion 227 and the formation surface of the conductive layer 213 in the opening portion 241 (here, the upper surface of the insulating layer 106 in the opening portion 241) in the cross-sectional view. The thickness T213O can be the shortest distance between the formation surface of the conductive layer 213 outside the opening portion 241 (here, the upper surface of the insulating layer 106 over the conductive layer 212b) and the upper surface of the conductive layer 213 in the cross-sectional view.

Next, the structures of the transistor 100 and the transistor 200 are described in detail.

There is no particular limitation on semiconductor materials used for the semiconductor layer 108 and the semiconductor layer 208. For example, a semiconductor of a single element or a compound semiconductor can be used. Examples of the single-element semiconductor include silicon and germanium. Examples of the compound semiconductor include gallium arsenide and silicon germanium. Other examples of the compound semiconductor include an organic semiconductor, a nitride semiconductor, and an oxide semiconductor (OS). These semiconductor materials may include an impurity as a dopant.

There is no particular limitation on the crystallinity of a semiconductor material used for each of the semiconductor layer 108 and the semiconductor layer 208, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case degradation of the characteristics of the transistor 100 and the transistor 200 can be inhibited.

For each of the semiconductor layer 108 and the semiconductor layer 208, silicon can be used. Examples of silicon include single crystal silicon, polycrystalline silicon, microcrystalline silicon, and amorphous silicon. An example of polycrystalline silicon is low-temperature polysilicon (LTPS). The transistor using amorphous silicon in the channel formation region can be formed over a large glass substrate, and can be manufactured at low cost. A transistor using polycrystalline silicon in the channel formation region has high field-effect mobility and enables high-speed operation. A transistor using microcrystalline silicon in the channel formation region has higher field-effect mobility and enables higher-speed operation than the transistor using amorphous silicon.

In this specification and the like, a transistor using single crystal silicon in a channel formation region is referred to as a Si transistor.

Each of the semiconductor layer 108 and the semiconductor layer 208 preferably includes a metal oxide exhibiting semiconductor characteristics (also referred to as an oxide semiconductor).

The band gaps of the metal oxides used for the semiconductor layer 108 and the semiconductor layer 208 are each preferably greater than or equal to 2.0 eV, further preferably greater than or equal to 2.5 eV.

A transistor including an oxide semiconductor (hereinafter referred to as an OS transistor) has much higher field-effect mobility than a transistor including amorphous silicon. In addition, the OS transistor has an extremely low off-state current, and charge accumulated in a capacitor that is connected in series to the transistor can retained for a long period. Furthermore, power consumption of the semiconductor device can be reduced when the OS transistor is used.

The insulating layer 110 preferably includes one or more inorganic insulating films. Examples of a material that can be used for the inorganic insulating film include an oxide, a nitride, an oxynitride, and a nitride oxide. Examples of the oxide include silicon oxide, aluminum oxide, magnesium oxide, gallium oxide, germanium oxide, yttrium oxide, zirconium oxide, lanthanum oxide, neodymium oxide, hafnium oxide, tantalum oxide, cerium oxide, gallium zinc oxide, and hafnium aluminate. Examples of the nitride include silicon nitride and aluminum nitride. Examples of the oxynitride include silicon oxynitride, aluminum oxynitride, gallium oxynitride, yttrium oxynitride, and hafnium oxynitride. Examples of the nitride oxide include silicon nitride oxide and aluminum nitride oxide. In particular, when silicon nitride is used for the insulating layer 110, the insulating layer 110 can be a layer that is less likely to transmit impurities, so that entry of impurities into the channel formations regions of the transistor 100 and the transistor 200 can be inhibited. Consequently, the transistor 100 and the transistor 200 can exhibit favorable electrical characteristics and have high reliability. Similarly, when silicon nitride is used also for the insulating layer 101, entry of impurities into the channel formation regions of the transistor 100 and the transistor 200 can be further suitably inhibited.

In this specification and the like, an oxynitride refers to a material that contains more oxygen than nitrogen in its composition, and a nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

At least part of the region of the insulating layer 101 that is in contact with the semiconductor layer 108 and the region of the insulating layer 101 that is in contact with the semiconductor layer 208 preferably has a function of capturing or fixing (also referred to as gettering) hydrogen. Thus, the hydrogen concentration in the channel formation regions of the semiconductor layer 108 and the semiconductor layer 208 can be reduced. Accordingly, oxygen vacancies (V_{O}) and V_{O}H in the channel formation regions can be reduced, so that the channel formation regions can be i-type or substantially i-type regions. Consequently, the transistor 100 and the transistor 200 can exhibit favorable electrical characteristics and have high reliability. Note that at least part of the region of the insulating layer 101 that is in contact with the semiconductor layer 108 and the region of the insulating layer 101 that is in contact with the semiconductor layer 208 may have a function of capturing or fixing hydrogen.

Examples of an insulator having a function of capturing or fixing hydrogen include an oxide containing magnesium and an oxide containing one or both of aluminum and hafnium. Examples of the oxide containing one or both of aluminum and hafnium include aluminum oxide, hafnium oxide, and an oxide containing aluminum and hafnium (hafnium aluminate). Silicon oxide may be added to these oxides. Examples of an insulator having a function of capturing or fixing hydrogen include an oxide containing magnesium and silicon, an oxide containing aluminum and silicon, and an oxide containing hafnium and silicon (hafnium silicate).

The oxide preferably includes an oxygen atom having a dangling bond. Such an oxide has a property of capturing or fixing hydrogen with the dangling bond in some cases. The oxide preferably have an amorphous structure, for example. This is because some oxygen atoms in an oxide having an amorphous structure have dangling bonds. The oxide metal oxide preferably has an amorphous structure, but a crystal region may be partly formed. Furthermore, the above oxide may have a crystal grain boundary. This is because, in an oxide having a crystal grain boundary, some oxygen atoms in the vicinity of the crystal grain boundary have dangling bonds in some cases.

The insulating layer 110 may be a layer containing oxygen. For example, a film from which oxygen is released by heating may be used for the insulating layer 110. When the insulating layer 110 releases oxygen by being heated during the manufacturing process of the transistor 100, oxygen can be supplied to the semiconductor layer 108 and the semiconductor layer 208. Supply of oxygen from the insulating layer 110 to the semiconductor layer 108 and the semiconductor layer 208, particularly to the channel formation regions, can repair oxygen vacancies (V_{O}) and reduce oxygen vacancies (V_{O}). Consequently, the transistor 100 and the transistor 200 can exhibit favorable electrical characteristics and have high reliability.

For example, the insulating layer 110 can be supplied with oxygen when heat treatment in an atmosphere containing oxygen or plasma treatment in an atmosphere containing oxygen is performed. Alternatively, an oxide film may be formed over the upper surface of the insulating layer 110 by a sputtering method in an atmosphere containing oxygen to supply oxygen. After that, the oxide film may be removed.

The use of a material having high electrical conductivity for the semiconductor layer 108 and the semiconductor layer 208 enables the transistor 100 and the transistor 200 to have a high on-state current. However, the use of a material having high electrical conductivity facilitates the formation of oxygen vacancies (V_{O}); the increased oxygen vacancies (V_{O}) in the channel formation region shift the threshold voltage of the transistor, which might increase the drain current flowing at a gate voltage of 0 V (hereinafter, also referred to as cut-off current). For example, a negative shift of the threshold voltage might increase the cut-off current in the case of an n-channel transistor. When the insulating layer 110 contains oxygen, oxygen is supplied to at least the region of the semiconductor layer 108 that is in contact with the insulating layer 110, i.e., the channel formation region of the transistor 100, so that the oxygen vacancies (V_{O}) in the channel formation region can be reduced. In addition, oxygen is supplied to at least the region of the semiconductor layer 208 that is in contact with the insulating layer 110, i.e., the channel formation region of the transistor 200, so that the oxygen vacancies (V_{O}) in the channel formation region can be reduced. Thus, shifts in the threshold voltages of the transistor 100 and the transistor 200 can be inhibited and the transistors can have both a low cut-off current and a high on-state current. Consequently, the semiconductor device 20 can have both low power consumption and high performance.

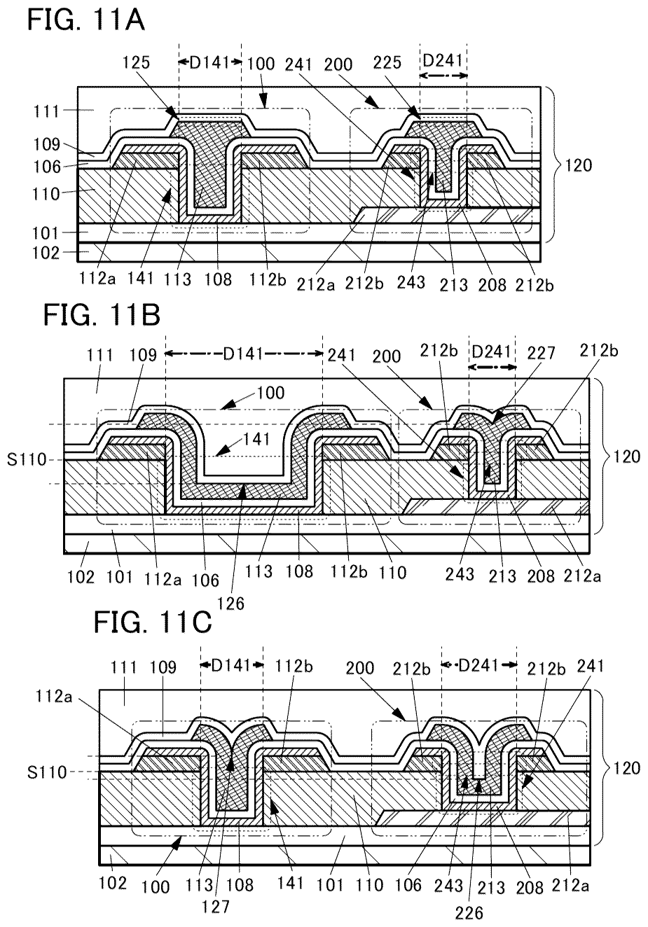

FIG. 11A illustrates an example where a flat portion 125 is included in the upper surface of the conductive layer 113, which is illustrated in FIG. 8A, in the second region thereof overlapping with the opening portion 141. Furthermore, a flat portion 225 is included in the upper surface of the conductive layer 213, which is illustrated in FIG. 8A, in the fourth region thereof overlapping with the opening portion 241 in the example illustrated in FIG. 11A. For example, the center of the opening portion 141 and the vicinity of the center can overlap with the flat portion 125 in the plan view. The center of the opening portion 241 and the vicinity of the center can overlap with the flat portion 225 in the plan view.

When the width D141 of the opening portion 141 is small compared with the thickness of the conductive layer 113, for example, it is possible that the portion 127 is not visibly recognized as that illustrated in FIG. 9B and is seen as the flat portion 125 even without planarization treatment on the upper surface of the conductive layer 113. When the width D241 of the opening portion 241 is small compared with the thickness of the conductive layer 213, for example, it is possible that the portion 227 is not seen as in FIG. 10B and is seen as the flat portion 225 even without planarization treatment on the upper surface of the conductive layer 213. The flat portion 125 can be formed at a higher position than the upper surface of the insulating layer 106 over the conductive layer 112a or the conductive layer 112b, for example. The flat portion 225 can be formed at a higher position than the upper surface of the insulating layer 106 over the conductive layer 212b, for example.

FIG. 11B illustrates an example in which the conductive layer 113 illustrated in FIG. 8A has a shape along the insulating layer 106 in the region overlapping with the opening portion 141 in the transistor 100. Specifically, the conductive layer 113 has a shape along the upper surface of the insulating layer 106 and the side surface of the insulating layer 106 in the opening portion 141 in the example illustrated in FIG. 11B.

In the transistor 100 illustrated in FIG. 11B, the first region positioned outside the opening portion 141 and the second region overlapping with the opening portion 141, which are the regions in the conductive layer 113, can have the same or substantially the same thickness. In this case, the upper surface 126 of the second region in the conductive layer 113 can be provided in the opening portion 141, for example. The upper surface 126 can be provided, for example, between the upper surface of the insulating layer 101 and the upper surface S110 in the cross-sectional view. The upper surface 126 may be provided between the upper surface S110 and the upper surface of the conductive layer 112a, or may be provided between the upper surface S110 and the upper surface of the conductive layer 112b in the cross-sectional view. Furthermore, the portion 227 included in the conductive layer 213 can be provided at a higher position than the upper surface 126. The upper surface 126 can include a flat portion. In the transistor 100 illustrated in FIG. 11B, the thickness of the second region in the conductive layer 113 can be the shortest distance between the formation surface of the conductive layer 113 (here, the upper surface of the insulating layer 106 in the opening portion 141) and the upper surface 126 in the cross-sectional view.

When the width D141 of the opening portion 141 is large compared with the thickness of the conductive layer 113, the conductive layer 113 has the structure illustrated in FIG. 11B in some cases. The large width D141 can increase the channel length of the transistor 100. Accordingly, the channel length of the transistor 100 illustrated in FIG. 11B can be longer than that of the transistor 100 illustrated in FIG. 8A, for example. Thus, the transistor 100 illustrated in FIG. 11B can have better saturation characteristics than the transistor 100 illustrated in FIG. 8A, for example. Meanwhile, the transistor 100 illustrated in FIG. 8A can have a higher on-state current than the transistor 100 illustrated in FIG. 11B, for example.

FIG. 11C illustrates an example in which the conductive layer 213 illustrated in FIG. 8A has a shape along the insulating layer 106 in the region overlapping with the opening portion 241 in the transistor 200. Specifically, the conductive layer 213 has a shape along the upper surface of the insulating layer 106 and the side surfaces of the insulating layer 106 in the opening portion 241 and the opening portion 243 in the example illustrated in FIG. 11C.

In the conductive layer 213 in the transistor 200 illustrated in FIG. 11C, the thickness of the third region, which is the region that is positioned outside the opening portion 241 can be equal to or substantially equal to the thickness of the fourth region that is the region overlapping with the opening portion 241. In this case, the upper surface 226 of the fourth region in the conductive layer 213 can be provided in the opening portion 241 or the opening portion 243, for example. The upper surface 226 can be provided, for example, between the upper surface of the insulating layer 101 and the upper surface S110 or between the upper surface S110 and the upper surface of the conductive layer 212b in the cross-sectional view. FIG. 11C illustrates an example in which, in the cross-sectional view, the upper surface 226 is provided between the upper surface of the insulating layer 101 and the upper surface S110, that is, the upper surface 226 is provided in the opening portion 241. Note that the portion 127 included in the conductive layer 113 can be provided at a higher position than the upper surface 226. The upper surface 226 can include a flat portion. In the transistor 200 illustrated in FIG. 11C, the thickness of the fourth region of the conductive layer 213 can be the shortest distance between the formation surface of the conductive layer 213 (here, the upper surface of the insulating layer 106 in the opening portion 241) and the upper surface 226 in the cross-sectional view.

When the width D241 of the opening portion 241 is large compared with the thickness of the conductive layer 213, the conductive layer 213 has the structure illustrated in FIG. 11C in some cases. The large width D241 enables the transistor 200 to be easily manufactured. Accordingly, the transistor 200 illustrated in FIG. 11C can be manufactured more easily than the transistor 200 illustrated in FIG. 8A, for example. Meanwhile, the transistor 200 illustrated in FIG. 8A can be a transistor having a size smaller than the transistor 200 illustrated in FIG. 11C, for example. Note that the width D241 in the case of the transistor 200 with the structure illustrated in FIG. 11C can be larger than or equal to the width D141 in the case of the transistor 100 with the structure illustrated in FIG. 11C, for example. Even in this case, the channel length of the transistor 200 can be shorter than the channel length of the transistor 100.

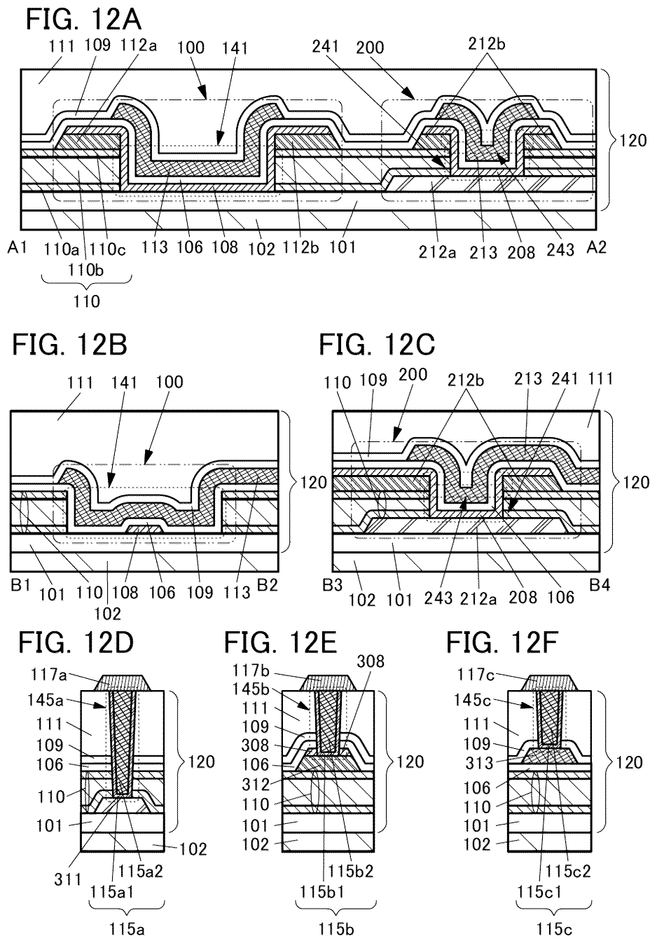

FIG. 12A, FIG. 12B, FIG. 12C, FIG. 12D, FIG. 12E, and FIG. 12F illustrate an example in which the insulating layer 110 illustrated in FIG. 3A, FIG. 3B, FIG. 3C, FIG. 3D, FIG. 3E, and FIG. 3F has a three-layer structure of an insulating layer 110a, an insulating layer 110b over the insulating layer 110a, and an insulating layer 110c over the insulating layer 110b. Note that the insulating layer 110 may have a stacked-layer structure of two layers or a stacked-layer structure of four or more layers. For the planar structure example, FIG. 1A to FIG. 2B can be referred to, for example.

In the structure example illustrated in FIG. 12A to FIG. 12C, the insulating layer 110a can include a region in contact with the upper surface of the insulating layer 101, a region in contact with the upper surface of the conductive layer 212a, a region in contact with the side surface of the conductive layer 212a, a region in contact with the side surface of the semiconductor layer 108, a region in contact with the side surface of the semiconductor layer 208, and a region in contact with the side surface of the insulating layer 106. The insulating layer 110b can include a region in contact with the side surface of the semiconductor layer 108, a region in contact with the side surface of the semiconductor layer 208, and a region in contact with the side surface of the insulating layer 106. The insulating layer 110c can include a region in contact with the lower surface of the conductive layer 112a, a region in contact with the lower surface of the conductive layer 112b, a region in contact with the lower surface of the conductive layer 212b, a region in contact with the side surface of the semiconductor layer 108, a region in contact with the side surface of the semiconductor layer 208, and a region in contact with a lower surface of the insulating layer 106. Although FIG. 12A to FIG. 12F illustrate an example where the insulating layer 110a is not planarized and the insulating layer 110b is planarized, the insulating layer 110a may be planarized and the insulating layer 110b is not necessarily planarized. In the case where the insulating layer 110b is not planarized, the insulating layer 110c may be planarized or is not necessarily planarized.

The insulating layer 110b preferably contains oxygen. The oxygen content in the insulating layer 110b is preferably higher than the oxygen content in the insulating layer 110a and the oxygen content in the insulating layer 110c, for example. The oxygen content per unit volume of the insulating layer 110b is preferably higher than the oxygen content per unit volume of the insulating layer 110a and the oxygen content per unit volume of the insulating layer 110c, for example. Any one or more of the oxide and oxynitride described above is preferably used for the insulating layer 110b. Specifically, one or both of silicon oxide and silicon oxynitride can be suitably used for the insulating layer 110b. Thus, at least the region of the semiconductor layer 108 that is in contact with the insulating layer 110b can function as the channel formation region of the transistor 100. Thus, at least the region of the semiconductor layer 208 that is in contact with the insulating layer 110b can function as the channel formation region of the transistor 200.

The content of an element such as oxygen can be measured by secondary ion mass spectrometry (SIMS) or X-ray photoelectron spectroscopy (XPS), for example. When the content percentage of a target element is high (e.g., higher than or equal to 0.5 atomic % or higher than or equal to 1 atomic %), XPS is suitable. By contrast, when the content percentage of a target element is low (e.g., lower than or equal to 0.5 atomic % or lower than or equal to 1 atomic %), SIMS is suitable. To compare the contents of elements, a combined analysis using both SIMS and XPS is further preferably performed. When the desorbed amount of the element is measured by thermal desorption spectroscopy (TDS), the content of the element can be compared between two layers, for example. Note that SIMS, XPS, a TDS method, or the like can also be used for the measurement of the content of an element other than oxygen.

It is further preferable that a film from which oxygen is released by heating be used as the insulating layer 110b. When the insulating layer 110b releases oxygen by being heated during the manufacturing process of the transistor 100 and the transistor 200, the oxygen can be supplied to the semiconductor layer 108 and the semiconductor layer 208. Supply of oxygen from the insulating layer 110b to the semiconductor layer 108 and the semiconductor layer 208, particularly to the channel formation region, can repair oxygen vacancies (V_{O}) and reduce oxygen vacancies (V_{O}). Consequently, the transistor 100 and the transistor 200 can exhibit favorable electrical characteristics and have high reliability.

For example, the insulating layer 110b can be supplied with oxygen when heat treatment in an atmosphere containing oxygen or plasma treatment in an atmosphere containing oxygen is performed. Alternatively, an oxide film may be formed over the upper surface of the insulating layer 110b by a sputtering method in an atmosphere containing oxygen to supply oxygen. After that, the oxide film may be removed.

The insulating layer 110b is preferably formed by a film formation method such as a sputtering method or a plasma-enhanced chemical vapor deposition (PECVD) method. In particular, by a sputtering method not using a hydrogen gas as a film formation gas, a film having an extremely low hydrogen content can be formed. Thus, supply of hydrogen to the channel formation regions can be inhibited and the electrical characteristics of the transistor 100 and the transistor 200 can be stabilized.

Preferably, a substance easily diffuses into the insulating layer 110b. In other words, the diffusion coefficient of a substance in the insulating layer 110b is preferably high. Preferably, oxygen in particular easily diffuses in the insulating layer 110b. That is, the diffusion coefficient of oxygen in the insulating layer 110b is preferably high. Oxygen contained in the insulating layer 110b diffuses in the insulating layer 110b. Accordingly, oxygen is supplied to the semiconductor layer 108 through the interface between the insulating layer 110b and the semiconductor layer 108, and oxygen is supplied to the semiconductor layer 208 through the interface between the insulating layer 110b and the semiconductor layer 208.

For calculation of the diffusion coefficient of oxygen, TDS can be used. Alternatively, SIMS may be used. Note that the diffusion coefficient of a substance other than oxygen can also be calculated by TDS or SIMS in some cases.

The use of a material having high electrical conductivity for the semiconductor layer 108 and the semiconductor layer 208 enables the transistors to have a high on-state current. However, the use of a material having high electrical conductivity facilitates the formation of oxygen vacancies (V_{O}); the increased oxygen vacancies (V_{O}) in the channel formation region shift the threshold voltage of the transistor, which might increase the drain current flowing at a gate voltage of 0 V (hereinafter, also referred to as cut-off current). For example, a negative shift of the threshold voltage might increase the cut-off current in the case of an n-channel transistor. The insulating layer 110b enables oxygen supply to at least the region of the semiconductor layer 108 that is in contact with the insulating layer 110b, i.e., the channel formation region of the transistor 100, reducing the oxygen vacancies (V_{O}) in the channel formation region. Similarly, the insulating layer 110b enables oxygen supply to at least the region of the semiconductor layer 208 that is in contact with the insulating layer 110b, i.e., the channel formation region of the transistor 200, reducing the oxygen vacancies (V_{O}) in the channel formation region. This inhibits the threshold voltage shift and allows the transistor 100 and the transistor 200 to have both a low cut-off current and a high on-state current. Consequently, the semiconductor device 20 can have both low power consumption and high performance.

It is preferable that the insulating layer 110a and the insulating layer 110c themselves release small amounts of impurities (e.g., hydrogen and water) and not easily transmit impurities. In this case, impurities contained in the insulating layer 110a and the insulating layer 110c can be inhibited from diffusing into the channel formation region of the transistor 100 and the channel formation region of the transistor 200. Consequently, the transistor 100 and the transistor 200 can exhibit favorable electrical characteristics and have high reliability.

A film that is less likely to transmit oxygen is preferably used as each of the insulating layer 110a and the insulating layer 110c; for example, a film that is less likely to transmit oxygen than the insulating layer 110b is preferably used. A film having a low oxygen diffusion coefficient is preferably used as each of the insulating layer 110a and the insulating layer 110c; for example, a film having a lower oxygen diffusion coefficient than the insulating layer 110b is preferably used. Thus, oxygen contained in the insulating layer 110b can be inhibited from diffusing into the conductive layer 212a through the insulating layer 110a and diffuses into the conductive layer 112a, the conductive layer 112b, and the conductive layer 212b through the insulating layer 110c. As a result, an increase in the electric resistance of the conductive layer 112a, the conductive layer 112b, the conductive layer 212a, and the conductive layer 212b can be suppressed. At the same time, oxygen contained in the insulating layer 110b can be inhibited from diffusing into the insulating layer 110a side and the insulating layer 110c side, which increases the amount of oxygen supplied to the channel formation region of the transistor 100 and the channel formation region of the transistor 200 from the insulating layer 110b and can reduce oxygen vacancies (V_{O}) and V_{O}H in the channel formation regions. Consequently, the transistor 100 and the transistor 200 can exhibit favorable electrical characteristics and have high reliability.

It is preferable that the insulating layer 110a and the insulating layer 110c each include nitrogen and be each formed using any one or more of the nitride and nitride oxide described above. For example, silicon nitride or silicon nitride oxide can be suitably used for each of the insulating layer 110a and the insulating layer 110c. Alternatively, any one or more of an oxide and an oxynitride may be used for one or both of the insulating layer 110a and the insulating layer 110c. For example, aluminum oxide can be suitably used for each of the insulating layer 110a and the insulating layer 110c.

The thickness of the insulating layer 110b can be, for example, greater than or equal to 5 nm and less than 3 μm, greater than or equal to 5 nm and less than or equal to 2.5 μm, greater than or equal to 5 nm and less than or equal to 2 μm, greater than or equal to 5 nm and less than or equal to 1.5 μm, greater than or equal to 7 nm and less than or equal to 1.2 μm, greater than or equal to 7 nm and less than or equal to 1 μm, greater than or equal to 7 nm and less than or equal to 500 nm, greater than or equal to 7 nm and less than or equal to 300 nm, greater than or equal to 10 nm and less than or equal to 200 nm, greater than or equal to 10 nm and less than or equal to 100 nm, greater than or equal to 10 nm and less than or equal to 50 nm, or greater than or equal to 10 nm and less than or equal to 30 nm. The thicknesses of the insulating layer 110a and the insulating layer 110c can each be less than or equal to the thickness of the insulating layer 110b. The thicknesses of the insulating layer 110a and the insulating layer 110c can each be, for example, greater than or equal to 3 nm and less than or equal to 1 μm, greater than or equal to 3 nm and less than or equal to 500 nm, greater than or equal to 3 nm and less than or equal to 300 nm, greater than or equal to 3 nm and less than or equal to 200 nm, greater than or equal to 5 nm and less than or equal to 100 nm, greater than or equal to 5 nm and less than or equal to 50 nm, greater than or equal to 5 nm and less than or equal to 30 nm, or greater than or equal to 5 nm and less than or equal to 20 nm.

The thickness of the insulating layer 110a can be the shortest distance between the formation surface of the insulating layer 110b (here, the upper surface of the insulating layer 101) and the lower surface of the insulating layer 110b in the cross-sectional view. The thickness of the insulating layer 110b can be the shortest distance between the formation surface of the insulating layer 110b (here, the upper surface of the insulating layer 110a) in a region not overlapping with the conductive layer 212a and the lower surface of the insulating layer 110c in the cross-sectional view. Note that the thickness of the insulating layer 110b may be the shortest distance between the formation surface of the insulating layer 110b and the lower surface of the insulating layer 110c in the region overlapping with the conductive layer 212a in the cross-sectional view. The thickness of the insulating layer 110c can be the shortest distance between the formation surface of the insulating layer 110c (the upper surface of the insulating layer 110b here) and the lower surface of the conductive layer 112a, the lower surface of the conductive layer 112b, or the lower surface of the conductive layer 212b in the cross-sectional view.

When the thicknesses of the insulating layer 110a and the insulating layer 110c are large, more impurities might be released from the insulating layer 110a and the insulating layer 110c, resulting in an increase in impurities diffusing into the channel formation region of the transistor 100 and the channel formation region of the transistor 200 in some cases. Meanwhile, when the thicknesses of the insulating layer 110a and the insulating layer 110c are small, oxygen contained in the insulating layer 110b diffuses into the conductive layer 212a side through the insulating layer 110a and into the conductive layer 112a, the conductive layer 112b, and the conductive layer 212b side through the insulating layer 110c in some cases. Accordingly, the amount of oxygen supplied to the channel formation region of the transistor 100 and the channel formation region of the transistor 200 might be reduced. When the thicknesses of the insulating layer 110a and the insulating layer 110c are each set within the above-described range, the oxygen vacancies (V_{O}) and V_{O}H in the channel formation regions can be reduced. Thus, the channel formation region of the transistor 100 and the channel formation region of the transistor 200 can each be an i-type or substantially i-type region. Furthermore, the conductive layer 112a, the conductive layer 112b, the conductive layer 212a, and the conductive layer 212b can be inhibited from being oxidized by oxygen contained in the insulating layer 110b and from having increased electric resistance. Consequently, the transistor 100 and the transistor 200 can exhibit favorable electrical characteristics and have high reliability.

As described above, when the insulating layer 110 has a stacked-layer structure of a plurality of layers as illustrated in FIG. 12A to FIG. 12F, the transistor included in the semiconductor device 20 can have favorable electrical characteristics and high reliability in some cases, as compared with the case where the insulating layer 110 is a single layer. On the other hand, when the insulating layer 110 is a single layer as illustrated in FIG. 3A to FIG. 3F, the number of manufacturing steps of the semiconductor device 20 can be smaller than that in the case where the insulating layer 110 has a stacked-layer structure of a plurality of layers. Accordingly, the manufacturing cost of the semiconductor device 20 can be reduced. The semiconductor device 20 can thus be an inexpensive semiconductor device.

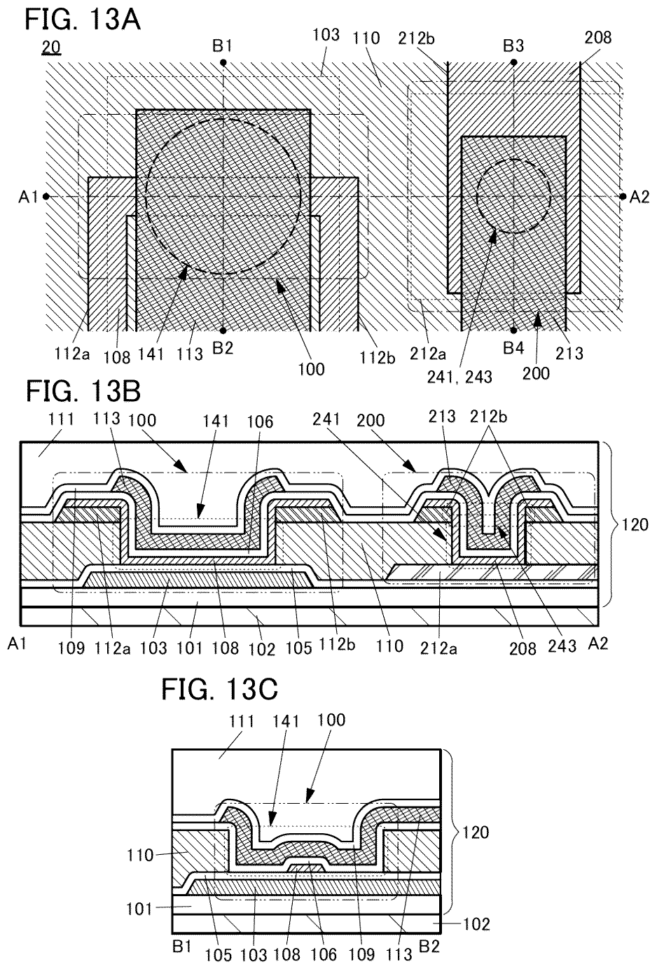

FIG. 13A illustrates an example in which the transistor 100 illustrated in FIG. 1A includes the conductive layer 103 and the insulating layer 105. FIG. 13B is a cross-sectional view of a cut plane along the dashed-dotted line A1-A2 in FIG. 13A. FIG. 13C is a cross-sectional view of a cut plane along the dashed-dotted line B1-B2 in FIG. 13A. Note that FIG. 3C can be referred to for a cut plane along the dashed-dotted line B3-B4.

In the semiconductor device 20 illustrated in FIG. 13A to FIG. 13C, the conductive layer 103 is provided over the insulating layer 101, and the insulating layer 105 is provided over the conductive layer 103 and the insulating layer 101. The insulating layer 105 has a shape along the upper surface and the side surface of the conductive layer 103 and the upper surface of the insulating layer 101. The insulating layer 105 can include a region in contact with the upper surface of the conductive layer 103, a region in contact with the side surface of the conductive layer 103, and a region in contact with the upper surface of the insulating layer 101.

The insulating layer 110, the semiconductor layer 108, and the conductive layer 212a are provided over the insulating layer 105. The opening portion 141 included in the insulating layer 110 reaches the insulating layer 105. The bottom surface of the semiconductor layer 108 can include a region in contact with the upper surface of the insulating layer 105. The insulating layer 106 can include a region in contact with the upper surface of the insulating layer 105.

The conductive layer 103 includes a region overlapping with the regions of the semiconductor layer 108, the insulating layer 106, and the conductive layer 113 that are positioned in the opening portion 141, with the insulating layer 105 therebetween. Thus, not only the conductive layer 113 but also the conductive layer 103 can function as a gate electrode, and not only the insulating layer 106 but also the insulating layer 105 can function as a gate insulating layer. Thus, the transistor 100 illustrated in FIG. 13A to FIG. 13C can be referred to as a dual-gate transistor in which gate electrodes are provided on both sides with a channel formation region interposed therebetween. The transistor 100 not including the conductive layer 103 as in FIG. 1A, FIG. 3A, FIG. 3B, and the like can be referred to as a single-gate transistor.

In the transistor 100 illustrated in FIG. 13A to FIG. 13C, the conductive layer 113 can be referred to as a first gate electrode, a front gate electrode, or simply a gate electrode, for example. The conductive layer 103 can be referred to as a second gate electrode, a back gate electrode, or simply a gate electrode. Note that the above name of the conductive layer 113 and the above name of the conductive layer 103 may be interchanged with each other. The insulating layer 106 can be referred to as a first gate insulating layer, and the insulating layer 105 can be referred to as a second gate insulating layer. Note that the insulating layer 105 may be referred to as the first gate insulating layer, and the insulating layer 106 may be referred to as the second gate insulating layer.

When the transistor 100 includes the conductive layer 103, the potential of the back channel side of the semiconductor layer 108 can be fixed and a shift of the threshold voltage can be inhibited. Here, a shift of the threshold voltage of the transistor 100 in the negative direction might increase the cut-off current. When the shift of the threshold voltage of the transistor 100 in the negative direction is inhibited, a transistor with a low cut-off current can be obtained. Note that characteristics with a low cut-off current are sometimes referred to as normally-off characteristics.

As described above, the transistor 100 that is a dual-gate transistor as illustrated in FIG. 13A to FIG. 13C can have more favorable electrical characteristics than the transistor 100 that is a single-gate transistor. On the other hand, for example, when the transistor 100 is a single-gate transistor as illustrated in FIG. 1A, FIG. 3A, and FIG. 3B, the number of manufacturing steps of the semiconductor device 20 can be smaller than that in the case where the transistor 100 is a dual-gate transistor. Accordingly, the manufacturing cost of the semiconductor device 20 can be reduced. The semiconductor device 20 can thus be an inexpensive semiconductor device.

For the conductive layer 103, a material similar to the material usable for the conductive layer 212a can be used, for example. For the insulating layer 105, a material similar to the material that can be used for the insulating layer 106 can be used, for example.

### Structure Example 2 of Semiconductor Device

A structure example of the semiconductor device 20 in which the conductive layer included in the transistor 100 and the conductive layer included in the transistor 200 are electrically connected to each other is described below.

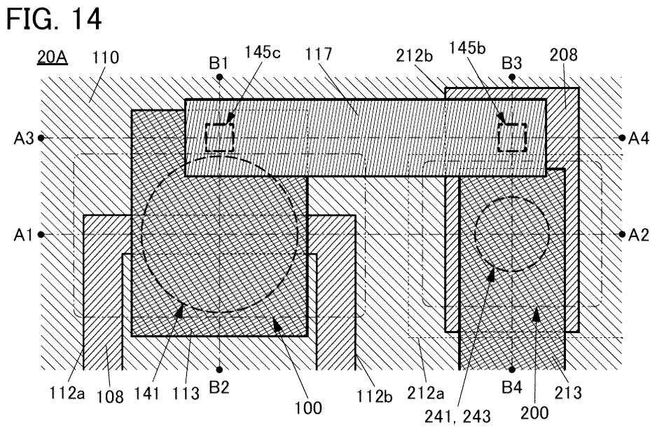

FIG. 14 is a plan view illustrating a structure example of the semiconductor device 20, in which the conductive layer 113 functioning as the gate electrode of the transistor 100 is electrically connected to the conductive layer 212b functioning as the other of the source electrode and the drain electrode of the transistor 200. The semiconductor device 20 illustrated in FIG. 14 is referred to as a semiconductor device 20A.

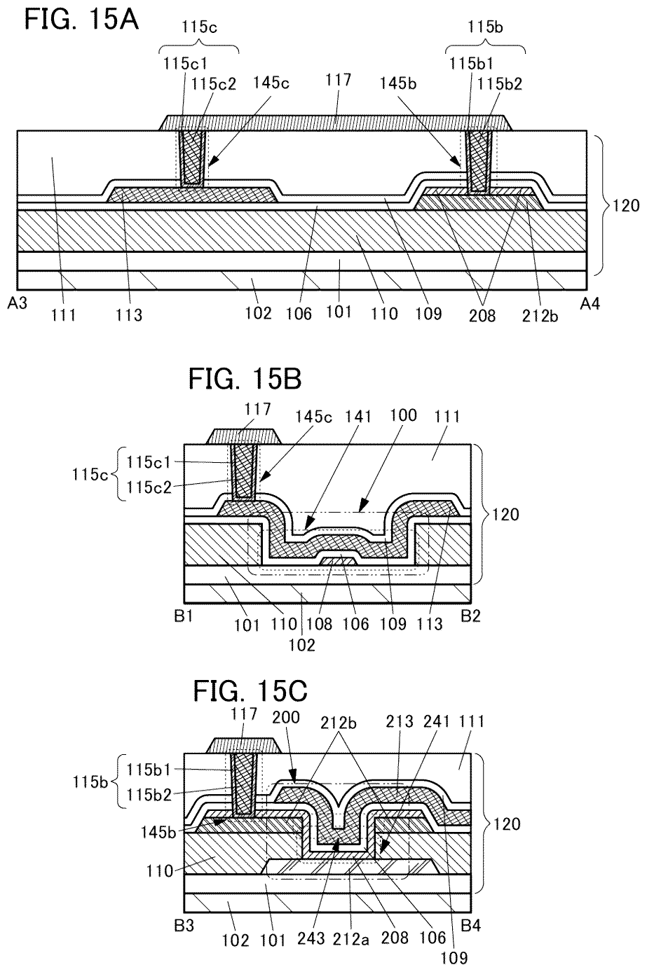

FIG. 15A is a cross-sectional view of a cut plane along the dashed-dotted line A3-A4 in FIG. 14. FIG. 15B is a cross-sectional view of a cut plane along the dashed-dotted line B1-B2 in FIG. 14. FIG. 15C is a cross-sectional view of a cut plane along the dashed-dotted line B3-B4 in FIG. 14. FIG. 3A can be referred to for a cross-sectional view of a cut plane along the dashed-dotted line A1-A2 in FIG. 14.

As illustrated in FIG. 14, FIG. 15A, and FIG. 15B, the insulating layer 109 and the insulating layer 111 include the opening portion 145c reaching the conductive layer 113, and the plug 115c is provided to be embedded in the opening portion 145c. FIG. 15A and FIG. 15B illustrate an example in which the plug 115c includes the conductive layer 115cl and the conductive layer 115c2.

As illustrated in FIG. 14, FIG. 15A, and FIG. 15C, the semiconductor layer 208, the insulating layer 106, the insulating layer 109, and the insulating layer 111 include the opening portion 145b reaching the conductive layer 212b, and the plug 115b is provided to be embedded in the opening portion 145b. FIG. 15A and FIG. 15C illustrate an example in which the plug 115b includes the conductive layer 115bl and the conductive layer 115b2.

Then, as illustrated in FIG. 15A, the plug 115b and the plug 115c are electrically connected to each other through the conductive layer 117 provided over the plug 115b, the plug 115c, and the insulating layer 111. Thus, the conductive layer 113 and the conductive layer 212b are electrically connected to each other through the plug 115b, the plug 115c, and the conductive layer 117.

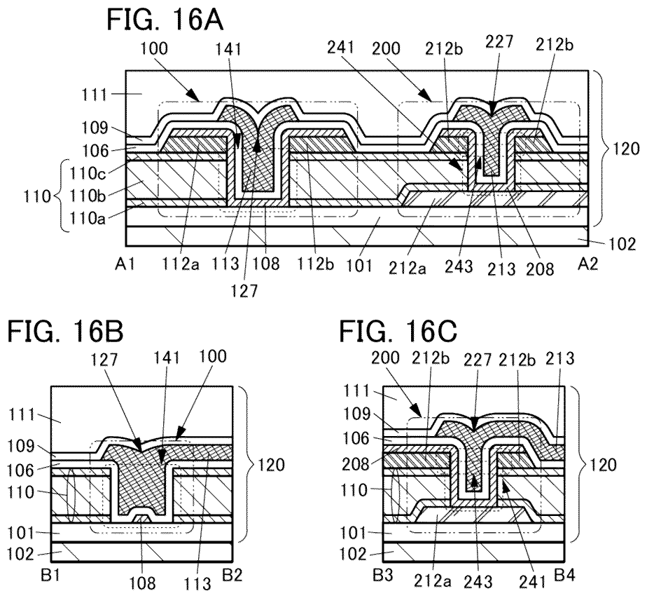

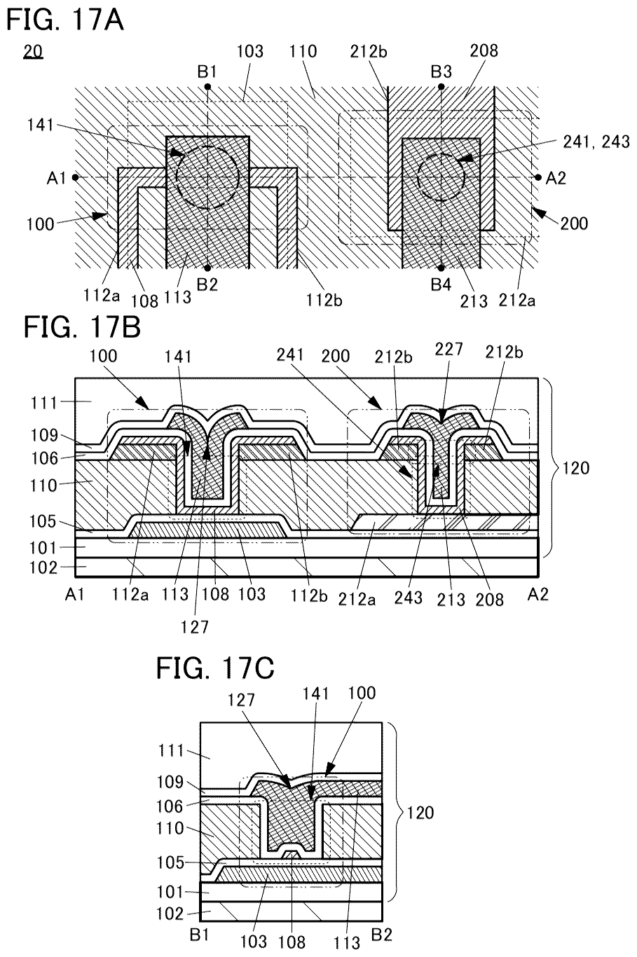

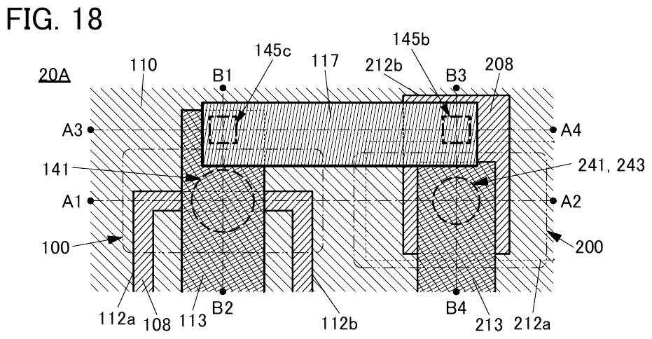

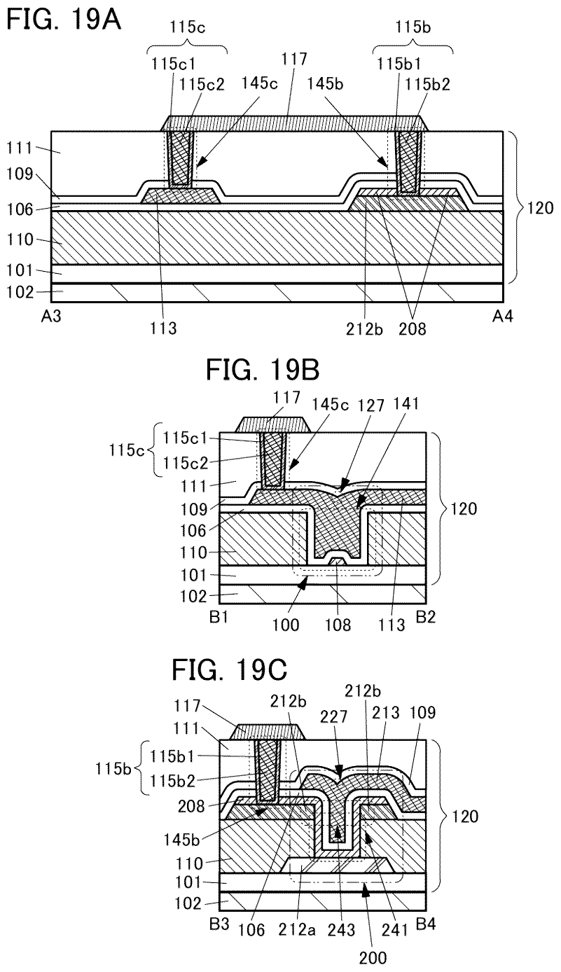

FIG. 16A, FIG. 16B, FIG. 16C, FIG. 17A, FIG. 17B, FIG. 17C, FIG. 18, FIG. 19A, FIG. 19B, and FIG. 19C illustrate modification examples of the structures illustrated in FIG. 12A, FIG. 12B, FIG. 12C, FIG. 13A, FIG. 13B, FIG. 13C, FIG. 14, FIG. 15A, FIG. 15B, and FIG. 15C. In each example, the conductive layer 113 is provided to be embedded in the opening portion 141 and the conductive layer 213 is provided to be embedded in the opening portion 241 and the opening portion 243.

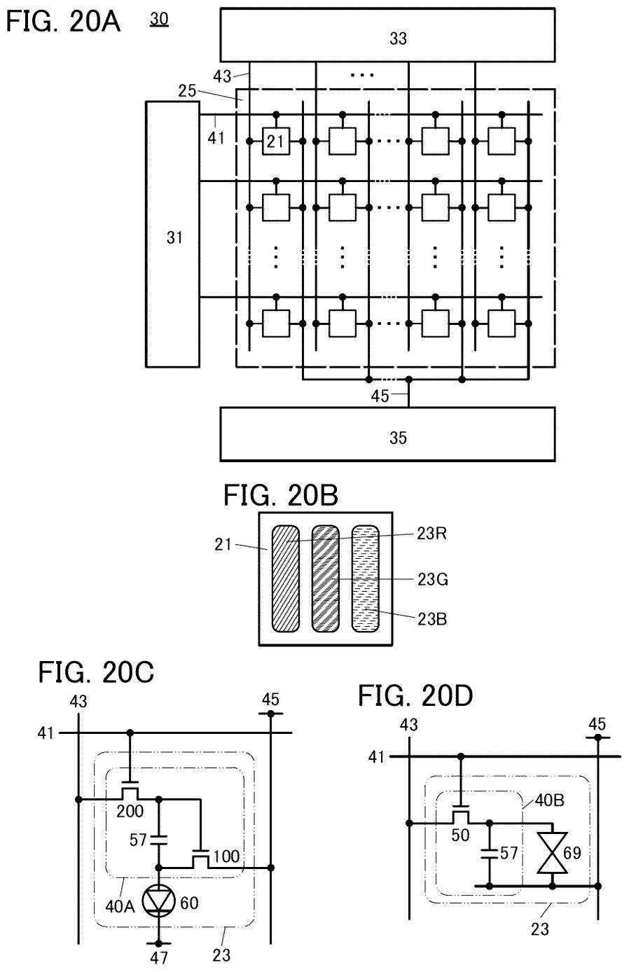

The semiconductor device 20 can be used for a display device, and for example, can be used for a pixel circuit included in the display device. FIG. 20A is a block diagram illustrating a structure example of a display device 30 that is the display device of one embodiment of the present invention. The display device 30 includes a display portion 25, a scan line driver circuit 31, a signal line driver circuit 33, and a power supply circuit 35. The display portion 25 includes a plurality of pixels 21 arranged in a matrix. Note that the power supply circuit 35 may be provided outside the display device 30.

The scan line driver circuit 31 is electrically connected to the pixels 21 through a wiring 41. The wiring 41 extends in the row direction of the matrix, for example.

The signal line driver circuit 33 is electrically connected to the pixels 21 through a wiring 43. The wiring 43 extends in the column direction of the matrix, for example.

The power supply circuit 35 is electrically connected to the pixels 21 through a wiring 45. For example, all the pixels 21 can be electrically connected to the power supply circuit 35 through the same wiring 45.

In FIG. 20A, the wiring 41 and the wiring 43 are indicated by straight lines; however, one straight line does not necessarily mean one wiring, and a plurality of wirings may be represented by one straight line in some cases. In the following block diagrams, circuit diagrams, and the like, a plurality of wirings may be represented by one straight line. As for wirings other than the wiring 41 and the wiring 43, a plurality of wirings may be represented by one straight line.

The pixel 21 includes a display element, and an image can be displayed on the display portion 25 with the display element. As the display element, a light-emitting element can be used, for example; specifically, an organic EL element can be used. As the display element, a liquid crystal element (also referred to as a liquid crystal device) may also be used.

The scan line driver circuit 31 has a function of selecting, row by row, the pixel 21 to which image data is to be written, for example. Specifically, the scan line driver circuit 31 can select the pixel 21 to which image data is to be written by outputting a signal to the wiring 41. Here, the scan line driver circuit 31 can select all the pixels 21 by, for example, outputting the signal to the wiring 41 in the first row, outputting the signal to the wiring 41 in the second row, and then outputting the signals to the wirings 41 from the third row to the last row sequentially. Thus, the signal output from the scan line driver circuit 31 to the wiring 41 is a scan signal, and the wiring 41 can be referred to as a scan line.

The signal line driver circuit 33 has a function of generating image data. The image data is supplied to the pixel 21 through the wiring 43. For example, image data can be written to all the pixels 21 included in a row selected by the scan line driver circuit 31. Here, the image data can be represented as a signal (image signal). Thus, the wiring 43 can be referred to as a signal line.

The power supply circuit 35 has a function of generating a power supply potential and supplying it to the wiring 45. The power supply circuit 35 has a function of generating, for example, a high power supply potential (hereinafter, also simply referred to as “high potential” or “VDD”) and supplying it to the wiring 45. The power supply circuit 35 may have a function of generating a low power supply potential (hereinafter, also simply referred to as “low potential” or “VSS”). The wiring 45 is supplied with a power supply potential, thus, the wiring 45 can be referred to as a power supply line.

FIG. 20B is a plan view illustrating a structure example of the pixel 21. The pixel 21 can include a plurality of subpixels 23. FIG. 20B illustrates an example in which the pixel 21 includes a subpixel 23R, a subpixel 23G, and a subpixel 23B. Here, in the case where the pixel 21 includes a light-emitting element as a display element, for example, the planar shape of the subpixel illustrated in FIG. 20B corresponds to the planar shape of a light-emitting region of the light-emitting element. Although FIG. 20B illustrates the subpixel 23R, the subpixel 23G, and the subpixel 23B that have the same or substantially the same aperture ratio (also referred to as size or size of a light-emitting region), one embodiment of the present invention is not limited thereto. The aperture ratio of each of the subpixel 23R, the subpixel 23G, and the subpixel 23B can be determined as appropriate. The subpixel 23R, the subpixel 23G, and the subpixel 23B may have different aperture ratios, or two or more of the subpixel 23R, the subpixel 23G, and the subpixel 23B may have the same or substantially the same aperture ratio.

In this specification and the like, for example, description common to the subpixel 23R, the subpixel 23G, and the subpixel 23B is sometimes made using the collective term “subpixel 23” without letters of the alphabet distinguishing them from each other. As for other components that are distinguished from each other using letters of the alphabet, matters common to the components are sometimes described using reference numerals without the letters of the alphabet.

The pixel 21 illustrated in FIG. 20B employs stripe arrangement as the arrangement method of the subpixels 23. Note that S-stripe arrangement, matrix arrangement, delta arrangement, Bayer arrangement, PenTile arrangement, or the like may be employed as the arrangement method of the subpixels 23.

The subpixel 23R, the subpixel 23G, and the subpixel 23B emit light of different colors. The subpixel 23R, the subpixel 23G, and the subpixel 23B are subpixels of three colors of red (R), green (G), and blue (B) or subpixels of three colors of yellow (Y), cyan (C), and magenta (M), for example. The pixel 21 may include four or more subpixels 23. For example, the pixel 21 may include subpixels of four colors of R, G, B, and white (W). In the display device 30, the display portion 25 can display a full-color image by including, in the pixel 21, the plurality of subpixels 23 emitting light of different colors. For example, the pixel 21 may include subpixels of R, G, B, and infrared (IR) light.

Note that a sensor may be provided in the display portion 25, for example, in the pixel 21. For example, the display portion 25 may have a function of a fingerprint sensor. For example, the display portion 25 may have a function of an optical or ultrasonic fingerprint sensor.

FIG. 20C is a circuit diagram illustrating a structure example of the subpixel 23. The subpixel 23 illustrated in FIG. 20C includes a pixel circuit 40A and a light-emitting element 60. As the light-emitting element 60, an OLED (Organic Light Emitting Diode) or a QLED (Quantum-dot Light Emitting Diode) is preferably used, for example. Examples of a light-emitting substance contained in the light-emitting element 60 include a substance emitting fluorescent light (a fluorescent material), a substance emitting phosphorescent light (a phosphorescent material), a substance exhibiting thermally activated delayed fluorescence (a thermally activated delayed fluorescent (TADF) material), and an inorganic compound (e.g., a quantum dot material). An LED such as a micro-LED (Light Emitting Diode) can also be used as the light-emitting element 60.

The pixel circuit 40A includes the transistor 200, the transistor 100, and a capacitor 57. That is, the pixel circuit 40A is a 2Tr (transistor) 1C (capacitor) pixel circuit.

In the pixel circuit 40A, one of a source and a drain of the transistor 200 is electrically connected to the wiring 43. The other of the source and the drain of the transistor 200 is electrically connected to a gate of the transistor 100. The gate of the transistor 100 is electrically connected to one electrode of the capacitor 57. A gate of the transistor 200 is electrically connected to the wiring 41.

One of the source and the drain of the transistor 100 is electrically connected to the wiring 45. The other of the source and the drain of the transistor 100 is electrically connected to the other electrode of the capacitor 57. The other electrode of the capacitor 57 is electrically connected to one electrode of the light-emitting element 60. The other electrode of the light-emitting element 60 is electrically connected to a wiring 47. Here, the one electrode of the light-emitting element 60 is also referred to as a pixel electrode. The wiring 47 can be shared by all the subpixels 23, for example. Therefore, the other electrode of the light-emitting element 60 can also be referred to as a common electrode.

As described above, the wiring 41 functions as a scan line, the wiring 43 functions as a signal line, and the wiring 45 functions as a power supply line. The wiring 47 functions as a power supply line; for example, when the wiring 45 is supplied with a high power supply potential, the wiring 47 is supplied with a low power supply potential. The wiring 47 can be electrically connected to the power supply circuit 35, for example.

The transistor 200 has a function of a switch and is also referred to as a selection transistor. The transistor 200 has a function of controlling electrical continuity and discontinuity between the wiring 43 and the gate of the transistor 100 on the basis of the potential of the wiring 41. When the transistor 200 is brought into an on state, image data is written to the pixel circuit 40A, and when the transistor 200 is brought into an off state, the written image data is retained. Here, the transistor 200 preferably has a high on-state current, in which case image data can be written to the pixel circuit 40A at high speed.

The transistor 100 has a function of controlling the amount of current flowing through the light-emitting element 60 and is also referred to as a driving transistor. The capacitor 57 has a function of retaining a gate potential of the transistor 100. The emission luminance of the light-emitting element 60 is controlled in accordance with a potential that corresponds to image data and is supplied to the gate of the transistor 100. Specifically, in the case where the wiring 45 is supplied with a high power supply potential and the wiring 47 is supplied with a low power supply potential, the amount of current flowing from the wiring 45 to the wiring 47 is controlled in accordance with the gate potential of the transistor 100. Thus, the emission luminance of the light-emitting element 60 is controlled. Here, the transistor 100 preferably has good saturation characteristics, in which case current flowing through the light-emitting element 60 can be stabilized and the emission luminance of the light-emitting element 60 can be stabilized. For example, in the case where a still image is displayed on the display portion 25, generation of a time-related variation in current flowing through the light-emitting element 60 can be inhibited, and generation of a time-related variation in emission luminance of the light-emitting element 60 can be inhibited.

As the transistor 100 and the transistor 200 illustrated in FIG. 20C, the transistor 100 and the transistor 200 illustrated in FIG. 3A, FIG. 8A, FIG. 14, FIG. 15B, FIG. 15C, FIG. 18, FIG. 19B, FIG. 19C, and the like can be used. As described above, the transistor 100 has a longer channel length and better saturation characteristics than the transistor 200. The transistor 100 can be a transistor having a minute size. Accordingly, when the transistor 100 is used as the driving transistor, the saturation characteristics of the driving transistor can be improved while the pixel 21 provided with the subpixels 23 is miniaturized. Thus, the current flowing through the light-emitting element 60 can be stable, and the emission luminance of the light-emitting element 60 can be stable.

The transistor 200 can have a shorter channel length and a larger on-state current than the transistor 100. In addition, the transistor 200 can be a transistor having a minute size. Accordingly, when the transistor 200 is used as the selection transistor, the on-state current of the selection transistor can be increased while the pixel 21 provided with the subpixels 23 is miniaturized. Accordingly, image data can be written to the pixel 21 at high speed while the pixel 21 is miniaturized.

Thus, when the semiconductor device 20 is used for a display device, the display device can achieve high resolution, high reliability, and high-speed driving. The semiconductor device 20A is regarded as being used for the display device 30 in the case where the display device 30 includes the pixel circuit 40A and the transistor 100 and the transistor 200 illustrated in FIG. 3A, FIG. 8A, FIG. 14, FIG. 15B, FIG. 15C, FIG. 18, FIG. 19B, and FIG. 19C are used as the transistor 100 and the transistor 200 provided in the pixel circuit 40A.

Here, when the width D141 illustrated in FIG. 4B is larger than the thickness T110_2 illustrated in FIG. 5B, for example, the difference between the channel length of the transistor 100 and the channel length of the transistor 200 can be increased. This is preferable because the saturation characteristics of the transistor 100 can be further improved and the on-state current of the transistor 200 can be further increased in some cases.

FIG. 20D is a circuit diagram illustrating a structure example of the subpixel 23. The subpixel 23 illustrated in FIG. 20D includes a pixel circuit 40B and a liquid crystal element 69.

The pixel circuit 40B includes a transistor 50 and the capacitor 57. That is, the pixel circuit 40B is a 1Tr1C-type pixel circuit.

In the pixel circuit 40B, one of the source and the drain of the transistor 50 is electrically connected to the wiring 43. The other of the source and the drain of the transistor 50 is electrically connected to one electrode of the capacitor 57. The one electrode of the capacitor 57 is electrically connected to one electrode of the liquid crystal element 69. A gate of the transistor 50 is electrically connected to the wiring 41. The other electrode of the capacitor 57 and the other electrode of the liquid crystal element 69 are electrically connected to the wiring 45. Here, the one electrode of the liquid crystal element 69 is also referred to as a pixel electrode. The other electrode of the liquid crystal element 69 may be referred to as a common electrode. In the pixel circuit 40B, a ground potential can be supplied to the wiring 45, for example.

In the pixel circuit 40B, the transistor 50 has a function of a switch and has a function of controlling electrical continuity and discontinuity between the wiring 43 and the one electrode of the liquid crystal element 69 on the basis of the potential of the wiring 41. When the transistor 50 is brought into an on state, image data is written to the pixel circuit 40B, and when the transistor 50 is brought int an off state, the written image data is retained.

The capacitor 57 has a function of retaining the potential of the one electrode of the liquid crystal element 69. The alignment state of the liquid crystal element 69 is controlled in accordance with a potential that corresponds to image data and is supplied to the one electrode of the liquid crystal element 69.

Examples of a mode of the liquid crystal element 69 include a TN (twisted nematic) mode, an STN (super twisted nematic) mode, a VA (vertical alignment) mode, an ASM (axially symmetric aligned micro-cell) mode, an OCB (optically compensated birefringence) mode, an FLC (ferroelectric liquid crystal) mode, an AFLC (antiferroelectric liquid crystal) mode, an MVA (multi-domain vertical alignment) mode, a PVA (patterned vertical alignment) mode, an IPS (in-plane switching) mode, an FFS (fringe field switching) mode, and a TBA (transverse bend alignment) mode. Other examples include an ECB (Electrically Controlled Birefringence) mode, a PDLC (Polymer Dispersed Liquid Crystal) mode, a PNLC (Polymer Network Liquid Crystal) mode, a guest-host mode, and the like. However, the mode is not limited thereto, and a variety of modes can be used.

The transistor 50 can have a structure similar to that of the transistor 100 or the transistor 200 described in this specification and the like. When the transistor 50 has a structure similar to that of the transistor 100, the transistor 50 can have a long channel length as compared with the case where the transistor 50 has a structure similar to that of the transistor 200, for example; thus, the off-state current of the transistor 50 can be reduced. Accordingly, image data can be retained in the subpixel 23 for a long time. Meanwhile, when the transistor 50 has a structure similar to that of the transistor 200, the transistor 50 can have a short channel length as compared with the case where the transistor 50 has a structure similar to that of the transistor 100; thus, the on-state current of the transistor 50 can be increased. Accordingly, image data can be written to the subpixel 23 at high speed.

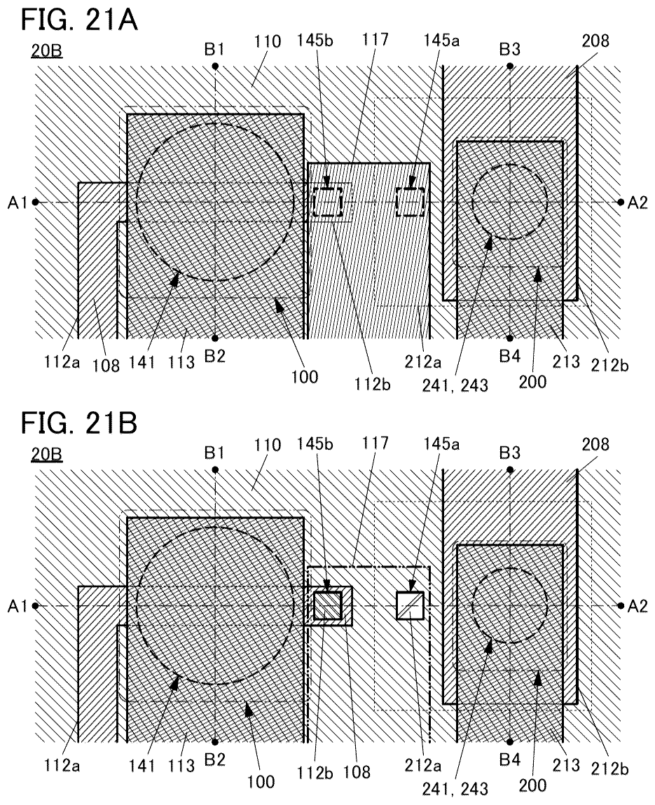

FIG. 21A is a plan view illustrating a structure example of the semiconductor device 20, in which the conductive layer 112b functioning as the other of the source electrode and the drain electrode of the transistor 100 is electrically connected to the conductive layer 212a functioning as one of the source electrode and the drain electrode of the transistor 200. Specifically, the conductive layer 112b and the conductive layer 212a are electrically connected to each other through the conductive layer 117 in the example illustrated in FIG. 21A. FIG. 21B is a plan view illustrating the conductive layer 117 illustrated in FIG. 21A with a dashed double-dotted line. The semiconductor device 20 illustrated in FIG. 21A and FIG. 21B is referred to as a semiconductor device 20B.

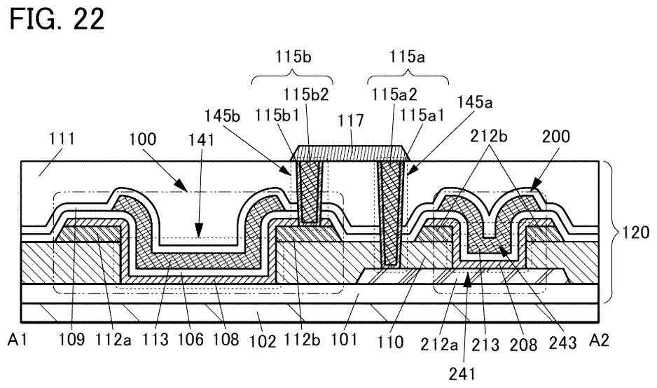

FIG. 22 is a cross-sectional view of a cut plane along the dashed-dotted line A1-A2 in FIG. 21A and FIG. 21B. Note that FIG. 3B can be referred to for a cross-sectional view of a cut plane along the dashed-dotted line B1-B2 in FIG. 21A and FIG. 21B, and FIG. 3C can be referred to for a cross-sectional view of a cut plane along the dashed-dotted line B3-B4.

As illustrated in FIG. 21A, FIG. 21B, and FIG. 22, the semiconductor layer 108, the insulating layer 106, the insulating layer 109, and the insulating layer 111 include the opening portion 145b reaching the conductive layer 112b, and the plug 115b is provided to be embedded in the opening portion 145b. FIG. 22 illustrates an example in which the plug 115b includes the conductive layer 115bl and the conductive layer 115b2.

As illustrated in FIG. 21A, FIG. 21B, and FIG. 22, the insulating layer 110, the insulating layer 106, the insulating layer 109, and the insulating layer 111 include the opening portion 145a reaching the conductive layer 212a, and the plug 115a is provided to be embedded in the opening portion 145a. FIG. 22 illustrates an example in which the plug 115a includes the conductive layer 115al and the conductive layer 115a2.

Then, as illustrated in FIG. 22, the plug 115a and the plug 115b are electrically connected to each other through the conductive layer 117 provided over the plug 115a, the plug 115b, and the insulating layer 111. Thus, the conductive layer 112b and the conductive layer 212a are electrically connected to each other through the plug 115a, the plug 115b, and the conductive layer 117.

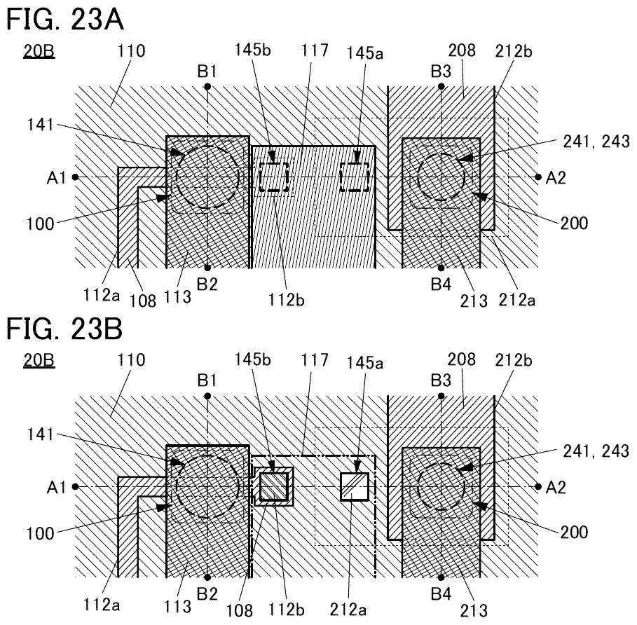

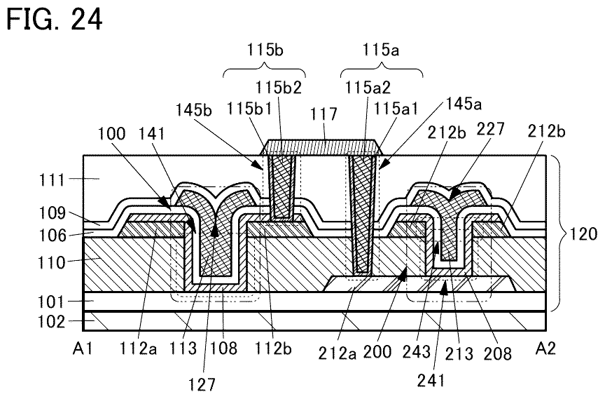

FIG. 23A, FIG. 23B, and FIG. 24 illustrate a modification example of the structure illustrated in FIG. 21A, FIG. 21B, and FIG. 22. In the example, the conductive layer 113 is provided to be embedded in the opening portion 141 and the conductive layer 213 is provided to be embedded in the opening portion 241 and the opening portion 243.

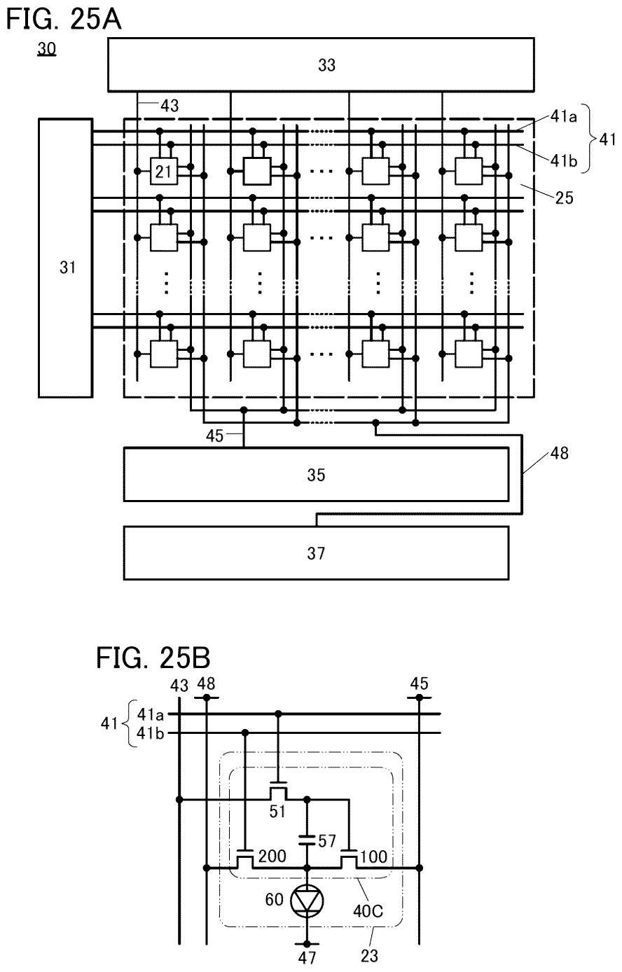

FIG. 25A is a block diagram illustrating a structure example of the display device 30 and is a modification example of the display device 30 illustrated in FIG. 20A. The display device 30 illustrated in FIG. 25A is different from the display device 30 illustrated in FIG. 20A in including a wiring 41a and a wiring 41b as the wiring 41 and including a reference potential generation circuit 37.

The reference potential generation circuit 37 is electrically connected to the pixels 21 through a wiring 48. For example, all the pixels 21 can be electrically connected to the reference potential generation circuit 37 through the same wiring 48. The reference potential generation circuit 37 has a function of generating a reference potential for correcting a variation in the gate-source voltage among the driving transistors and supplying it to the wiring 48, for example. Since the potential of the wiring 48 is a reference potential, the wiring 48 can be referred to as a reference potential line. Note that the reference potential generation circuit 37 may also be referred to as a power supply circuit. The power supply circuit 35 and the reference potential generation circuit 37 may be combined to be one circuit. For example, the reference potential generation circuit 37 may be included in the power supply circuit 35.

FIG. 25B is a circuit diagram illustrating a structure example of the subpixel 23 included in the pixel 21 illustrated in FIG. 25A. The subpixel 23 illustrated in FIG. 25B includes a pixel circuit 40C and the light-emitting element 60.

The pixel circuit 40C includes a transistor 51, the transistor 100, the transistor 200, and the capacitor 57. That is, the pixel circuit 40C is a 3Tr (transistor) 1C (capacitor) pixel circuit.

In the pixel circuit 40C, one of a source and a drain of the transistor 51 is electrically connected to the wiring 43. The other of the source and the drain of the transistor 51 is electrically connected to the gate of the transistor 100. The gate of the transistor 100 is electrically connected to one electrode of the capacitor 57. A gate of the transistor 51 is electrically connected to the wiring 41a.

One of the source and the drain of the transistor 100 is electrically connected to the wiring 45. One of a source and a drain of the transistor 200 is electrically connected to the wiring 48. The other of the source and the drain of the transistor 100 is electrically connected to the other of the source and the drain of the transistor 200. The other of the source and the drain of the transistor 200 is electrically connected to the other electrode of the capacitor 57. The other electrode of the capacitor 57 is electrically connected to one electrode of the light-emitting element 60. The gate of the transistor 200 is electrically connected to the wiring 41b. The other electrode of the light-emitting element 60 is electrically connected to a wiring 47.

In the pixel circuit 40C, the transistor 51 has a function of a selection transistor. The transistor 100 has a function of a driving transistor. The transistor 200 has a function of a switch and has a function of controlling electrical continuity and discontinuity between the wiring 48 and the one electrode of the light-emitting element 60 on the basis of the potential of the wiring 41b. A reference potential is supplied to the wiring 48, for example. The reference potential of the wiring 48 supplied through the transistor 200 can inhibit variation in gate-source voltage of the transistors 100 provided in the plurality of subpixels 23.

The wiring 48 can function as a monitor line for outputting current flowing through the transistor 100 or current flowing through the light-emitting element 60 to the outside of the subpixel 23. Current output to the wiring 48 can be converted into a potential by a source follower circuit, for example. Alternatively, the current can be converted into a digital signal by an A/D converter, for example.

The transistor 100 and the transistor 200 illustrated in FIG. 3B, FIG. 3C, FIG. 8B, FIG. 8C, FIG. 21A, FIG. 21B, FIG. 22, FIG. 23A, FIG. 23B, and FIG. 24 can be used as the transistor 100 and the transistor 200 illustrated in FIG. 25B. When the transistor 100 is used as the driving transistor, the saturation characteristics of the driving transistor can be improved while the subpixel 23 is miniaturized. When the transistor 200 is used as a transistor electrically connected to the wiring 48 functioning as a reference potential line, a reference potential can be supplied to the pixel circuit 40C at high speed while the subpixel 23 is miniaturized. Note that the transistor 51 can have a structure similar to that of the transistor 200, for example.

Although the planar shape of the opening portion 145 is rectangular in FIG. 14, FIG. 18, FIG. 21A, FIG. 21B, FIG. 23A, and FIG. 23B, one embodiment of the present invention is not limited thereto; the planar shape can be a shape similar to the shape that the opening portion 141 can have, a shape similar to the shape that the opening portion 241 can have, or a shape similar to the shape that the opening portion 243 can have.

### Structure Example 3 of Semiconductor Device

Structure examples of the transistor 100 and the transistor 200 that are different from the structures illustrated in FIG. 1A, FIG. 3A, FIG. 6A, FIG. 8A, and the like are described below.

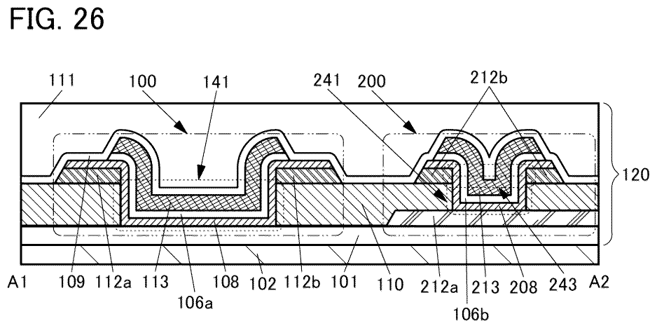

FIG. 26 is a cross-sectional view illustrating an example in which the insulating layer 106 illustrated in FIG. 3A is processed into an island shape, for example.

FIG. 26 illustrates an example in which the transistor 100 includes an insulating layer 106a as the insulating layer 106 and the transistor 200 includes an insulating layer 106b as the insulating layer 106. In the example illustrated in FIG. 26, an end portion of an upper surface of the insulating layer 106a is aligned or substantially aligned with an end portion of a lower surface of the conductive layer 113, and an end portion an upper surface of the insulating layer 106b is aligned or substantially aligned with an end portion of a lower surface of the conductive layer 213. For example, when the insulating layer 106 illustrated in FIG. 3A is processed with the same mask pattern as the conductive layer 113 and the conductive layer 213, the gate insulating layer of the transistor 100 and the gate insulating layer of the transistor 200 can have a structure illustrated in FIG. 26. Note that the end portion of the upper surface of the insulating layer 106a is not necessarily aligned or substantially aligned with the end portion of the lower surface of the conductive layer 113, and the end portion of the upper surface of the insulating layer 106b is not necessarily aligned or substantially aligned with the end portion of the lower surface of the conductive layer 213. For example, the end portion of the upper surface of the insulating layer 106a may be positioned outside the end portion of the lower surface of the conductive layer 113, and the end portion of the upper surface of the insulating layer 106b may be positioned outside the end portion of the lower surface of the conductive layer 213.

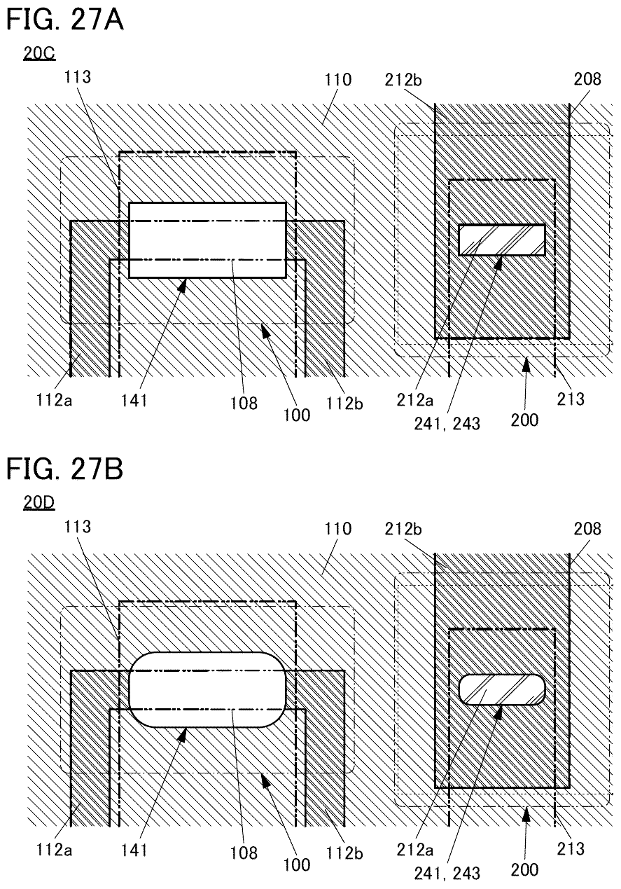

FIG. 27A is a plan view illustrating an example in which the planar shapes of the opening portion 141, the opening portion 241, and the opening portion 243 illustrated in FIG. 1A are rectangular. FIG. 27B is a plan view illustrating an example in which the planar shapes of the opening portion 141, the opening portion 241, and the opening portion 243 illustrated in FIG. 1A are rectangular with rounded corners. In FIG. 27A and FIG. 27B, the semiconductor layer 108, the conductive layer 113, and the conductive layer 213 are indicated by dashed double-dotted lines. The semiconductor layer 208 is shown without being hatched. Here, the semiconductor device 20 illustrated in FIG. 27A is referred to as a semiconductor device 20C, and the semiconductor device 20 illustrated in FIG. 27B is referred to as a semiconductor device 20D.

For example, when the planar shapes of the opening portion 141, the opening portion 241, and the opening portion 243 are circular as illustrated in FIG. 1A, the processing accuracy at the time of forming the opening portion 141, the opening portion 241, and the opening portion 243 can be increased. When the planar shapes of the opening portion 141, the opening portion 241, and the opening portion 243 are rectangular, rectangular with rounded corners, or the like, the opening portion 141, the opening portion 241, and the opening portion 243 each have a side surface with a flat or substantially flat region. Thus, coverage with a layer provided in the opening portion 141, a layer provided in the opening portion 241, and a layer provided in the opening portion 243 can be improved in some cases. In the case where the planar shapes of the opening portion 141, the opening portion 241, and the opening portion 243 are rectangular, by making the corners angular, the areas of the opening portion 141, the opening portion 241, and the opening portion 243 in the plan view can be increased as compared with the case where the corners are rounded, while the transistor 100 and the transistor 200 are miniaturized. Meanwhile, in the case where the corners of the opening portion 141, the opening portion 241, and the opening portion 243 are rounded, coverage of the corners of the opening portion 141 with the layer provided in the opening portion 141, coverage of the corners of the opening portion 241 with the layer provided in the opening portion 241, and coverage of the corners of the opening portion 243 in with layer provided in the opening portion 243 can be improved as compared with the case where the corners of the opening portion 141, the opening portion 241, and the opening portion 243 are angular.

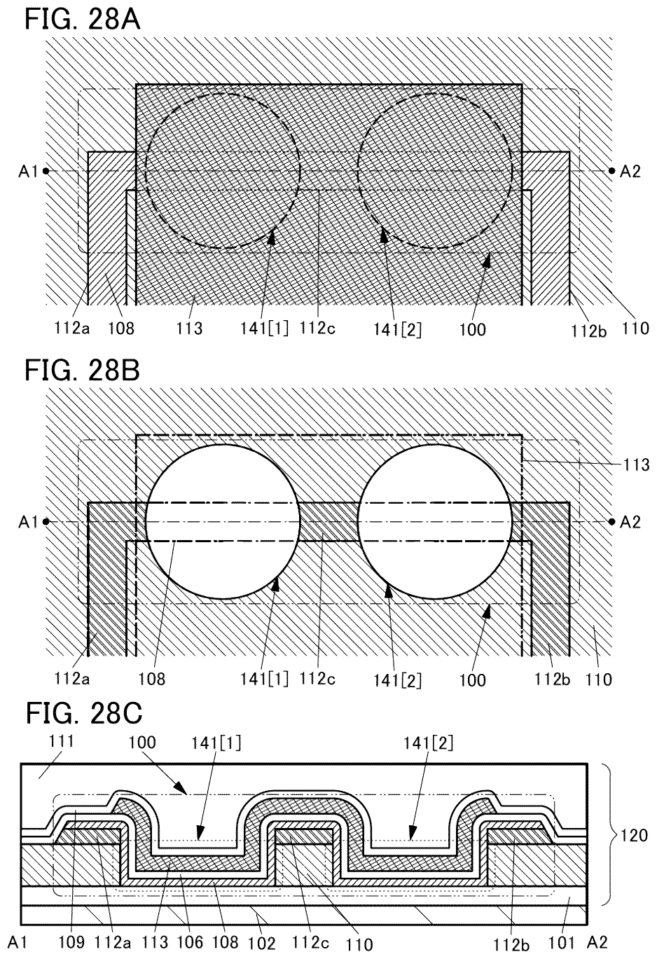

FIG. 28A is a plan view illustrating an example in which one transistor 100 illustrated in FIG. 1A is provided across the inside of two opening portions 141. FIG. 28B is a plan view illustrating the conductive layer 113 illustrated in FIG. 28A with a dashed double-dotted line. FIG. 28C is a cross-sectional view of a cut plane along the dashed-dotted line A1-A2 in FIG. 28A and FIG. 28B. In FIG. 28A to FIG. 28C, the two opening portions 141 are distinguished by the terms an opening portion 141[1] and an opening portion 141[2]. A conductive layer 112 c is provided as the conductive layer 112 between the opening portion 141[1] and the opening portion 141[2].

In the transistor 100 illustrated in FIG. 28A to FIG. 28C, the conductive layer 112a and the conductive layer 112c are provided to face each other with the opening portion 141[1] therebetween in the plan view. The conductive layer 112b and the conductive layer 112c are provided to face each other with the opening portion 141[2] therebetween in the plan view. In the example illustrated in FIG. 28A to FIG. 28C, one transistor 100 includes three conductive layers 112. Note that one transistor 100 may be provided across the inside of three or more opening portions 141. In that case, four or more conductive layers 112 can be provided in one transistor 100.

When one transistor 100 is provided across the inside of a plurality of opening portions 141, the channel length of the transistor 100 in the vertical direction can be long and the saturation characteristics of the transistor 100 can be improved as compared with the case where one transistor 100 is provided in one opening portion 141. Meanwhile, when one transistor 100 is provided in one opening portion 141, the transistor 100 can have a minute size as compared with the case where one transistor 100 is provided across the inside of a plurality of opening portions 141.

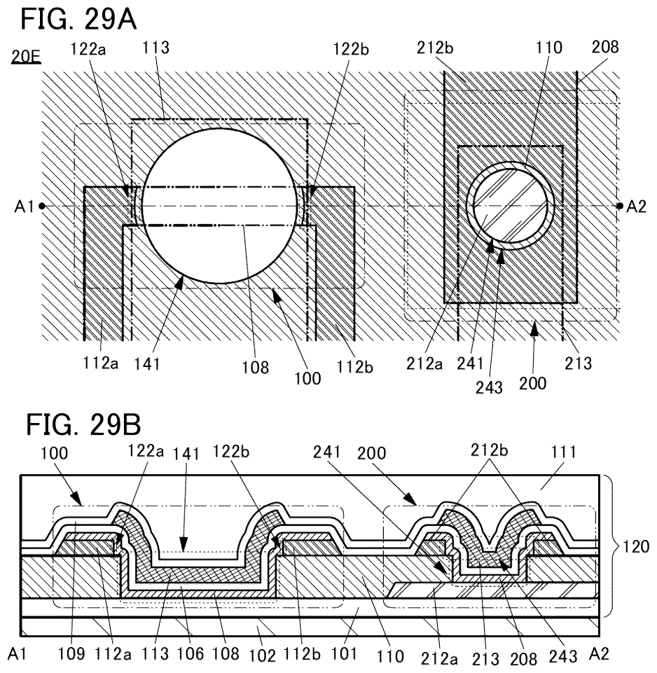

FIG. 29A is a plan view illustrating an example in which end portions of the conductive layer 112a and the conductive layer 112b illustrated in FIG. 1A, which face the opening portion 141 in the plan view, are not aligned with end portions of the insulating layer 110 in the opening portion 141. In addition, an end portion of the insulating layer 110 in the opening portion 241 is not aligned with an end portion of the conductive layer 212b in the opening portion 243 in the example illustrated in FIG. 29A. In FIG. 29A, the semiconductor layer 108, the conductive layer 113, and the conductive layer 213 are indicated by dashed double-dotted lines. The semiconductor layer 208 is shown without being hatched. FIG. 29B is a cross-sectional view taken along the dashed-dotted line A1-A2 in FIG. 29A. The semiconductor device 20 illustrated in FIG. 29A and FIG. 29B is referred to as a semiconductor device 20E.

In FIG. 29A and FIG. 29B, the end portion of the conductive layer 112a that faces the opening portion 141 in the plan view is referred to as an end portion 122a, and the end portion of the conductive layer 112b that faces the opening portion 141 in the plan view is referred to as an end portion 122b. In the example illustrated in FIG. 29A and FIG. 29B, the end portion 122a and the end portion 122b are positioned outside the end portion of the insulating layer 110 in the opening portion 141, that is, on the side opposite to the opening portion 141. In the example illustrated in FIG. 29A and FIG. 29B, the end portion of the conductive layer 212b in the opening portion 243 is positioned outside the end portion of the insulating layer 110 in the opening portion 241, that is, on the side opposite to the opening portion 241. The end portion 122a and the end portion 122b may be positioned more on the inner side than the end portion of the insulating layer 110 in the opening portion 141. In this case, the end portion 122a and the end portion 122b overlap with the opening portion 141. The end portion of the conductive layer 212b in the opening portion 243 may be positioned more on the inner side than the end portion of the insulating layer 110 in the opening portion 241. In this case, the end portion of the conductive layer 212b in the opening portion 243 overlaps with the opening portion 241.

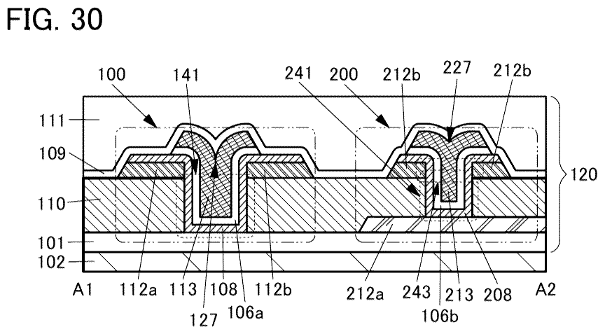

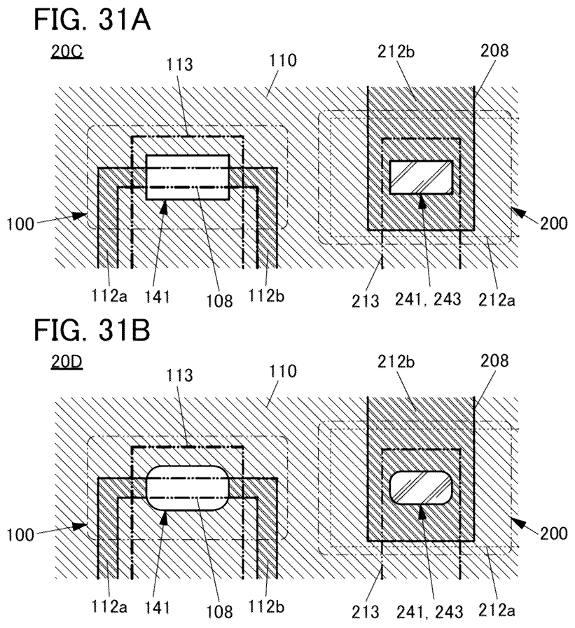

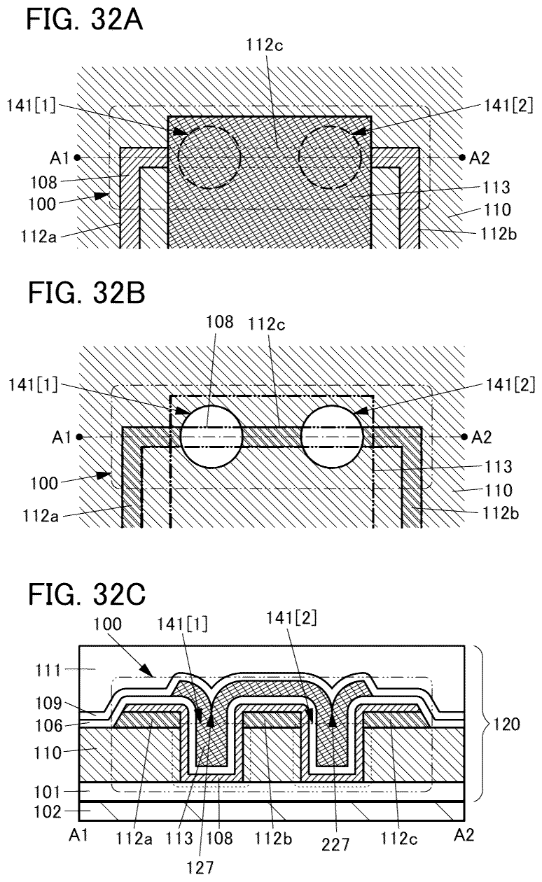

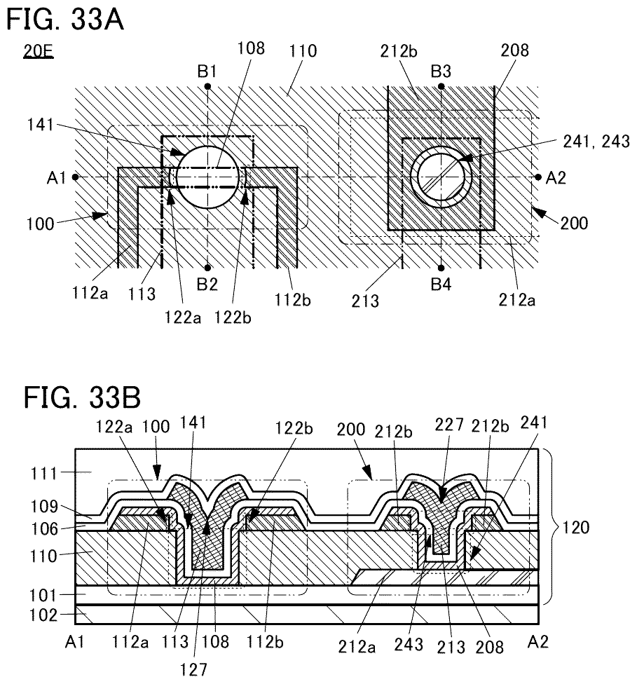

FIG. 30, FIG. 31A, FIG. 31B, FIG. 32A, FIG. 32B, FIG. 32C, FIG. 33A, and FIG. 33B illustrate modification examples of the structures illustrated in FIG. 26, FIG. 27A, FIG. 27B, FIG. 28A, FIG. 28B, FIG. 28C, FIG. 29A, and FIG. 29B. In each example, the conductive layer 113 is provided to be embedded in the opening portion 141 and the conductive layer 213 is provided to be embedded in the opening portion 241 and the opening portion 243.

### Structure Example 4 of Semiconductor Device

A structure example in which a plurality of layers 120 included in the semiconductor device 20 are stacked is described below.

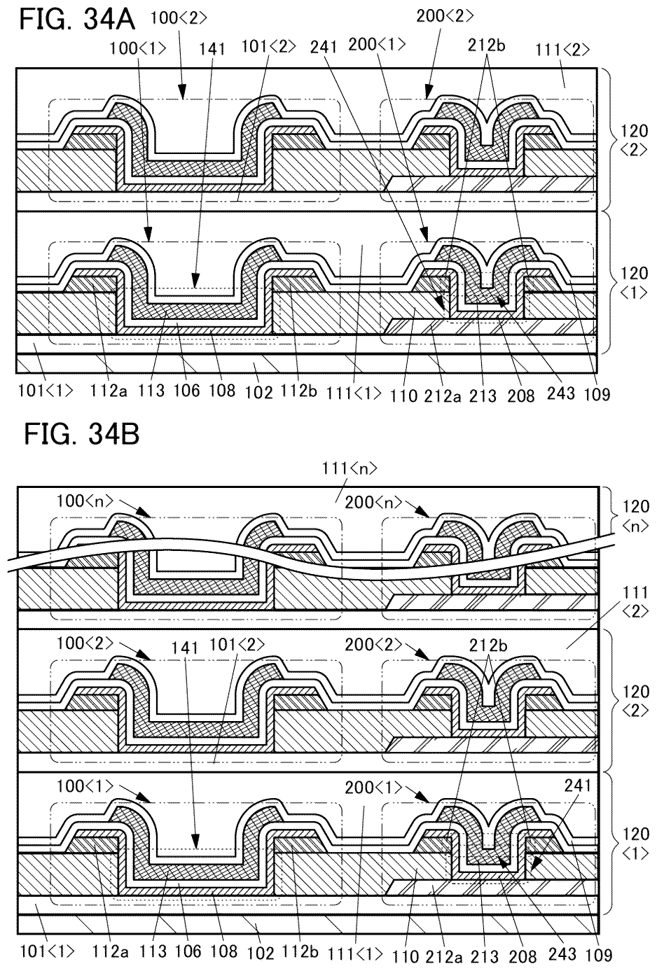

FIG. 34A is a cross-sectional view illustrating an example in which two layers 120 illustrated in FIG. 3A are stacked. In FIG. 34A, the two layers 120 are distinguished by being described as a layer 120<1> and a layer 120<2> in this order from the bottom. The same may be applicable to subsequent drawings.

In the following description, in the case where similar components are provided in the plurality of layers 120, <i> (i is an integer greater than or equal to 1) is sometimes added to the reference numerals representing the components provided in the layers 120 to distinguish these components. For example, the insulating layer 101 provided in the layer 120<1> is referred to as an insulating layer 101<1>, and the insulating layer 101 provided in the layer 120<2> is referred to as an insulating layer 101<2>, whereby the two insulating layers 101 are distinguished from each other.

As illustrated in FIG. 34A, the transistor 100<1> and the transistor 100<2> can be provided to include a region where they overlap with each other. The transistor 200<1> and the transistor 200<2> can be provided to include a region where they overlap with each other.

FIG. 34B is a cross-sectional view illustrating an example in which n layers 120 (n is an integer greater than or equal to 3) illustrated in FIG. 3A are stacked. In FIG. 34B, the n layers 120 are distinguished by being described as a layer 120<1> to a layer 120<n> in this order from the bottom. The same may be applicable to subsequent drawings.

As illustrated in FIG. 34B, the transistor 100<1> to the transistor 100<n> can be provided to include a region where they overlap with each other. The transistor 200<1> to the transistor 200<n> can be provided to include a region where they overlap with each other. Although FIG. 34A and FIG. 34B illustrate an example in which the transistors having the same structure include a region where they overlap with each other, the transistors having different structures may include a region where they overlap with each other. For example, the transistor 100 and the transistor 200 may include a region where they overlap with each other.

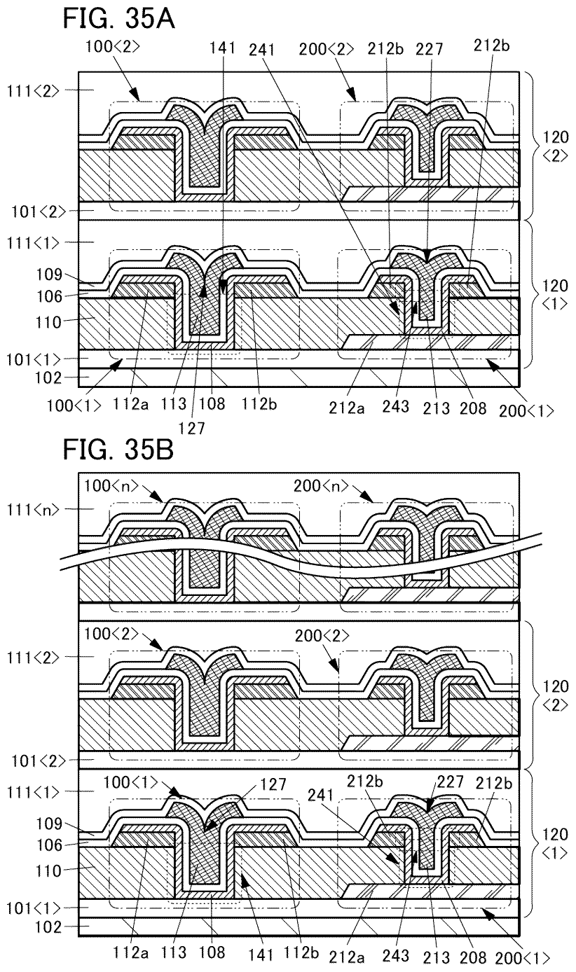

FIG. 35A and FIG. 35B illustrate a modification example of the structure illustrated in FIG. 34A and FIG. 34B. In the example, the conductive layer 113 is provided to be embedded in the opening portion 141 and the conductive layer 213 is provided to be embedded in the opening portion 241 and the opening portion 243.

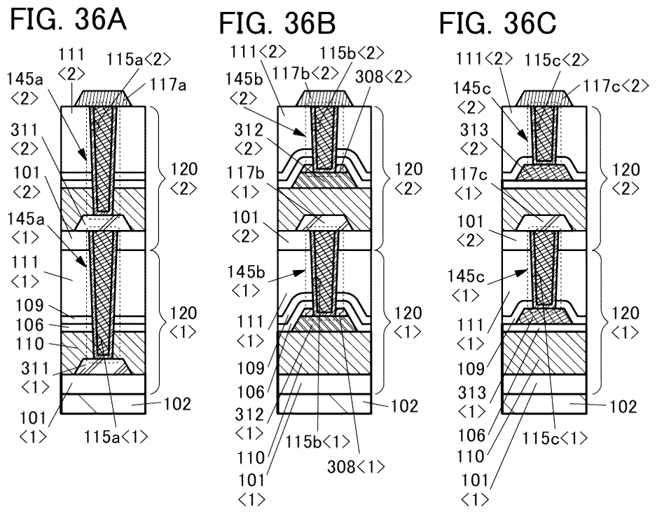

FIG. 36A, FIG. 36B, and FIG. 36C are cross-sectional views illustrating of examples of two stacked layers 120 illustrated in FIG. 3D, FIG. 3E, and FIG. 3F, respectively. In FIG. 36B, the conductive layer 117b electrically connected to a plug 115b<i> is referred to as a conductive layer 117b<i>. In FIG. 36C, the conductive layer 117c electrically connected to the plug 115c<i> is referred to as a conductive layer 117c<i>. The same may be applicable to subsequent drawings.

As illustrated in FIG. 36A, in the layer 120<1>, the conductive layer 311<1> is provided over the insulating layer 101<1>, and the insulating layer 110, the insulating layer 106, the insulating layer 109, the insulating layer 111<1>, and the insulating layer 101<2> are stacked in this order over the conductive layer 311<1> and the insulating layer 101<1>. An opening portion 145a<1> reaching the conductive layer 311<1> is provided in the insulating layer 101<2>, the insulating layer 111<1>, the insulating layer 109, the insulating layer 106, and the insulating layer 110; a plug 115a<1> is provided to be embedded in the opening portion 145a<1>. That is, part of the opening portion 145a<1> and part of the conductive layer 115a<1> are provided in the layer 120<2>. The conductive layer 311<1> is electrically connected to the conductive layer 311<2> provided over the plug 115a<1> and the insulating layer 101<2> through the plug 115a<1>.

In the layer 120<2>, an opening portion 145a<2> reaching the conductive layer 311<2> is provided in the insulating layer 110, the insulating layer 106, the insulating layer 109, and the insulating layer 111<2> that are provided over the conductive layer 311<2>. The plug 115a<2> is provided to be embedded in the opening portion 145a<2>. The conductive layer 117a is provided over the plug 115a<2> and the insulating layer 111<2>, and the conductive layer 311<2> and the conductive layer 117a are electrically connected through the plug 115a<2>.

In the above manner, the conductive layer 311<1>, the conductive layer 311<2>, and the conductive layer 117a can be electrically connected through the plug 115a<1> and the plug 115a<2>.

As illustrated in FIG. 36B, in the layer 120<1>, the insulating layer 110 is provided over the insulating layer 101<1>, and a conductive layer 312<1> is provided over the insulating layer 110. A semiconductor layer 308<1> is provided over the conductive layer 312<1>; the insulating layer 106, the insulating layer 109, the insulating layer 111<1>, and the insulating layer 101<2> are provided in this order over the semiconductor layer 308<1> and the insulating layer 110. An opening portion 145b<1> reaching the conductive layer 312<1> is provided in the insulating layer 101<2>, the insulating layer 111<1>, the insulating layer 109, the insulating layer 106, and the semiconductor layer 308<1>, and a plug 115b<1> is provided to be embedded in the opening portion 145b<1>. That is, part of the opening portion 145b<1> and part of the conductive layer 115b<1> are provided in the layer 120<2>.

A conductive layer 117b<1> is provided over the conductive layer 115b<1> and the insulating layer 101<2>. That is, the conductive layer 117b<1> is provided in the layer 120<2>. The insulating layer 110 is provided over the conductive layer 117b<1> and the insulating layer 101<2>. The conductive layer 117b<1> is provided in the same layer as the conductive layer 212a included in the layer 120<2>, for example. The conductive layer 312<1> is electrically connected to the conductive layer 117b<1> through the plug 115b<1>.

In the layer 120<2>, a semiconductor layer 308<2> is provided over the conductive layer 312<2>, and the insulating layer 106, the insulating layer 109, and the insulating layer 111<2> are stacked in this order over the semiconductor layer 308<2>. An opening portion 145b<2> reaching the conductive layer 312<2> is provided in the insulating layer 111<2>, the insulating layer 109, the insulating layer 106, and the semiconductor layer 308<2>; a plug 115b<2> is provided to be embedded in the opening portion 145b<2>. A conductive layer 117b<2> is provided over the plug 115b<2> and the insulating layer 111<2>, and the conductive layer 312<2> is electrically connected to the conductive layer 117b<2> through the plug 117b<2>.

As illustrated in FIG. 36C, in the layer 120<1>, the insulating layer 110 and the insulating layer 106 are stacked in this order over the insulating layer 101<1>, and a conductive layer 313<1> is provided over the insulating layer 106. The insulating layer 109, the insulating layer 111<1>, and the insulating layer 101<2> are stacked in this order over the conductive layer 313<1> and the insulating layer 106. An opening portion 145c<1> reaching the conductive layer 313<1> is provided in the insulating layer 101<2>, the insulating layer 111<1>, and the insulating layer 109, and a plug 115c<1> is provided to be embedded in the opening portion 145c<1>. That is, part of the opening portion 145c<1> and part of the conductive layer 115c<1> are provided in the layer 120<2>.

The conductive layer 117c<1> is provided over the conductive layer 115c<1> and the insulating layer 101<2>. That is, the conductive layer 117c<1> is provided in the layer 120<2>. The insulating layer 110 is provided over the conductive layer 117c<1> and the insulating layer 101<2>. The conductive layer 117c<1> is provided in the same layer as the conductive layer 212 a included in the layer 120<2>, for example. The conductive layer 313<1> is electrically connected to the conductive layer 117c<1> through the plug 115c<1>.

In the layer 120<2>, the insulating layer 109 and the insulating layer 111<2> are stacked in this order over the conductive layer 313<2>. An opening portion 145c<2> reaching the conductive layer 313<2> is provided in the insulating layer 111<2> and the insulating layer 109, and a plug 115c<2> is provided to be embedded in the opening portion 145c<2>. The conductive layer 117c<2> is provided over the plug 115c<2> and the insulating layer 111<2>, and the conductive layer 313<2> is electrically connected to the conductive layer 117c<2> through the plug 117c<2>.

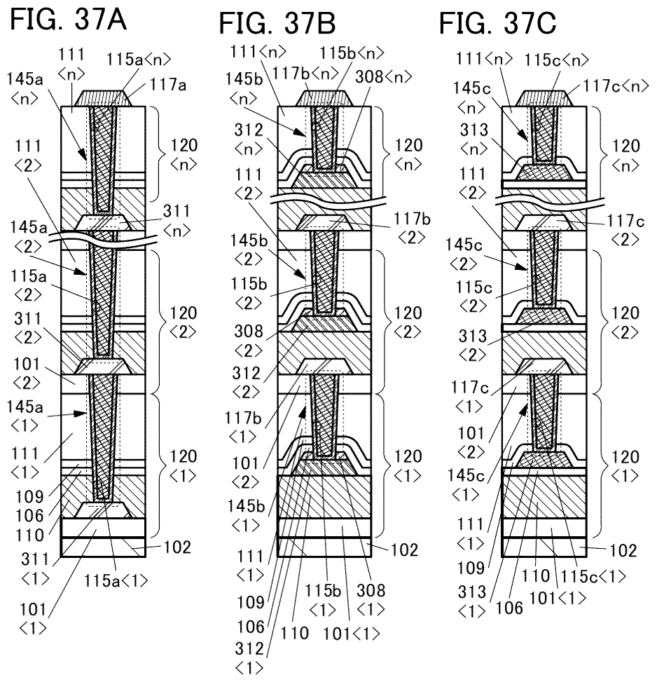

FIG. 37A, FIG. 37B, and FIG. 37C are cross-sectional views of examples of n stacked layers 120 illustrated in FIG. 3D, FIG. 3E, or FIG. 3F, respectively. The layer 120<1> can have a structure similar to that of the layer 120<1> illustrated in FIG. 36A, FIG. 36B, and FIG. 36C. In the layer 120<2> to the layer 120<n−1> as well as in the layer 120<1>, the conductive layer 311, the conductive layer 312, the conductive layer 313, the plug 115a, the plug 115b, the plug 115c, the conductive layer 117b, the conductive layer 117c, and the like are provided. The layer 120<n> can have a structure similar to that of the layer 120<2> illustrated in FIG. 36A, FIG. 36B, or FIG. 36C.

In the example illustrated in FIG. 37A, the conductive layer 117a is provided over a plug 115a<n> and an insulating layer 111<n>. The conductive layer 311<1> to the conductive layer 311<n> can be electrically connected to the conductive layer 117a through the plug 115a<1> to a plug 115a<n>, respectively. In the example illustrated in FIG. 37B, a conductive layer 117b<n> is provided over a plug 115b<n>and the insulating layer 111<n>. Furthermore, in the example illustrated in FIG. 37C, a conductive layer 117c<n> is provided over a plug 115c<n> and the insulating layer 111<n>.

When the plurality of layers 120 are stacked in the semiconductor device 20 as described above, many transistors 100 and transistors 200 can be provided in the semiconductor device 20 while an increase in the area occupied by the semiconductor device 20 is inhibited. In addition, components such as transistors provided in different layers 120 can be electrically connected to each other. In the above manner, a small and high-performance semiconductor device can be provided. The semiconductor device illustrated in FIG. 34A to FIG. 37C can be used for the display device 30 illustrated in FIG. 20A and the display device 30 illustrated in FIG. 25A, for example. The semiconductor device illustrated in FIG. 34A to FIG. 37C can be used for the scan line driver circuit 31, the signal line driver circuit 33, the power supply circuit 35, and the reference potential generation circuit 37, for example.

Materials that can be used for the components of the semiconductor device 20 are described below.

### Semiconductor Layer 108 and Semiconductor Layer 208

Metal oxides that can be used for the semiconductor layer 108 and the semiconductor layer 208 are specifically described. Examples of the metal oxide include indium oxide, gallium oxide, and zinc oxide. The metal oxide preferably contains at least indium or zinc. Note that the element M is a metal element or a metalloid element that has a high binding energy with oxygen, such as a metal element or a metalloid element whose binding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, and still further preferably one or more of gallium and tin. In this specification and the like, a metal element and a metalloid element may be collectively referred to as a “metal element”, and a “metal element” in this specification and the like may refer to a metalloid element.

For each of the semiconductor layer 108 and the semiconductor layer 208, an indium oxide (In oxide), an indium zinc oxide (In—Zn oxide), an indium tin oxide (also referred to as In—Sn oxide or ITO), an indium titanium oxide (In—Ti oxide), an indium gallium oxide (In—Ga oxide), an indium tungsten oxide (also referred to as In—W oxide or IWO), an indium gallium aluminum oxide (In—Ga—Al oxide), an indium gallium tin oxide (also referred to as In—Ga—Sn oxide or IGTO), a gallium zinc oxide (also referred to as Ga—Zn oxide or GZO), an aluminum zinc oxide (also referred to as Al—Zn oxide or AZO), an indium aluminum zinc oxide (also referred to as In—Al—Zn oxide or IAZO), an indium tin zinc oxide (also referred to as In—Sn—Zn oxide or ITZO (registered trademark)), an indium tin gallium oxide (In—Sn—Ga oxide), an indium titanium zinc oxide (In—Ti—Zn oxide), an indium gallium zinc oxide (also referred to as In—Ga—Zn oxide or IGZO), an indium gallium tin zinc oxide (also referred to as In—Ga—Sn—Zn oxide or IGZTO), or an indium gallium aluminum zinc oxide (also referred to as In—Ga—Al—Zn oxide, IGAZO, IGZAO, or IAGZO) can be used, for example. Alternatively, an indium tin oxide containing silicon (also referred to as ITSO), a gallium tin oxide (Ga—Sn oxide), an aluminum tin oxide (Al—Sn oxide), or the like can be used. Alternatively, the above-described oxide having an amorphous structure can be used. For example, indium oxide having an amorphous structure, indium tin oxide having an amorphous structure, or the like can be used.

By increasing the proportion of the number of indium atoms in the total number of atoms of all the metal elements contained in the metal oxide, the field-effect mobility of the transistor can be increased. In addition, the transistor can have a high on-state current.

Note that the metal oxide may contain, instead of indium or in addition to indium, one or more kinds of metal elements with large period numbers. The larger the overlap between orbits of metal elements is, the more likely it is that the metal oxide will have high carrier conductivity. Thus, a transistor including a metal element with a large period number in the periodic table can have high field-effect mobility in some cases. Examples of the metal element with a large period number include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. By containing a non-metallic element, the metal oxide sometimes has an increased carrier concentration, a reduced band gap, or the like, in which case the transistor can have increased field-effect mobility. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor can be inhibited, and the reliability of the transistor can be increased.

By increasing the proportion of the number of the element M atoms in the total number of atoms of all the metal elements contained in the metal oxide, oxygen vacancies (V_{O}) can be inhibited from being formed in the metal oxide. Thus, generation of carriers due to oxygen vacancies (V_{O}) is inhibited, which makes the off-state current of the transistor low. Furthermore, a change in electrical characteristics of the transistor is suppressed, and the reliability of the transistor can be increased.

The compositions of the metal oxides used for the semiconductor layer 108 and the semiconductor layer 208 affect the electrical characteristics and reliability of the transistors. Thus, by varying the composition of the metal oxide in accordance with the electrical characteristics and reliability required for the transistor, the semiconductor device can have both good electrical characteristics and high reliability.

When the metal oxide is an In-M-Zn oxide, the proportion of the number of In atoms is preferably higher than or equal to that of the number of M atoms in the In-M-Zn oxide. Examples of the atomic ratio of the metal elements in such an In-M-Zn oxide include In:M:Zn=1:1:1, In:M:Zn=1:1:1.2, In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=10:1:1, In:M:Zn=10:1:3, In:M:Zn=10:1:4, In:M:Zn=10:1:6, In:M:Zn=10:1:7, In:M:Zn=10:1:8, In:M:Zn=5:2:5, In:M:Zn=10:1:10, In:M:Zn=20:1:10, In:M:Zn=40:1:10, and a composition in the neighborhood of any of these atomic ratios. Note that a composition in the neighborhood includes the range of ±30 % of an intended atomic ratio. By increasing the proportion of the number of indium atoms in the metal oxide, the on-state current, field-effect mobility, or the like of the transistor can be improved.

The proportion of the number of In atoms may be lower than that of the number of M atoms in the In-M-Zn oxide. Examples of the atomic ratio of the metal elements in such an In-M-Zn oxide include In:M:Zn=1:3:2, In:M:Zn=1:3:3, In:M:Zn=1:3:4, and a composition in the neighborhood of any of these atomic ratios. By increasing the proportion of the number of M atoms in the metal oxide, generation of oxygen vacancies (V₀) can be inhibited.

In the case where a plurality of metal elements are contained as the element M, the sum of the proportions of the numbers of atoms of the metal elements can be the proportion of the number of the element M atoms.

In this specification and the like, the proportion of the number of indium atoms in the total number of atoms of all the metal elements contained is sometimes referred to as the content percentage of indium. The same applies to other metal elements.

The use of a material with a high indium content percentage for the semiconductor layer 108 and the semiconductor layer 208 can increase the on-state current, field-effect mobility, or the like of the transistors. Furthermore, with the element M, generation of oxygen vacancies (V_{O}) can be inhibited. The content percentage of the element M (the proportion of the number of the element M atoms in the total number of atoms of all the metal elements contained) is preferably higher than or equal to 0.1 % and lower than or equal to 3%, further preferably higher than or equal to 0.1% and lower than or equal to 2%. Accordingly, a transistor with favorable electrical characteristics can be provided. For example, a metal oxide with In:M:Zn of 40:1:10 or the neighborhood thereof is preferably used. The element M is preferably one or more kinds of the above elements, further preferably one or more kinds selected from aluminum, gallium, tin, and yttrium. Specifically, a metal oxide with In:Sn:Zn of 40:1:10 or the neighborhood thereof can be suitably used. Alternatively, a metal oxide with In:Al:Zn of 40:1:10 or the neighborhood thereof can be suitably used.

Here, in the case where a metal oxide having a polycrystalline structure is used for the semiconductor layer 108 and the semiconductor layer 208, the grain boundary becomes a recombination center and captures carriers and thus might reduce the on-state current of the transistor. In the case where a metal oxide with a composition that tends to form a poly crystalline structure is used, the metal oxide preferably contains an element that hinders crystallization. For example, an indium tin oxide containing silicon (ITSO) is less likely to have a polycrystalline structure than an indium tin oxide (ITO), and thus can be suitably used for the semiconductor layer 108 and the semiconductor layer 208. In the case where ITSO is used, the content percentage of silicon (the proportion of the number of silicon atoms in the total number of atoms of all the metal elements contained) is preferably higher than or equal to 1% and lower than or equal to 20%, further preferably higher than or equal to 3% and lower than or equal to 20%, further preferably higher than or equal to 3% and lower than or equal to 15%, still further preferably higher than or equal to 5% and lower than or equal to 15%. Specifically, a metal oxide with In:Sn:Si of 45:5:4, In:Sn:Si of 95:5:8, or the neighborhood thereof can be suitably used.

For analysis of the compositions of the semiconductor layer 108 and the semiconductor layer 208, for example, energy dispersive X-ray spectrometry (EDX), X-ray photoelectron spectrometry (XPS), inductively coupled plasma-mass spectrometry (ICP-MS), or inductively coupled plasma-atomic emission spectrometry (ICP-AES) can be used. Alternatively, any of these methods may be combined with each other for the analysis. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

For the formation of a metal oxide, a sputtering method or an atomic layer deposition (ALD) method can be suitably used. In the case where the metal oxide is formed by a sputtering method, the composition of the formed metal oxide may be different from the composition of a sputtering target. In particular, the content percentage of zinc in the formed metal oxide may be reduced to approximately 50% of that of the sputtering target.

The semiconductor layer 108 and the semiconductor layer 208 may each have a stacked-layer structure including two or more metal oxide layers. The two or more metal oxide layers included in each of the semiconductor layer 108 and the semiconductor layer 208 may have the same composition or substantially the same compositions. Employing a stacked-layer structure of metal oxide layers having the same composition can reduce the manufacturing cost because the metal oxide layers can be formed using the same sputtering target, for example.

The two or more metal oxide layers included in each of the semiconductor layer 108 and the semiconductor layer 208 may have different compositions. For example, a stacked-layer structure of a first metal oxide layer having a composition of In:M:Zn=1:3:4 [atomic ratio] or in the neighborhood thereof and a second metal oxide layer having a composition of In:M:Zn=1:1:1 [atomic ratio] or in the neighborhood thereof and being provided over the first metal oxide layer can be suitably employed. In addition, it is particularly preferable to use gallium, aluminum, or tin as the element M. The element M in the first metal oxide layer and that in the second metal oxide layer may be the same or different from each other. For example, the first metal oxide layer and the second metal oxide layer may be IGZO layers having different compositions.

For example, a stacked-layer structure of the first metal oxide layer having In:Zn=4:1 [atomic ratio] or a composition in the neighborhood thereof and the second metal oxide layer having In:M:Zn=1:1:1 [atomic ratio] or a composition in the neighborhood thereof and being provided over the first metal oxide layer can be suitably used.

For example, a stacked-layer structure of any one selected from an indium oxide, an indium gallium oxide, and IGZO, and any one selected from IAZO, IAGZO, and ITZO (registered trademark) may be employed.

In the case where the first metal oxide layer containing a first metal oxide and the second metal oxide layer containing a second metal oxide form a stacked-layer structure and the first metal oxide and the second metal oxide have the same composition or substantially the same compositions, the boundary (interface) between the first metal oxide layer and the second metal oxide layer cannot clearly be observed in some cases.

It is preferable to use a metal oxide having crystallinity for the semiconductor layer 108 and the semiconductor layer 208. Examples of the structure of a metal oxide having crystallinity include a CAAC (c-axis aligned crystalline) structure, a polycrystalline structure, and a nano-crystal (nc) structure. With use of a metal oxide having crystallinity, the density of defect states in the semiconductor layer 208 and the semiconductor layer 108 can be reduced, which enables the semiconductor device to have high reliability.

The semiconductor layer 108 and the semiconductor layer 208 are each preferably formed using a CAAC-OS or an nc-OS.

The CAAC-OS includes a plurality of layered crystals. The c-axis of the crystal is aligned in the normal direction of the formation surface. The semiconductor layer 108 and the semiconductor layer 208 each preferably include a layered crystal parallel or substantially parallel to the formation surface. For example, the semiconductor layer 208 preferably includes a layered crystal parallel or substantially parallel to the upper surface of the conductive layer 212b in a region in contact with the upper surface, and a layered crystal parallel or substantially parallel to the side surface of the conductive layer 212b in a region in contact with the side surface. In particular, in the opening portion 241, the semiconductor layer 208 preferably includes a layered crystal parallel or substantially parallel to the side surface of the insulating layer 110 serving as the formation surface. With such a structure, the layered crystals of the semiconductor layer 208 are formed parallel or substantially parallel to the channel length direction of the transistor 200, so that the on-state current of the transistor can be increased. Similarly, the semiconductor layer 108 preferably includes a layered crystal parallel or substantially parallel to the formation surface (here, the side surface of the insulating layer 110, the side surface of the conductive layer 112a, and the side surface of the conductive layer 112b). In particular, in a region overlapping with the conductive layer 113, the semiconductor layer 108 preferably includes a layered crystal parallel or substantially parallel to the side surface of the insulating layer 110 serving as the formation surface.

The use of a metal oxide having high crystallinity for a channel formation region can reduce the density of defect states in the channel formation region. By contrast, the use of a metal oxide layer having low crystallinity enables a transistor to allow a large amount of current to flow therethrough.

In the case where the metal oxide is formed by a sputtering method, the crystallinity of the formed metal oxide can be increased as the substrate temperature at the time of formation is higher. For example, the substrate temperature at the time of formation can be adjusted by the temperature of the stage on which the substrate is placed at the time of formation. Furthermore, the higher the proportion of the flow rate of an oxygen gas to the total flow rate of the film formation gas used for the formation (also referred to as an oxygen flow rate ratio) or the oxygen partial pressure in a treatment chamber is, the higher the crystallinity of the formed metal oxide layer can be.

The crystallinity of the semiconductor layer 108 and the semiconductor layer 208 can be analyzed with an X-ray diffraction (XRD) pattern, a transmission electron microscope (TEM) image, or an electron diffraction (ED) pattern, for example. Alternatively, any of these methods may be combined with each other for the analysis.

In the case where a metal oxide is used for the semiconductor layer 108 and the semiconductor layer 208, VoH in the channel formation regions is preferably reduced as much as possible so that the semiconductor layer 108 and the semiconductor layer 208 become highly purified intrinsic or substantially highly purified intrinsic semiconductor layers. In order to obtain such a metal oxide with sufficiently reduced V_{O}H, it is important to remove impurities such as water and hydrogen in the metal oxide (this treatment is sometimes referred to as dehydration or dehydrogenation treatment) and supply oxygen to the metal oxide to repair oxygen vacancies (V_{O}). When a metal oxide with sufficiently reduced impurities such as V_{O}H is used for a channel formation region of a transistor, stable electrical characteristics can be given. Supplying oxygen to a metal oxide to repair oxygen vacancies (V_{O}) is sometimes referred to as oxygen adding treatment.

In the case where a metal oxide is used for each of the semiconductor layer 108 and the semiconductor layer 208, the carrier concentration in the channel formation region is preferably lower than or equal to 1×10¹⁸ cm⁻³, further preferably lower than 1×10¹⁷ cm⁻³, still further preferably lower than 1×10¹⁶ cm⁻³, yet still further preferably lower than 1×10¹³ cm⁻³, yet still further preferably lower than 1×10¹² cm⁻³. Note that the lower limit of the carrier concentration in the channel formation region is not particularly limited and can be, for example, 1×10⁻⁹ cm⁻³.

A change in electrical characteristics of an OS transistor due to radiation irradiation is small, i.e., an OS transistor has high tolerance to radiation; thus, an OS transistor can be suitably used even in an environment where radiation can enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a proton beam, and a neutron beam).

The semiconductor layer 108 and the semiconductor layer 208 may each include a layered substance functioning as a semiconductor. The layered substance is a general term of a group of materials having a layered crystal structure. In the layered crystal structure, layers formed by covalent bonding or ionic bonding are stacked with bonding such as the Van der Waals bonding, which is weaker than covalent bonding or ionic bonding. The layered material has high electrical conductivity in a unit layer, that is, high two-dimensional electrical conductivity. When a material functioning as a semiconductor and having high two-dimensional electrical conductivity is used for a channel formation region, a transistor having a high on-state current can be provided.

Examples of the layered substance include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide that can be used for a channel formation region of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

### Conductive Layer 112a, Conductive Layer 112b, Conductive Layer 113, Conductive Layer 212a, Conductive Layer 212b, and Conductive Layer 213

The conductive layer 112a, the conductive layer 112b, the conductive layer 113, the conductive layer 212a, the conductive layer 212b, and the conductive layer 213 may each have a single-layer structure or a stacked-layer structure of two or more layers. The conductive layer 112a, the conductive layer 112b, the conductive layer 113, the conductive layer 212a, the conductive layer 212b, and the conductive layer 213 can each be formed using, for example, one or more of chromium, copper, aluminum, gold, silver, zinc, tantalum, titanium, tungsten, manganese, nickel, iron, cobalt, molybdenum, and niobium, or an alloy containing one or more of these metals as its components. For each of the conductive layer 112a, the conductive layer 112b, the conductive layer 113, the conductive layer 212a, the conductive layer 212b, and the conductive layer 213, a conductive material with low electrical resistance that contains one or more of copper, silver, gold, and aluminum can be suitably used. Copper or aluminum is particularly preferable because of its high mass-productivity.

For each of the conductive layer 112a, the conductive layer 112b, the conductive layer 113, the conductive layer 212a, the conductive layer 212b, and the conductive layer 213, a conductive metal oxide (also referred to as an oxide conductor) can be used. Examples of an oxide conductor (OC) include an indium oxide, a zinc oxide, an In—Sn oxide (ITO), an In—Zn oxide, an In—W oxide, an In—W—Zn oxide, an In—Ti oxide, an In—Ti—Sn oxide, an In—Sn—Si oxide (also referred to as an ITO containing silicon or an ITSO), zinc oxide to which gallium is added, and an In—Ga—Zn oxide. A conductive oxide containing indium is particularly preferable because of its high conductivity.

When an oxygen vacancy is formed in a metal oxide having semiconductor characteristics and hydrogen is added to the oxygen vacancy, a donor level is formed in the vicinity of the conduction band. As a result, the conductivity of the metal oxide is increased, and thus, the metal oxide becomes a conductor. The metal oxide having become a conductor can be referred to as an oxide conductor.

Each of the conductive layer 112a, the conductive layer 112b, the conductive layer 113, the conductive layer 212a, the conductive layer 212b, and the conductive layer 213 may have a stacked-layer structure of a conductive film containing the above-described oxide conductor (metal oxide) and a conductive film containing a metal or an alloy. The use of the conductive film containing a metal or an alloy can reduce the wiring resistance.

A Cu—X alloy film (X is Mn, Ni, Cr, Fe, Co, Mo, Ta, or Ti) may be used for each of the conductive layer 112a, the conductive layer 112b, the conductive layer 113, the conductive layer 212a, the conductive layer 212b, and the conductive layer 213. The use of a Cu—X alloy film can reduce the manufacturing cost because a wet etching method can be used in the processing.

Note that the conductive layer 112a, the conductive layer 112b, the conductive layer 113, the conductive layer 212a, the conductive layer 212b, and the conductive layer 213 may be formed using the same material or different materials.

The conductive layer 112a and the conductive layer 112b each include a region in contact with the semiconductor layer 108. The conductive layer 212a and the conductive layer 212b each include a region in contact with the semiconductor layer 208. In the case where a metal oxide is used for the semiconductor layer 108, when the conductive layer 112a and the conductive layer 112b are formed using a metal that is easily oxidized (e.g., aluminum), an insulating oxide (e.g., aluminum oxide) might be formed between the conductive layer 112a and the semiconductor layer 108 and between the conductive layer 112b and the semiconductor layer 108 to prevent electrical continuity between these layers. Similarly, in the case where a metal oxide is used for the semiconductor layer 208, when the conductive layer 212a and the conductive layer 212b are formed using a metal that is easily oxidized, an insulating oxide might be formed between the conductive layer 212a and the semiconductor layer 208 and between the conductive layer 212b and the semiconductor layer 208 to prevent electrical continuity between these layers. Therefore, the conductive layer 112a, the conductive layer 112b, the conductive layer 212a, and the conductive layer 212b are preferably formed using a conductive material that is not easily oxidized, a conductive material that maintains low electric resistance even after being oxidized, or an oxide conductive material.

For each of the conductive layer 112a, the conductive layer 112b, the conductive layer 212a, and the conductive layer 212b, for example, one or more of titanium, tantalum nitride, titanium nitride, a nitride containing titanium and aluminum, a nitride containing tantalum and aluminum, ruthenium, ruthenium oxide, ruthenium nitride, an oxide containing strontium and ruthenium, and an oxide containing lanthanum and nickel is preferably used. These materials are preferable because they are conductive materials that are not easily oxidized or materials that maintain low electric resistance even after being oxidized.

The conductive layer 112a, the conductive layer 112b, the conductive layer 212a, and the conductive layer 212b can each be formed using any of the above-described oxide conductors. Specifically, a conductive oxide such as indium oxide, zinc oxide, ITO, an In—Zn oxide, an In—W oxide, an In—W—Zn oxide, an In—Ti oxide, an In—Ti—Sn oxide, an In—Sn oxide containing silicon, or zinc oxide to which gallium is added can be used.

A nitride conductor may be used for each of the conductive layer 112a, the conductive layer 112b, the conductive layer 212a, and the conductive layer 212b. Examples of the nitride conductor include tantalum nitride and titanium nitride.

The conductive layer 112a, the conductive layer 112b, the conductive layer 113, the conductive layer 212a, the conductive layer 212b, and the conductive layer 113 may each have a stacked-layer structure. In that case, at least a region in contact with the semiconductor layer 108 or the semiconductor layer 208 is preferably formed using a conductive material that is not easily oxidized, a conductive material that maintains low electric resistance even after being oxidized, or an oxide conductive material. A region in contact with neither the semiconductor layer 108 nor the semiconductor layer 208 is preferably formed using a material with low electrical resistivity. In that case, the electric resistance of the conductive layer can be reduced. For example, an In—Sn—Si oxide (ITSO) can be suitably used for the region in contact with the semiconductor layer 108 or the semiconductor layer 208, and copper or tungsten can be suitably used for the region in contact with neither the semiconductor layer 108 nor the semiconductor layer 208.

### Insulating Layer 106

The insulating layer 106 may have a single-layer structure or a stacked-layer structure of two or more layers. The insulating layer 106 may have a single-layer structure or a stacked-layer structure of two or more layers. Examples of a material that can be used for the inorganic insulating film include an oxide, a nitride, an oxynitride, and a nitride oxide. For the insulating layer 106, a material usable for the insulating layer 110 can be used.

The insulating layer 106 includes regions in contact with the semiconductor layer 108 and the semiconductor layer 208. In the case where a metal oxide is used for the semiconductor layer 108 and the semiconductor layer 208, any of the above-described oxides and oxynitrides is preferably used for at least a film of the insulating layer 106 that is in contact with the semiconductor layer 108 and the semiconductor layer 208. A film from which oxygen is released by heating is further preferably used as the insulating layer 106.

Specifically, in the case where the insulating layer 106 has a single-layer structure, an oxide or an oxynitride is preferably used for the insulating layer 106. Specifically, silicon oxide or silicon oxynitride can be suitably used for the insulating layer 106.

In the case where the insulating layer 106 has a stacked-layer structure, an insulating film in contact with the semiconductor layer 108 and the semiconductor layer 208 preferably includes an oxide or an oxynitride, and an insulating film in contact with the conductive layer 213 and the conductive layer 113 preferably includes a nitride or a nitride oxide. As the oxide or the oxynitride, for example, silicon oxide or silicon oxynitride can be suitably used. As the nitride or the nitride oxide, silicon nitride or silicon nitride oxide can be suitably used.

Silicon nitride and silicon nitride oxide release a smaller amount of impurities (e.g., water and hydrogen) and are less likely to transmit oxygen and hydrogen, and thus can be suitably used for the insulating layer 106. Diffusion of impurities from the insulating layer 106 into the semiconductor layer 108 and the semiconductor layer 208 is inhibited, whereby the transistors can have favorable electrical characteristics and high reliability.

A miniaturized transistor including a thin gate insulating layer might have a high leakage current. When a high dielectric constant material (also referred to as a high-k material) is used for the gate insulating layer, the voltage at the time of operation of the transistor can be reduced while the physical thickness is maintained. Examples of the high-k material usable for the insulating layer 106 include gallium oxide, hafnium oxide, zirconium oxide, an oxide including aluminum and hafnium, an oxynitride including aluminum and hafnium, an oxide including silicon and hafnium, an oxynitride including silicon and hafnium, and a nitride including silicon and hafnium.

### Insulating Layer 109 and Insulating Layer 111

A material that does not easily allow diffusion of impurities is preferably used for the insulating layer 109 functioning as a protective layer of the transistor 100 and the transistor 200. Providing the insulating layer 109 can effectively inhibit diffusion of impurities into the transistors from the outside and can increase the reliability of the semiconductor device. Examples of the impurities include water and hydrogen. Preferably, the insulating layer 111 functions as an interlayer insulating layer and is planarized as described above.

The insulating layer 109 and the insulating layer 111 can each be an insulating layer including an inorganic material. For example, an inorganic material such as an oxide, an oxynitride, a nitride oxide, or a nitride can be suitably used for the insulating layer 109 and the insulating layer 111. Specifically, one or more of silicon oxide, silicon nitride, silicon nitride oxide, silicon oxynitride, aluminum oxide, aluminum oxynitride, aluminum nitride, hafnium oxide, and hafnium aluminate can be used.

One or both of the insulating layer 109 and the insulating layer 111 may be an insulating layer containing an organic material. For example, while the insulating layer 109 is an inorganic material, the insulating layer 111 may be an organic material. As the organic material, for example, one or more of an acrylic resin and a polyimide resin can be used. As the organic material, a photosensitive material may be used. When the insulating layer 111 is an organic material, the insulating layer 111 can be planarized without using a chemical mechanical polishing (CMP) method.

### Substrate 102

Although there is no great limitation on a material of the substrate 102, it is necessary that the substrate have heat resistance high enough to withstand at least heat treatment performed later. Although there is no great limitation on a material of the substrate 102, it is necessary that the substrate have heat resistance high enough to withstand at least heat treatment performed later. For example, a single crystal semiconductor substrate or a polycrystalline semiconductor substrate of silicon or silicon carbide, a compound semiconductor substrate of silicon germanium or the like, an SOI substrate, a glass substrate, a quartz substrate, a sapphire substrate, a ceramic substrate, or an organic resin substrate may be used as the substrate 102. The substrate 102 may be provided with a semiconductor element. Note that the shapes of the semiconductor substrate and an insulating substrate may each be a circle or a square.

A flexible substrate may be used as the substrate 102, and the transistor 100, the transistor 200, and the like may be formed directly on the flexible substrate. Alternatively, a separation layer may be provided between the substrate 102 and the transistor 100, the transistor 200, and the like. With the separation layer, part or the whole of a semiconductor device completed thereover can be separated from the substrate 102 and transferred onto another substrate. In such a case, the transistor 100, the transistor 200, and the like can be transferred onto a substrate having low heat resistance or a flexible substrate as well.

As the substrate 102, any of the above-described substrates over which an insulating layer is stacked may be used.

### Example of Method for Manufacturing Semiconductor Device

An example of a method for manufacturing the semiconductor device of one embodiment of the present invention will be described below with reference to drawings. Note that as for a material and a formation method of each component, portions similar to the portions described above are not described in some cases.

Thin films included in the semiconductor device (e.g., insulating films, semiconductor films, and conductive films) can be formed by a sputtering method, a CVD method, a vacuum evaporation method, a pulsed laser deposition (PLD) method, an ALD method, a molecular beam epitaxy (MBE) method, or the like. Examples of a CVD method include a PECVD method and a thermal CVD method. As an example of the thermal CVD method, a metal organic chemical vapor deposition (MOCVD) method is given.

The thin films included in the semiconductor device (insulating films, semiconductor films, conductive films, and the like) can be formed by a wet film formation method such as spin coating, dipping, spray coating, inkjetting, dispensing, screen printing, offset printing, a doctor knife method, slit coating, roll coating, curtain coating, and knife coating.

When the thin films included in the semiconductor device are formed, a photolithography method can be used, for example. Alternatively, a nanoimprinting method, a sandblasting method, a lift-off method, or the like may be used to form thin films. Alternatively, island-shaped thin films may be directly formed by a film formation method using a shielding mask such as a metal mask.

There are two typical methods for forming a layer using a photolithography method. In one of the methods, a resist mask is formed over a thin film that is to be processed, the thin film is processed by an etching method, for example, and then the resist mask is removed. In the other method, a photosensitive thin film is formed and then processed into a desired shape by light exposure and development.

As light used for light exposure in a photolithography method, for example, an i-line (with a wavelength of 365 nm), a g-line (with a wavelength of 436 nm), an h-line (with a wavelength of 405 nm), or light in which these lines are mixed can be used. Besides, ultraviolet rays, KrF laser light, ArF laser light, or the like can be used. In addition, light exposure may be performed by liquid immersion exposure technique. As the light used for light exposure, extreme ultraviolet (EUV) light or X-rays may be used. Instead of the light used for the light exposure, an electron beam can be used. It is preferable to use extreme ultraviolet light, X-rays, or an electron beam because extremely minute processing is possible. Note that when light exposure is performed by scanning with a beam such as an electron beam, a photomask is not needed.

For etching of thin films, one or more selected from a dry etching method, a wet etching method, and a sandblast method can be used.

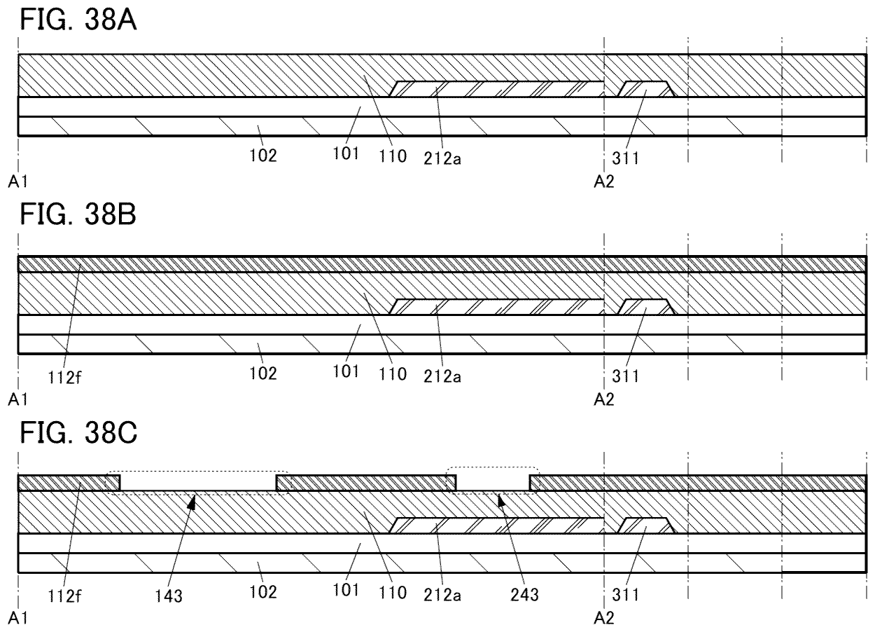

An example of a method for manufacturing the semiconductor device illustrated in FIG. 3A and FIG. 3D to FIG. 3F is described with reference to FIG. 38A to FIG. 42B. FIG. 38A to FIG. 42B each illustrate cross-sections corresponding to FIG. 3A and FIG. 3D to FIG. 3F arranged side by side.

First, the insulating layer 101 is formed over the substrate 102 (FIG. 38A). The insulating layer 101 can be formed by a sputtering method, a CVD method, or an ALD method, for example. Here, in the case where the insulating layer 101 has a stacked-layer structure of a plurality of layers, a method for forming at least one of the layers may be different from a method for forming the other layer(s). The same applies to other insulating layers, conductive layers, semiconductor layers, and the like described below.

Subsequently, a conductive film to be the conductive layer 212a and the conductive layer 311 is formed over the insulating layer 101, and the conductive film is processed to form the conductive layer 212a and the conductive layer 311 (FIG. 38A). For the formation of the conductive film to be the conductive layer 212a and the conductive layer 311, a sputtering method can be suitably used. The conductive film can be processed by an etching method and is preferably processed by a dry etching method in terms of microfabrication.

Next, the insulating layer 110 is formed over the insulating layer 101, the conductive layer 212a, and the conductive layer 311 (FIG. 38A). For the formation of the insulating layer 110, an ALD method, a sputtering method, or a CVD method can be suitably used, for example.

FIG. 38A illustrates an example in which the insulating layer 110 is planarized. The planarization can be performed by a CMP method, for example.

Next, a conductive film 112f to be the conductive layer 112a, the conductive layer 112b, the conductive layer 212b, and the conductive layer 312 in a later step is formed over the insulating layer 110 (FIG. 38B). For the formation of the conductive film 112f, a sputtering method can be suitably used, for example.

Next, part of the conductive film 112f is removed to form the opening portion 143 and the opening portion 243 in the conductive film 112f (FIG. 38C). The conductive film 112f can be processed by an etching method, and is preferably processed by a dry etching method in terms of microfabrication.

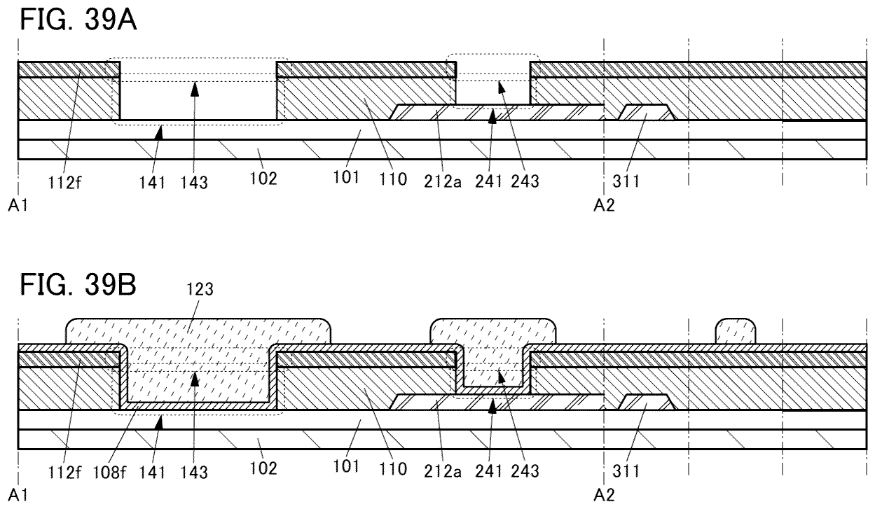

Then, the insulating layer 110 is partly removed to form the opening portion 141 and the opening portion 241 in the insulating layer 110 (FIG. 39A). The opening portion 141 is formed to include a region overlapping with the opening portion 143 and reach the insulating layer 101. The opening portion 241 is formed to include a region overlapping with the opening portion 243 and reach the conductive layer 212a. The part of the insulating layer 110 can be removed by an etching method, preferably a dry etching method in terms of microfabrication.

FIG. 39A illustrates an example in which the end portion of the insulating layer 110 in the opening portion 141 is aligned with the end portion of the conductive film 112f in the opening portion 143. I addition, the end portion of the insulating layer 110 in the opening portion 241 is aligned with the end portion of the conductive film 112f in the opening portion 243 in the example illustrated in FIG. 39A. In the case where the etching rate of the insulating layer 110 in the direction horizontal to the upper surface of the insulating layer 101 is different from the etching rate of the conductive film 112f in the direction horizontal to the upper surface of the insulating layer 101, for example, the end portion of the insulating layer 110 in the opening portion 141 is not aligned with the end portion of the conductive film 112f in the opening portion 143 in some cases. For example, in the case where the etching rate of the conductive film 112f in the direction horizontal to the upper surface of the insulating layer 101 is higher than the etching rate of the insulating layer 110 in the direction horizontal to the upper surface of the insulating layer 101, the end portion of the conductive film 112f in the opening portion 143 is positioned outside the end portion of the insulating layer 110 in the opening portion 141 in some cases, as in the example illustrated in FIG. 29B.

Note that in the formation of the opening portion 241 or after the formation of the opening portion 241, part of the conductive layer 212a in a region overlapping with the opening portion 241 may be removed. When the thickness of the region of the conductive layer 212a that is in contact with the lower surface of the semiconductor layer 208 to be formed in a later step is smaller than the thickness of the region of the conductive layer 212a that is not in contact with the semiconductor layer 208, the electric field of the gate electrode applied to the channel formation region in the vicinity of the conductive layer 212a can be intensified, leading to a high on-state current of the transistor 200.

Next, heat treatment may be performed. The heat treatment is performed at higher than or equal to 250° C. and lower than or equal to 650° C., preferably higher than or equal to 300° C. and lower than or equal to 500° C., further preferably higher than or equal to 320° C. and lower than or equal to 450° C. Note that the heat treatment is performed in an atmosphere of a nitrogen gas or an inert gas, for example. The heat treatment may be performed under reduced pressure. By the above-described heat treatment, an impurity such as water contained in the insulating layer 101 and the insulating layer 110, for example, can be reduced before the later-described semiconductor film to be the semiconductor layer 108, the semiconductor layer 208, and the semiconductor layer 308.

The gas used in the above heat treatment is preferably highly purified. For example, the amount of moisture contained in the gas used in the above heat treatment is less than or equal to 1 ppb, preferably less than or equal to 0.1 ppb, further preferably less than or equal to 0.05 ppb. The heat treatment using a highly purified gas can prevent, for example, entry of moisture into the insulating layer 101 and the insulating layer 110 as much as possible.

Then, a semiconductor film 108f to be the semiconductor layer 108, the semiconductor layer 208, and the semiconductor layer 308 is formed to cover the opening portion 141, the opening portion 143, the opening portion 241, and the opening portion 243 (FIG. 39B). The semiconductor film 108f can be formed to include a region in contact with an upper surface of the conductive film 112f, a region in contact with a side surface of the conductive film 112f in the opening portion 143, a region in contact with a side surface of the conductive film 112f in the opening portion 243, a region in contact with an upper surface of the conductive layer 212a, a region in contact with the side surface of the insulating layer 110 in the opening portion 141, a region in contact with the side surface of the insulating layer 110 in the opening portion 241, and a region in contact with the upper surface of the insulating layer 101.

A metal oxide film can also be used for the semiconductor film 108f, and specifically, an oxide semiconductor film can be used. The semiconductor film 108f can be formed by a sputtering method, a CVD method, or an ALD method, for example. Here, the semiconductor film 108f is preferably formed by a film formation method with favorable coverage, and is further preferably formed by a CVD method, an ALD method, or the like. For example, an In—Ga—Zn oxide may be deposited by an ALD method as the oxide semiconductor film. Note that in the case where the side surfaces of the opening portion 141, the opening portion 143, the opening portion 241, and the opening portion 243 each have a tapered shape, the semiconductor film 108f can be formed by a sputtering method.

In or after the formation of the semiconductor film 108f, microwave treatment is preferably performed in an oxygen-containing atmosphere, for example, to reduce the impurity concentration in the semiconductor film 108f. Specific examples of the impurity include hydrogen and carbon. The microwave treatment can increase the crystallinity of the semiconductor film 108f in some cases. Here, the microwave treatment refers to, for example, treatment using an apparatus including a power source that generates high-density plasma with use of a microwave.

The microwave treatment in an oxygen-containing atmosphere converts an oxygen gas into plasma using a high-frequency wave such as a microwave or RF and activates the oxygen plasma. The oxygen that acts on the oxide semiconductor has any of a variety of forms such as an oxygen atom, an oxygen molecule, an oxygen ion, and an oxygen radical (also referred to as O radical, which is an atom, a molecule, or an ion having an unpaired electron). Note that the oxygen that acts on the oxide semiconductor may have any one or more of the above forms; an oxygen radical is particularly preferable.

The aforementioned microwave treatment in an oxygen-containing atmosphere is preferably performed while the substrate is heated, in which case the impurity concentration in the semiconductor film 108f can be further reduced. The substrate heating temperature is higher than or equal to 100° C. and lower than or equal to 650° C., preferably higher than or equal to 200° C. and lower than or equal to 600° C., further preferably higher than or equal to 300° C. and lower than or equal to 450° C.

When the microwave treatment in an oxygen-containing atmosphere is performed while the substrate is heated, the carbon concentration in the oxide semiconductor film, which is measured by SIMS, can be lower than 1×10²⁰ atoms/cm³, preferably lower than 1×10¹⁹ atoms/cm³, further preferably lower than 1×10¹⁸ atoms/cm³.

The semiconductor film 108f can have a stacked structure of two or more layers. In that case, the layers may be formed by the same method or different methods. For example, in the case where the semiconductor film 108f has a stacked-layer structure of two layers, the lower layer of the semiconductor film 108f may be formed by a sputtering method and the upper layer of the semiconductor film 108f may be formed by an ALD method. An oxide semiconductor film deposited by a sputtering method is likely to have crystallinity. Thus, when an oxide semiconductor film having crystallinity is provided as the lower layer of the semiconductor film 108f, the crystallinity of the upper layer of the semiconductor film 108f can be increased. Even when a pin hole, disconnection, or the like is formed in the lower layer of the oxide semiconductor film formed by a sputtering method, a portion overlapping therewith can be filled with the upper layer of the semiconductor film 108f formed by an ALD method with favorable coverage.

Heat treatment is preferably performed after the formation of the semiconductor film 108f. The heat treatment can be performed in a temperature range where the oxide semiconductor film does not become polycrystals, i.e., at higher than or equal to 250° C. and lower than or equal to 650° C., preferably higher than or equal to 400° C. and lower than or equal to 600° C. Note that the heat treatment is performed in a nitrogen gas or inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas is approximately 20%. The heat treatment may be performed under reduced pressure. Alternatively, after heat treatment is performed in a nitrogen gas or inert gas atmosphere, the heat treatment may be performed in an atmosphere containing an oxidizing gas at 10 ppm or more, 1% or more, or 10% or more in order to compensate for oxygen released.

The gas used in the above heat treatment is preferably highly purified. For example, the amount of moisture contained in the gas used in the above heat treatment is less than or equal to 1 ppb, preferably less than or equal to 0.1 ppb, further preferably less than or equal to 0.05 ppb. The heat treatment using a highly purified gas can prevent entry of moisture or the like into the oxide semiconductor film, for example, as much as possible.

Although the heat treatment is performed after the formation of the semiconductor film 108f in the above description, the present invention is not limited thereto. The heat treatment may be performed in a later step.

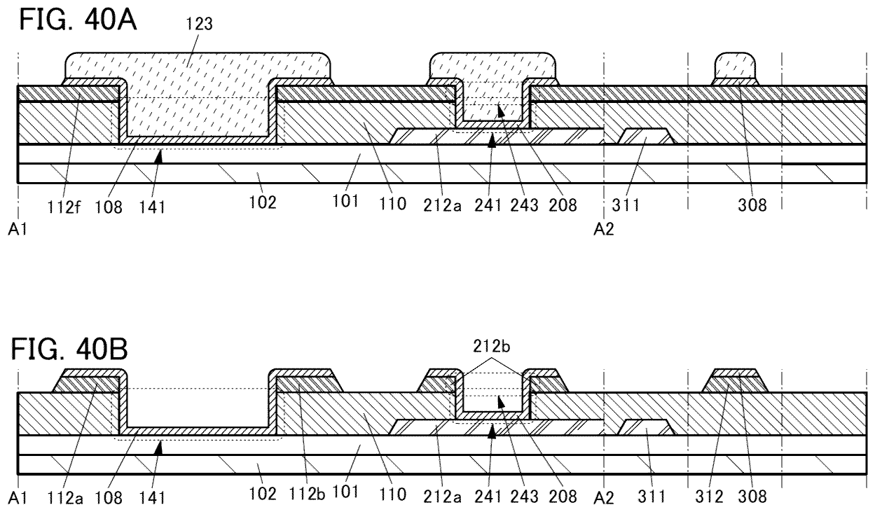

Next, the semiconductor film 108f is processed to form the semiconductor layer 108, the semiconductor layer 208, and the semiconductor layer 308 (FIG. 40A). Specifically, for example, a resist mask 123 reflecting the mask pattern is formed by a photolithography method, and the semiconductor film 108f is processed on the basis of the mask pattern, whereby the semiconductor layer 108, the semiconductor layer 208, and the semiconductor layer 308 are formed. The processing of the semiconductor film 108f can be performed by an etching method, preferably a dry etching method in terms of microfabrication. In the case where a metal oxide film is used as the semiconductor film 108f, the semiconductor layer 108, the semiconductor layer 208, and the semiconductor layer 308 can each be a layer containing a metal oxide.

The semiconductor layer 108 is formed to include a region positioned in the opening portion 141. The semiconductor layer 108 can be formed along the bottom surface and the side surface of the opening portion 141. The semiconductor layer 108 can be formed to include a region in contact with the upper surface of the conductive film 112f and a region in contact with the side surface of the conductive film 112f, for example. Furthermore, the semiconductor layer 108 can be formed to include a region in contact with the upper surface of the insulating layer 101.

The semiconductor layer 208 is formed to include a region positioned in the opening portion 241 and a region positioned in the opening portion 243. The semiconductor layer 208 can be formed along the bottom surface and the side surface of the opening portion 241 and the side surface of the opening portion 243. The semiconductor layer 208 can be formed to include, for example, a region in contact with the upper surface of the conductive layer 112f, a region in contact with the side surface of the conductive layer 112f, and a region in contact with the upper surface of the conductive layer 212a. Furthermore, the semiconductor layer 208 can be formed to include a region in contact with the side surface of the insulating layer 110.

The semiconductor layer 308 is formed over the conductive film 112f. For example, the semiconductor layer 308 is formed so that the lower surface of the semiconductor layer 308 includes a region in contact with the upper surface of the conductive film 112f.

Then, the conductive film 112f is processed to form the conductive layer 112a, the conductive layer 112b, the conductive layer 212b, and the conductive layer 312 over the insulating layer 110 (FIG. 40B). Specifically, the conductive film 112f is processed on the basis of a mask pattern formed by the resist mask 123 without removing the resist mask 123 formed at the time of processing the semiconductor film 108f, for example, whereby the conductive layer 112a, the conductive layer 112b, the conductive layer 212b, and the conductive layer 312 are formed. Thus, processing of the semiconductor film 108f and processing of the conductive film 112f can be performed successively. As described above, the conductive film 112f can be processed by an etching method, and is preferably processed by a dry etching method in terms of microfabrication. Note that the resist mask 123 is removed after the formation of the conductive layer 112a, the conductive layer 112b, the conductive layer 212b, and the conductive layer 312, for example.

As described above, the semiconductor film 108f and the conductive film 112f can be processed on the basis of the same mask pattern. Thus, the semiconductor layer 108, the conductive layer 112a, and the conductive layer 112b can be formed so that the end portion of the semiconductor layer 108, specifically, the end portion of its lower surface outside the opening portion 141 includes the region aligned or substantially aligned with the end portion of the conductive layer 112a, specifically, the end portion of an end portion of an upper surface thereof and the region aligned or substantially aligned with the end portion of the conductive layer 112b, specifically, the end portion of its upper surface. The semiconductor layer 208 and the conductive layer 212b can be formed so that the end portion of the semiconductor layer 208, specifically, the end portion of its lower surface outside the opening portion 243 includes the region aligned or substantially aligned with the end portion of the conductive layer 212b, specifically, the end portion of its upper surface. The semiconductor layer 308 and the conductive layer 312 can be formed so that the end portion of the semiconductor layer 308, specifically, the end portion of its lower surface includes the region aligned or substantially aligned with the end portion of the conductive layer 312, specifically, the end portion of its upper surface.

Thus, the number of manufacturing steps of the semiconductor device can be smaller than that in the case where, between the formation of the conductive film 112f and the formation of the semiconductor film 108f, the conductive film 112f is processed to form the conductive layer 112a, the conductive layer 112b, the conductive layer 212b, and the conductive layer 312 and then the semiconductor film 108f is formed and processed to form the semiconductor layer 108, for example. Accordingly, the manufacturing cost of the semiconductor device can be reduced. The semiconductor device of one embodiment of the present invention can be an inexpensive semiconductor device.

When the semiconductor film 108f and the conductive film 112f have different etching rates, for example, in the direction horizontal to the upper surface of the insulating layer 101, even though the semiconductor film 108f and the conductive film 112f are processed with the same mask pattern, the semiconductor layer 108, the conductive layer 112a, and the conductive layer 112b are sometimes formed so that the end portion of the lower surface of the semiconductor layer 108 outside the opening portion 141 is not aligned with the end portion of the upper surface of the conductive layer 112a and the end portion of the upper surface of the conductive layer 112b. Even in such a case, it can be said that the semiconductor layer 108, the conductive layer 112a, and the conductive layer 112b are formed so that the end portion of the lower surface of the semiconductor layer 108 outside the opening portion 141 is substantially aligned with the end portion of the upper surface of the conductive layer 112a and the end portion of the upper surface of the conductive layer 112b. The semiconductor layer 208 and the conductive layer 212b are sometimes formed so that the end portion of the lower surface of the semiconductor layer 208 outside the opening portion 243 is not aligned with the end portion of the upper surface of the conductive layer 212b. Even in such a case, it can be said that the semiconductor layer 208 and the conductive layer 212b are formed so that the end portion of the lower surface of the semiconductor layer 208 outside the opening portion 243 is substantially aligned with the end portion of the upper surface of the conductive layer 212b. The semiconductor layer 308 and the conductive layer 312 are sometimes formed so that the end portion of the lower surface of the semiconductor layer 308 is not aligned with the end portion of the upper surface of the conductive layer 312. Even in such a case, it can be said that the semiconductor layer 308 and the conductive layer 312 are formed so that the end portion of the lower surface of the semiconductor layer 308 is substantially aligned with the end portion of the upper surface of the conductive layer 312.

The conductive layer 112a and the conductive layer 112b are formed to face each other with the opening portion 141 interposed therebetween in a plan view. The conductive layer 212b is formed to have the opening portion 243.

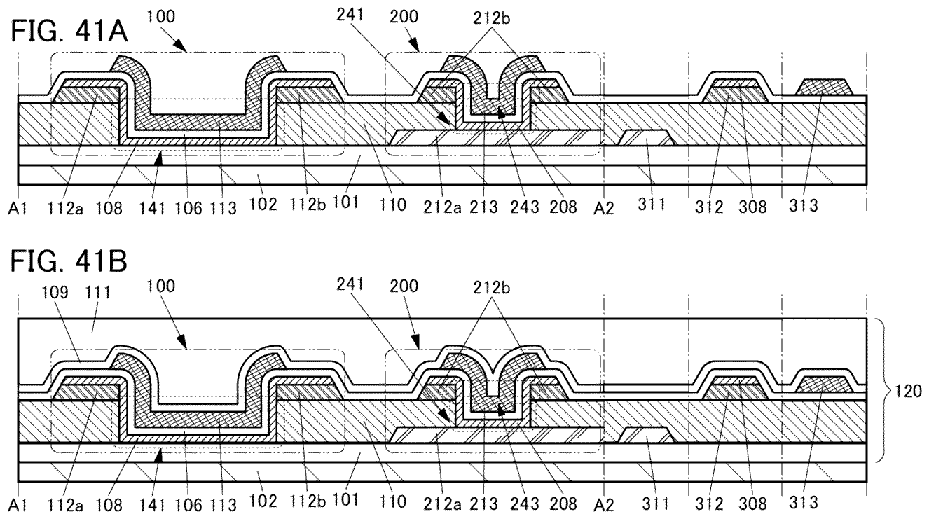

Then, the insulating layer 106 is formed to cover the semiconductor layer 108, the semiconductor layer 208, the semiconductor layer 308, the conductive layer 112a, the conductive layer 112b, the conductive layer 212b, the conductive layer 312, and the insulating layer 110 (FIG. 41A). The insulating layer 106 is formed over the semiconductor layer 108, the semiconductor layer 208, the semiconductor layer 308, and the insulating layer 110 to include a region positioned in the opening portion 141, a region positioned in the opening portion 241, and a region positioned in the opening portion 243. The insulating layer 106 can be formed by an ALD method, a CVD method, or a sputtering method, for example.

In the case of using a metal oxide for the insulating layer 108 and the semiconductor layer 208, the insulating layer 106 preferably functions as a barrier layer inhibiting diffusion of oxygen. When the insulating layer 106 has a function of inhibiting diffusion of oxygen, oxygen contained in the semiconductor layer 108 and the semiconductor layer 208 is inhibited from diffusing to above the insulating layer 106, and an increase in oxygen vacancies (V_{O}) in the semiconductor layer 108 and the semiconductor layer 208 can be suppressed. Consequently, the transistor can exhibit favorable electrical characteristics and have high reliability.

Note that in this specification and the like, a barrier layer refers to an insulating layer having a barrier property. For example, an insulating layer having a barrier property can be referred to as a barrier insulating layer. In this specification and the like, a barrier property means one or both of a function of inhibiting diffusion of a particular substance (or low permeability) and a function of capturing or fixing (also referred to as gettering) a particular substance.

When the temperature at the time of forming the insulating layer 106 functioning as the gate insulating layer is increased, an insulating layer with few defects can be obtained. However, the high temperature at the time of forming the insulating layer 106 sometimes allows release of oxygen from the semiconductor layer 108 and the semiconductor layer 208, which increases the amount of oxygen vacancies (V_{O}) and VoH in the semiconductor layer 108 and the semiconductor layer 208 in some cases. The substrate temperature at the time of forming the insulating layer 106 is preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C. When the substrate temperature at the time of forming the insulating layer 106 is within the above range, release of oxygen from the semiconductor layer 108 and the semiconductor layer 208 can be inhibited while the defects in the insulating layer 106 can be reduced. Consequently, the transistor can exhibit favorable electrical characteristics and have high reliability.

It is preferable to perform plasma treatment on the surfaces of the semiconductor layer 108 and the semiconductor layer 208 before the formation of the insulating layer 106. By the plasma treatment, impurities such as water adsorbed on the surfaces of the semiconductor layer 108 and the semiconductor layer 208 can be reduced. Therefore, impurities at the interface between the semiconductor layer 108 and the insulating layer 106 and the interface between the semiconductor layer 208 and the insulating layer 106 can be reduced, and highly reliable transistors can be provided. The plasma treatment is particularly suitable in the case where the surfaces of the semiconductor layer 108 and the semiconductor layer 208 are exposed to the air in a period between the formation of the semiconductor layer 108 and the semiconductor layer 208 and the formation of the insulating layer 106. For example, plasma treatment can be performed in an atmosphere containing oxygen, ozone, nitrogen, dinitrogen monoxide, argon, or the like. The plasma treatment and the formation of the insulating layer 106 are preferably performed successively without exposure to the air.

Next, a conductive film to be the conductive layer 113, the conductive layer 213, and the conductive layer 313 is formed over the insulating layer 106 and the conductive film is processed, whereby the conductive layer 113, the conductive layer 213, and the conductive layer 313 are formed. Thus, the transistor 100 and the transistor 200 can be manufactured (FIG. 41A).

The conductive layer 113 is formed to include a region positioned in the opening portion 141. The conductive layer 213 is formed to include a region positioned in the opening portion 241 and a region positioned in the opening portion 243. The conductive film to be the conductive layer 113 and the conductive layer 213 can be formed by a CVD method, a sputtering method, or an ALD method, for example. The conductive film can be processed by an etching method and is preferably processed by a dry etching method in terms of microfabrication.

Then, the insulating layer 109 is formed to cover the transistor 100 and the transistor 200. Specifically, the insulating layer 109 is formed to cover the conductive layer 113, the conductive layer 213, the conductive layer 313, and the insulating layer 106 (FIG. 41B). The insulating layer 109 can be formed by a sputtering method, a CVD method, or an ALD method, for example.

Heat treatment may be performed after the formation of the insulating layer 109. Note that the heat treatment is not necessarily performed. The heat treatment is not necessarily performed in this step, and heat treatment performed in a later step may also serve as the heat treatment in this step. In the case where treatment at a high temperature (e.g., film formation step) is performed in a later step, such treatment can serve as the heat treatment in this step in some cases.

Next, the insulating layer 111 is formed over the insulating layer 109 (FIG. 41B). The insulating layer 111 can be formed over the conductive layer 112a, the conductive layer 112b, the conductive layer 113, the conductive layer 212a, the conductive layer 212b, the conductive layer 213, the conductive layer 311, the conductive layer 312, the conductive layer 313, the semiconductor layer 108, the semiconductor layer 208, the semiconductor layer 308, and the insulating layer 106. The insulating layer 111 can be formed by a sputtering method, a CVD method, or an ALD method, for example.

After the formation of the insulating layer 111, planarization treatment is preferably performed on the upper surface of the insulating layer 111. The planarization treatment can be performed by a CMP method, for example.

Heat treatment may be performed after the formation of the insulating layer 109 but is not necessarily performed. Alternatively, heat treatment may be performed after the formation of the insulating layer 111 instead of being performed between the formation of the insulating layer 109 and the formation of the insulating layer 111. Heat treatment after the formation of the insulating layer 111 can be performed after the planarization treatment for the insulating layer 111. Note that heat treatment may be performed between the formation of the insulating layer 111 and the planarization treatment for the insulating layer 111.

The insulating layer 111 is formed in the above manner, whereby the layer 120 including the transistor 100, the transistor 200, and the like can be fabricated.

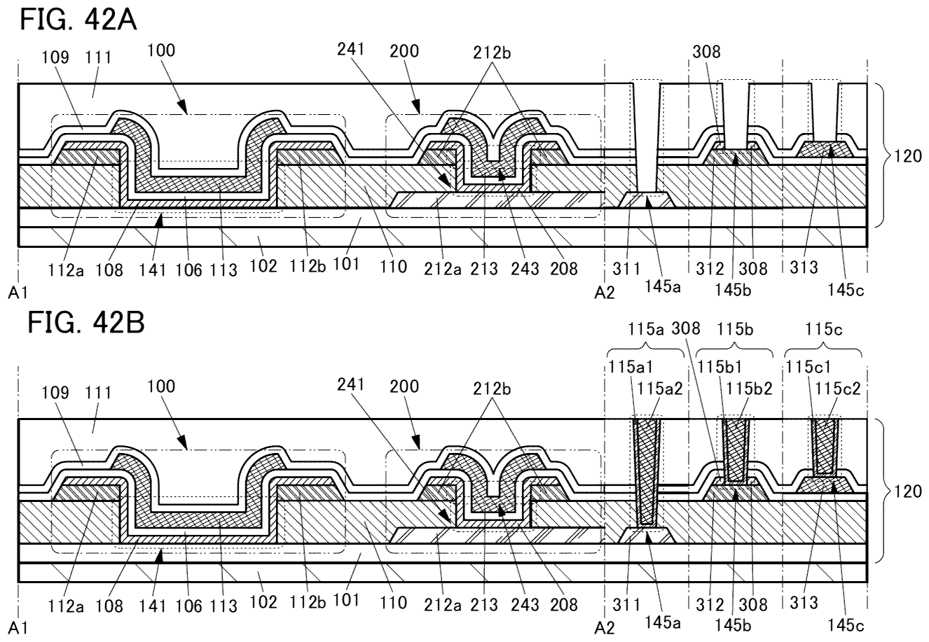

Next, parts of the insulating layer 111, the insulating layer 109, the insulating layer 106, the semiconductor layer 308, and the insulating layer 110 are removed. Thus, the opening portion 145a reaching the conductive layer 311 is formed in the insulating layer 111, the insulating layer 109, the insulating layer 106, and the insulating layer 110. In addition, the opening portion 145b reaching the conductive layer 312 is formed in the insulating layer 111, the insulating layer 109, the insulating layer 106, and the semiconductor layer 308. Furthermore, the opening portion 145c reaching the conductive layer 313 is formed in the insulating layer 111 and the insulating layer 109 (FIG. 42A). An etching method can be used to remove the parts of the insulating layer 111, the insulating layer 109, the insulating layer 106, the semiconductor layer 308, and the insulating layer 110, and a dry etching method is preferably used in terms of microfabrication.

When the opening portion 145a, the opening portion 145b, and the opening portion 145c are formed in parallel, the number of manufacturing steps of the semiconductor device can be smaller than that in the case where the opening portion 145a, the opening portion 145b, and the opening portion 145c are successively formed, for example. The formation in parallel is preferable because the semiconductor device of one embodiment of the present invention can be manufactured at low cost and inexpensive.

In this specification and the like, forming A and B in parallel means that at least part of the step of forming A and at least part of the step of forming B are performed in the same step. In other words, at least part of the step of forming A also serves as at least part of the step of forming B.

An example of a method for forming the opening portion 145a, the opening portion 145b, and the opening portion 145c is described in detail. First, a resist mask reflecting a mask pattern is formed by a photolithography method, for example. Then, the insulating layer 111 and the insulating layer 109 are processed on the basis of the mask pattern, so that the opening portion 145a, the opening portion 145b, and the opening portion 145c are formed in the insulating layer 111 and the insulating layer 109. Then, the insulating layer 106 is processed on the basis of the same mask pattern, so that the opening portion 145a and the opening portion 145b are formed in the insulating layer 106. After that, the insulating layer 110 is processed on the basis of the same mask pattern to form the opening portion 145a in the insulating layer 110, and the semiconductor layer 308 is processed to form the opening portion 145b in the semiconductor layer 308. The insulating layer 110 and the semiconductor layer 308 may be processed in parallel under the same processing conditions or may be successively processed under different processing conditions. In the case of successive processing, the semiconductor layer 308 may be processed after the processing of the insulating layer 110, or the insulating layer 110 may be processed after the processing of the semiconductor layer 308; however, the one that can be processed under conditions closer to those of the processing conditions of the insulating layer 106 is preferably processed first. For example, it is preferable that the insulating layer 110 be processed to form the opening portion 145a and then the semiconductor layer 308 be processed to form the opening portion 145b.

Next, a first conductive film to be the conductive layer 115a1, the conductive layer 115b1 and the conductive layer 115cl is formed to cover the opening portion 145a, the opening portion 145b, and the opening portion 145c. After that, a second conductive film to be the conductive layer 115a2, the conductive layer 115b2, and the conductive layer 115c2 is formed over the first conductive film to be embedded in the opening portion 145a, the opening portion 145b, and the opening portion 145c. For the formation of the first conductive film and the second conductive film, a CVD method, a sputtering method, or an ALD method can be used, for example.

Then, the first conductive film and the second conductive film are removed by a CMP method until the upper surface of the insulating layer 111 is exposed. Consequently, the conductive layer 115a1 is formed along a side surface and a bottom surface of the opening portion 145a, the conductive layer 115bl is formed along a side surface and a bottom surface of the opening portion 145b, and the conductive layer 115c1 is formed along a side surface and a bottom surface of the opening portion 145c. The conductive layer 115a2 is formed over the conductive layer 115a1 to be embedded in the opening portion 145a, the conductive layer 115b2 is formed over the conductive layer 115b1 to be embedded in the opening portion 145b, and the conductive layer 115c2 is formed over the conductive layer 115c1 to be embedded in the opening portion 145c. Through the above steps, the plug 115a is formed to be embedded in the opening portion 145a, the plug 115b is formed to be embedded in the opening portion 145b, and the plug 115c is formed to be embedded in the opening portion 145c (FIG. 42B).

Next, a conductive film to be the conductive layer 117a, the conductive layer 117b, and the conductive layer 117c is formed over the plug 115a, the plug 115b, the plug 115c, and the insulating layer 111, and the conductive film is processed to form the conductive layer 117a, the conductive layer 117b, and the conductive layer 117c (FIG. 3A and FIG. 3D to FIG. 3F). The conductive film to be the conductive layer 117a, the conductive layer 117b, and the conductive layer 117c can be formed by a sputtering method, a CVD method, or an ALD method, for example. The conductive film can be processed by an etching method and is preferably processed by a dry etching method in terms of microfabrication.

Through the above steps, the semiconductor device illustrated in FIG. 3A and FIG. 3D to FIG. 3F can be manufactured.

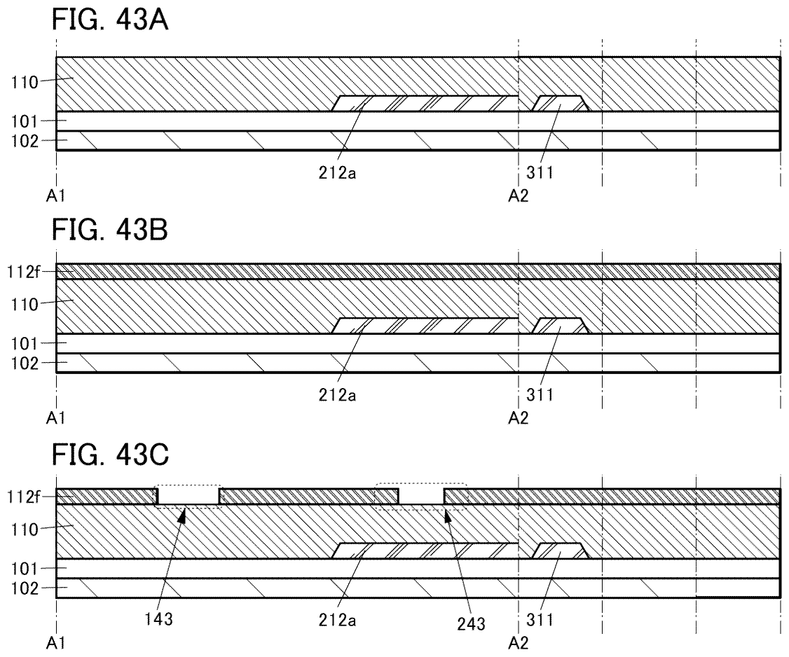

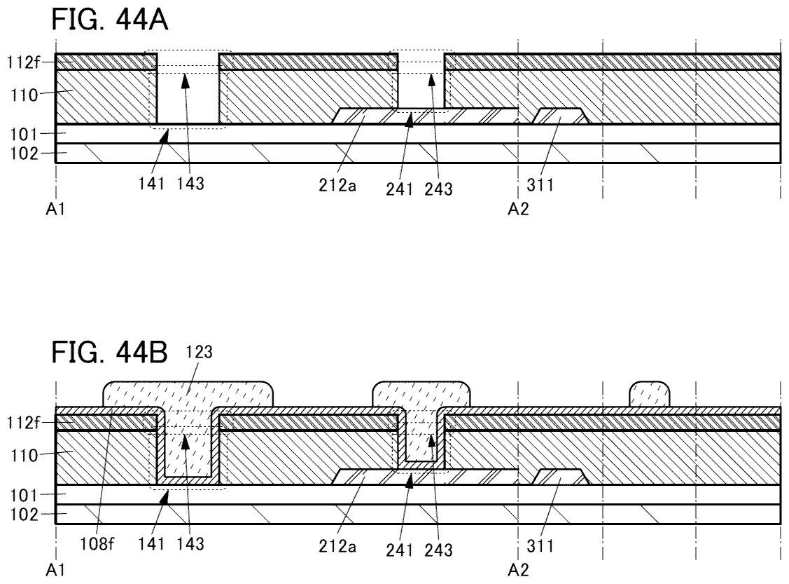

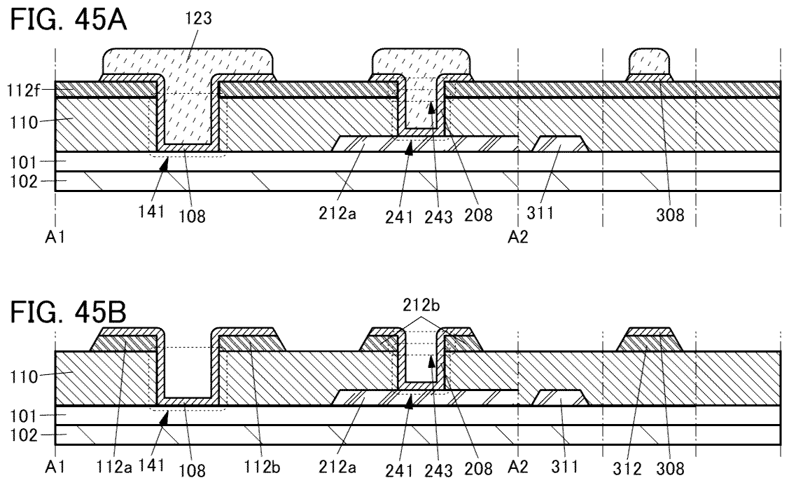

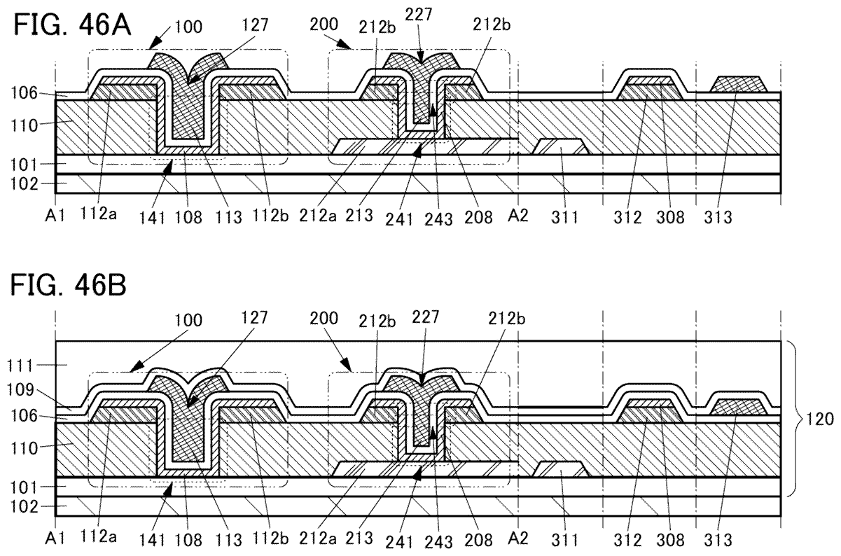

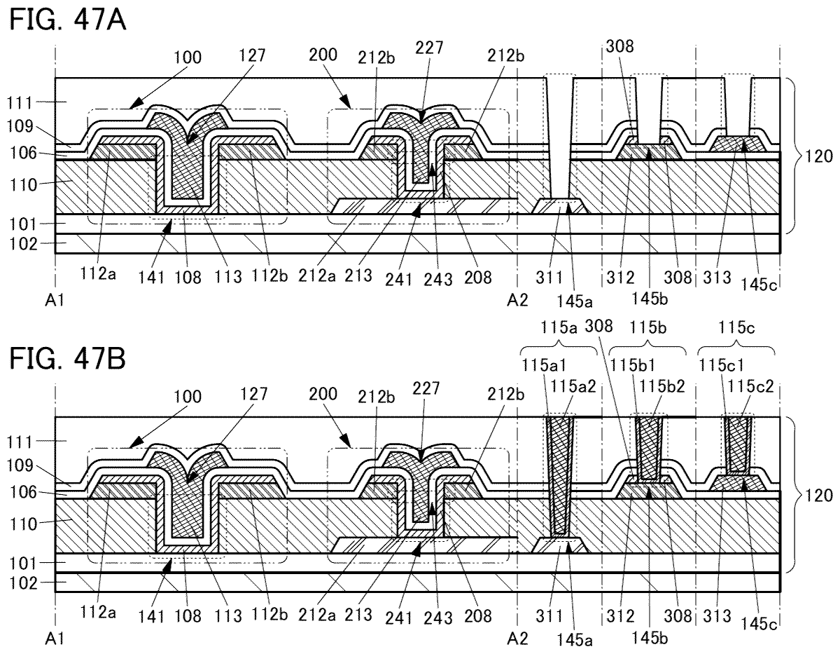

FIG. 43A to FIG. 47B are cross-sectional views showing an example of a method for manufacturing the semiconductor device illustrated in FIG. 8A. FIG. 43A, FIG. 43B, FIG. 43C, FIG. 44A, FIG. 44B, FIG. 45A, FIG. 45B, FIG. 46A, FIG. 46B, FIG. 47A, and FIG. 47B illustrate steps similar to those illustrated in FIG. 38A, FIG. 38B, FIG. 38C, FIG. 39A, FIG. 39B, FIG. 40A, FIG. 40B, FIG. 41A, FIG. 41B, FIG. 42A, and FIG. 42B, respectively. Note that in each of FIG. 43A to FIG. 47B, cross sections corresponding to FIG. 3D to FIG. 3F as well as a cross section corresponding to FIG. 8A are illustrated side by side.

In the step illustrated in FIG. 46A, the conductive layer 113 is formed to be embedded in the opening portion 141, and the conductive layer 213 is formed to be embedded in the opening portion 241. Note that the conductive layer 213 may be formed to be embedded in the opening portion 243.

The conductive layer 113 can be formed so that the portion 127 is provided at a higher position than the upper surface of the insulating layer 110. For example, the conductive layer 113 can be formed so that the level of the portion 127 is higher than the level of the upper surface of the insulating layer 110. In addition, the conductive layer 213 can be formed so that the level of the portion 227 is higher than the level of the upper surface of the insulating layer 110.

The conductive layer 113 can be formed to include the first region positioned outside the opening portion 141 and the second region overlapping with the opening portion 141. The conductive layer 113 can be formed so that the second region includes the portion 127 where the upper surface is the lowest in level. The conductive layer 113 can be formed so that the thickness of the portion 127 is larger than the thickness of the first region.

Similarly, the conductive layer 213 can be formed to include the third region positioned outside the opening portion 241 and the fourth region overlapping with the opening portion 241. The conductive layer 213 can be formed so that the fourth region includes the portion 227 where the upper surface is the lowest in level. The conductive layer 213 can be formed so that the thickness of the portion 227 is larger than the thickness of the third region.

As described above, in the method for manufacturing the semiconductor device of one embodiment of the present invention, a plurality of transistors having different electrical characteristics, for example, can be formed while sharing some steps. For example, the conductive layer 112a and the conductive layer 112b included in the transistor 100 and the conductive layer 212b included in the transistor 200 can be formed in the same step. In addition, the semiconductor layer 108 included in the transistor 100 and the semiconductor layer 208 included in the transistor 200 can be formed in the same step. Furthermore, the conductive layer 113 included in the transistor 100 and the conductive layer 213 included in the transistor 200 can be formed in the same step. Thus, a circuit having desired performance can be easily achieved with reduced manufacturing cost, for example. Consequently, an inexpensive semiconductor device having high performance can be manufactured. For example, in the case where the semiconductor device of one embodiment of the present invention is used for a display device, the display device can be inexpensive and can have high resolution, high reliability, and high driving speed.

The plurality of structure examples described in this specification and the like can be implemented in combination as appropriate. For example, the planar shapes of the opening portion 141, the opening portion 241, and the opening portion 243 illustrated in FIG. 27A, FIG. 27B, FIG. 31A, FIG. 31B, and the like can also be applied to the opening portion 141, the opening portion 241, and the opening portion 243 illustrated in other drawings.

At least part of the structure examples, the drawings corresponding thereto, and the like described in this embodiment can be combined with the other structure examples, the other drawings, and the like as appropriate.

### Embodiment 2

In this embodiment, a structure example of a display device that can employ the semiconductor device of one embodiment of the present invention will be described.

Since the transistor included in the semiconductor device of one embodiment of the present invention can be a transistor having a minute size, a display device employing the semiconductor device of one embodiment of the present invention can have high resolution. For example, the display device of one embodiment of the present invention can be used for display portions of information terminal devices (wearable devices) such as watch-type and bracelet-type information terminal devices and display portions of devices capable of being worn on the head, such as VR devices like head-mounted displays (HMDs) and glasses-type AR devices.

### Display Module

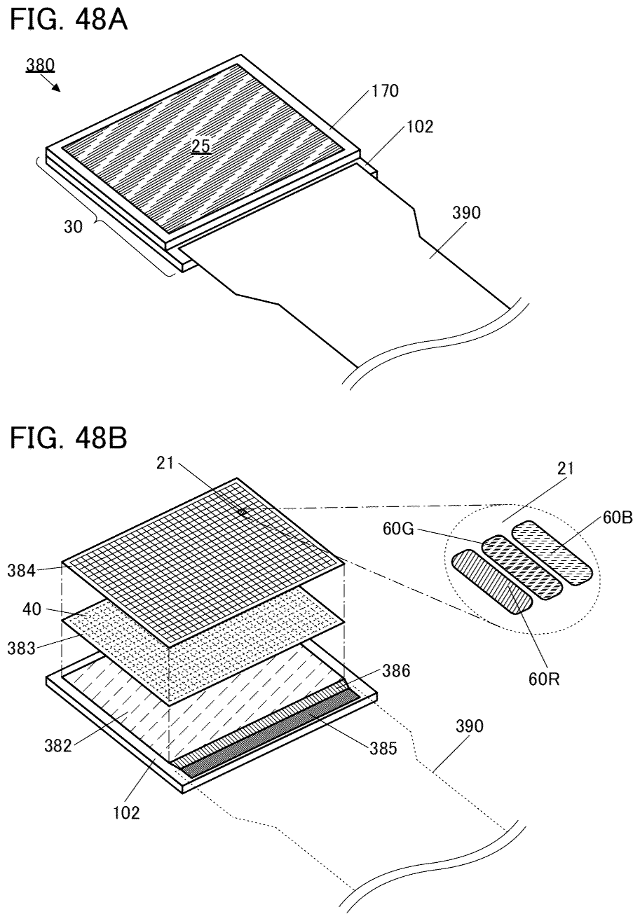

FIG. 48A is a perspective view of a display module 380. The display module 380 includes the display device 30 and an FPC 390.

The display module 380 includes the substrate 102 and a substrate 170. The display module 380 includes the display portion 25. The display portion 25 is a region where an image is displayed.

FIG. 48B is a perspective view schematically illustrating a structure on the substrate 102 side. Over the substrate 102, a circuit portion 382, a pixel circuit portion 383 over the circuit portion 382, and a pixel portion 384 over the pixel circuit portion 383 are stacked. In addition, a terminal portion 385 for connection to the FPC 390 is provided in a portion not overlapping with the pixel portion 384 over the substrate 102. The terminal portion 385 and the circuit portion 382 are electrically connected to each other through a wiring portion 386 formed of a plurality of wirings.

The pixel portion 384 includes a plurality of pixels 21 arranged periodically. An enlarged view of one pixel 21 is shown on the right side of FIG. 48B. The pixel 21 includes a light-emitting element 60R emitting red light, a light-emitting element 60G emitting green light, and a light-emitting element 60B emitting blue light.

The pixel circuit portion 383 includes a plurality of pixel circuits 40 arranged periodically. One pixel circuit 40 is a circuit controlling light emission of three light-emitting elements included in one pixel 21. One pixel circuit 40 may be provided with three circuits for controlling light emission of one light-emitting element. For example, the pixel circuit 40 for one light-emitting element can include at least one selection transistor, one current control transistor (driving transistor), and a capacitor. In that case, a gate signal is input to a gate of the selection transistor, and a source signal is input to a source of the selection transistor. Thus, an active-matrix display panel is obtained. Note that the pixel circuit 40 can also be included in the pixel 21.

The circuit portion 382 includes a circuit for driving the pixel circuits 40 in the pixel circuit portion 383. For example, one or both of a scan line driver circuit and a signal line driver circuit are preferably included. The circuit portion 382 may also include at least one of an arithmetic circuit, a memory circuit, a power supply circuit, and the like. A transistor included in the circuit portion 382 may constitute part of the pixel circuit 40. That is, the pixel circuit 40 may be constituted by a transistor included in the pixel circuit portion 383 and a transistor included in the circuit portion 382.

The FPC 390 functions as a wiring for supplying an image signal, a power supply potential, or the like to the circuit portion 382 from the outside. An IC may be mounted on the FPC 390.

The display module 380 can have a structure where one or both of the pixel circuit portion 383 and the circuit portion 382 are stacked below the pixel portion 384; hence, the aperture ratio (effective display area ratio) of the display portion 25 can be significantly high. For example, the aperture ratio of the display portion 25 can be higher than or equal to 40% and lower than 100%, preferably higher than or equal to 50% and lower than or equal to 95%, further preferably higher than or equal to 60% and lower than or equal to 95%. Furthermore, the pixels 21 can be arranged extremely densely and thus the display portion 25 can have extremely high resolution. For example, the pixels 21 are preferably arranged in the display portion 25 with a resolution of higher than or equal to 2000 ppi, further preferably higher than or equal to 3000 ppi, still further preferably higher than or equal to 5000 ppi, yet still further preferably higher than or equal to 6000 ppi, and lower than or equal to 20000 ppi or lower than or equal to 30000 ppi.

Such a display module 380 has extremely high resolution, and thus can be suitably used for a VR device such as a head-mounted display or a glasses-type AR device. For example, even in the case of a structure where the display portion of the display module 380 is seen through a lens, pixels of the extremely-high-resolution display portion 25 included in the display module 380 are prevented from being recognized when the display portion is enlarged by the lens, so that display providing a high sense of immersion can be performed. Without being limited thereto, the display module 380 can be suitably used for electronic devices including a relatively small display portion. For example, the display module 380 can be favorably used in a display portion of a wearable electronic device, such as a wrist watch.

A display device 30A, a display device 30B, and a display device 30C are described below as display devices that can be used as the display device 30.

### Display Device 30A

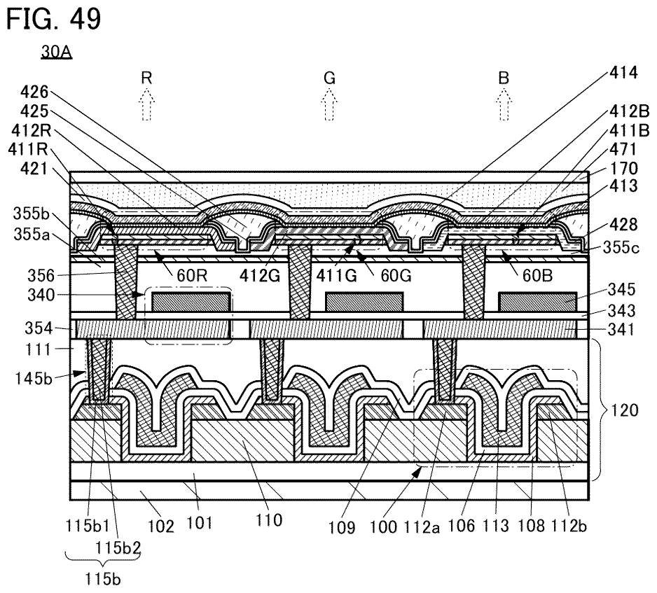

The display device 30A illustrated in FIG. 49 includes the substrate 102, the insulating layer 101, the insulating layer 110, the insulating layer 109, the insulating layer 111, the transistor 100, a capacitor 340, the light-emitting element 60R, the light-emitting element 60G, the light-emitting element 60B, and the like. The transistor 100 includes the conductive layer 112a, the conductive layer 112b, the semiconductor layer 108, the insulating layer 106, the conductive layer 113, and the like. As the transistor 100, a variety of transistors described as examples in Embodiment 1 can be used. The opening portion 145b reaching the conductive layer 112a is provided in the semiconductor layer 108, the insulating layer 106, the insulating layer 109, and the insulating layer 111, and a plug 115b is provided to be embedded in the opening portion 145b.

The substrate 102, the insulating layer 101, the insulating layer 110, the insulating layer 109, the insulating layer 111, and the plug 115b can be formed using any of the materials described as examples in Embodiment 1 and can have any of the functions described as examples in Embodiment 1. FIG. 49 illustrates an example in which the plug 115b includes the conductive layer 115b1 and the conductive layer 115b2. Note that as in Embodiment 1, the insulating layer 111 from the insulating layer 101 are collectively referred to as a layer 120. The transistor 100 is provided in the layer 120, for example.

An insulating layer 354 is provided over the insulating layer 111. Note that a barrier layer that prevents diffusion of impurities such as water or hydrogen from the insulating layer 111, for example, to the transistor 100 may be provided between the insulating layer 111 and the insulating layer 354.

The capacitor 340 is provided over the insulating layer 111. The capacitor 340 includes a conductive layer 341, a conductive layer 345, and an insulating layer 343 positioned therebetween. The conductive layer 341 functions as one electrode of the capacitor 340, the conductive layer 345 functions as the other electrode of the capacitor 340, and the insulating layer 343 functions as a dielectric of the capacitor 340.

The conductive layer 341 is provided over the insulating layer 111 and is embedded in the insulating layer 354. The conductive layer 341 is electrically connected to the conductive layer 112a of the transistor 100 through the plug 115b. The insulating layer 343 is provided to cover the conductive layer 341. The conductive layer 345 is provided in a region overlapping with the conductive layer 341 with the insulating layer 343 therebetween.

An insulating layer 355a is provided to cover the capacitor 340, an insulating layer 355b is provided over the insulating layer 355a, and an insulating layer 355c is provided over the insulating layer 355b.

An inorganic insulating film can be suitably used for each of the insulating layer 354, the insulating layer 343, the insulating layer 355a, the insulating layer 355b, and the insulating layer 355c. Examples of a material that can be used for the inorganic insulating film include an oxide, a nitride, an oxynitride, and a nitride oxide, as described above.

For example, it is preferable that a silicon oxide film be used as each of the insulating layer 355a and the insulating layer 355c and that a silicon nitride film be used as the insulating layer 355b. This enables the insulating layer 355b to function as an etching protective film. Although this embodiment describes an example where the insulating layer 355c is partly etched and a depressed portion is formed, the depressed portion is not necessarily provided in the insulating layer 355c.

The light-emitting element 60R, the light-emitting element 60G, and the light-emitting element 60B are provided over the insulating layer 355c.

The light-emitting element 60R includes a pixel electrode 411R, an organic layer 412R, a common layer 414, and a common electrode 413. The light-emitting element 60G includes a pixel electrode 411G, an organic layer 412G, the common layer 414, and the common electrode 413. The light-emitting element 60B includes a pixel electrode 411B, an organic layer 412B, the common layer 414, and the common electrode 413. The common layer 414 and the common electrode 413 are provided to be shared by the light-emitting element 60R, the light-emitting element 60G, and the light-emitting element 60B.

Hereinafter, the term “light-emitting element 60” is sometimes used to describe matters common to the light-emitting element 60R, the light-emitting element 60G, and the light-emitting element 60B. Similarly, in the description of matters common to components that are distinguished from each other using letters of the alphabet, such as the organic layer 412R, the organic layer 412G, and the organic layer 412B, reference numerals without the letters of the alphabet are sometimes used.

The organic layer 412R included in the light-emitting element 60R contains at least a light-emitting organic compound emitting red light. The organic layer 412G included in the light-emitting element 60G contains at least a light-emitting organic compound emitting green light. The organic layer 412B included in the light-emitting element 60B contains at least a light-emitting organic compound emitting blue light. Each of the organic layer 412R, the organic layer 412G, and the organic layer 412B can also be referred to as an EL layer and includes at least a layer containing a light-emitting organic compound (a light-emitting layer).

In the display device 30A, the light-emitting elements of different emission colors are separately formed; thus, the difference between the chromaticity at low luminance emission and that at high luminance emission is small. Furthermore, since the organic layer 412R, the organic layer 412G, and the organic layer 412B are separated from each other, crosstalk generated between adjacent subpixels can be inhibited while the display panel has high resolution. Accordingly, the display panel can have high resolution and high display quality.

In a region between adjacent light-emitting elements, an insulating layer 425, a resin layer 426, and a layer 428 are provided.

The pixel electrode 411R, the pixel electrode 411G, and the pixel electrode 411B of the light-emitting elements are electrically connected to the conductive layer 112a of the transistor 100 through a plug 356 that is embedded in the insulating layer 355a, the insulating layer 355b, and the insulating layer 355c, the conductive layer 341 that is embedded in the insulating layer 354, and the plug 115b. The upper surface of the insulating layer 355c and the upper surface of the plug 356 are level or substantially level with each other. Any of a variety of conductive materials can be used for the plugs. For the plug 356, a material similar to the material that can be used for the plug 115 can be used, for example.

A protective layer 421 is provided over the light-emitting element 60R, the light-emitting element 60G, and the light-emitting element 60B. The substrate 170 is attached onto the protective layer 421 with an adhesive layer 471.

An insulating layer covering an end portion of the upper surface of the pixel electrode 411 is not provided between two adjacent pixel electrodes 411. Thus, the distance between adjacent light-emitting elements can be extremely shortened. Accordingly, the display device can have high resolution or high definition.

### Display Device 30b

A display device whose structure is partly different from the above-described structure will be described below. Note that the above description is referred to for portions common to those described above, and the description is omitted in some cases.

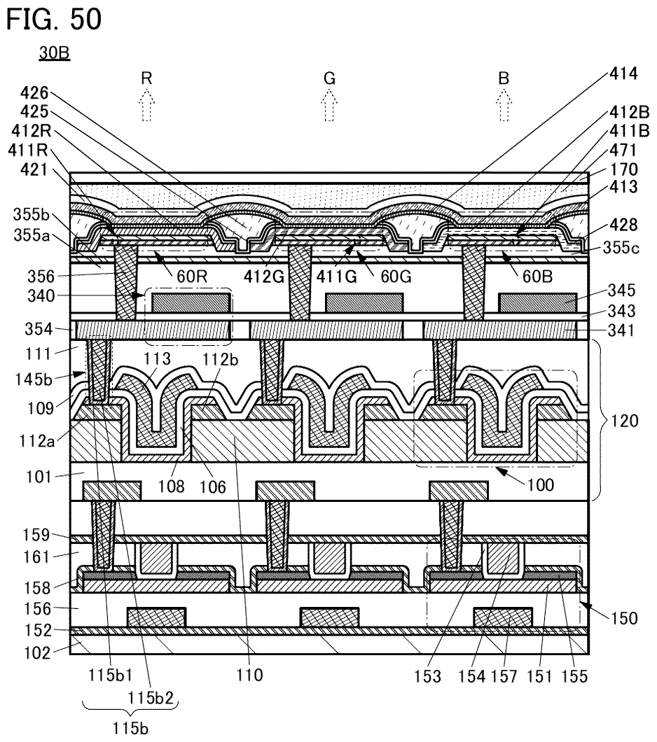

The display device 30B illustrated in FIG. 50 is an example where a transistor 150, which is a planar transistor whose semiconductor layer is formed on a plane, and the transistor 100 in which current flows in both the vertical direction and the lateral direction are stacked.

The transistor 150 includes a semiconductor layer 151, an insulating layer 153, a conductive layer 154, a pair of conductive layers 155, an insulating layer 156, and a conductive layer 157.

An insulating layer 152 is provided over the substrate 102. The insulating layer 152 functions as a barrier layer that prevents diffusion of impurities such as water and hydrogen from the substrate 102 into the transistor 150 and release of oxygen from the semiconductor layer 151 to the insulating layer 152 side. As the insulating layer 152, it is possible to use, for example, a film that is less likely to diffuse one or both of hydrogen and oxygen than a silicon oxide film, such as an aluminum oxide film, a hafnium oxide film, or a silicon nitride film.

The conductive layer 157 is provided over the insulating layer 152, and the insulating layer 156 is provided to cover the conductive layer 157. The conductive layer 157 functions as a first gate electrode of the transistor 150, and part of the insulating layer 156 functions as a first gate insulating layer. An oxide insulating film such as a silicon oxide film is preferably used for at least part of the insulating layer 156 that is in contact with the semiconductor layer 151. The upper surface of the insulating layer 156 is preferably planarized.

The semiconductor layer 151 is provided over the insulating layer 156. The semiconductor layer 151 preferably includes a metal oxide. The pair of conductive layers 155 is provided over and in contact with the semiconductor layer 151, and functions as a source electrode and a drain electrode.

An insulating layer 158 and an insulating layer 161 are provided to cover the upper surfaces and the side surfaces of the pair of conductive layers 155, the side surfaces of the semiconductor layer 151, and the like. The insulating layer 158 functions as a barrier layer that prevents diffusion of impurities such as water and hydrogen into the semiconductor layer 151 and release of oxygen from the semiconductor layer 151. As the insulating layer 158, an insulating film similar to the insulating layer 152 can be used.

An opening portion reaching the semiconductor layer 151 is provided between one of the pair of conductive layers 155 and the other thereof in the insulating layer 158 and the insulating layer 161 in a plan view. The conductive layer 154 and the insulating layer 153 that is in contact with the upper surface of the semiconductor layer 151 are embedded in the opening portion. The conductive layer 154 functions as a second gate electrode, and the insulating layer 153 functions as a second gate insulating layer.

The upper surface of the conductive layer 154, the upper surface of the insulating layer 153, and the upper surface of the insulating layer 161 are subjected to planarization treatment so as to be level or substantially level with each other, and an insulating layer 159 is provided to cover these layers. The insulating layer 159 functions as a barrier layer that prevents diffusion of impurities such as water and hydrogen into the transistor 100 and the transistor 150. As the insulating layer 159, an insulating film similar to the insulating layer 152 can be used.

The transistor 150 employs a structure where the semiconductor layer where a channel is formed is interposed between two gates. The two gates may be connected to each other and supplied with the same signal to drive the transistor. Alternatively, a potential for controlling the threshold voltage may be supplied to one of the two gates and a potential for driving may be supplied to the other to control the threshold voltage of the transistor 150.

### Display Device 30c

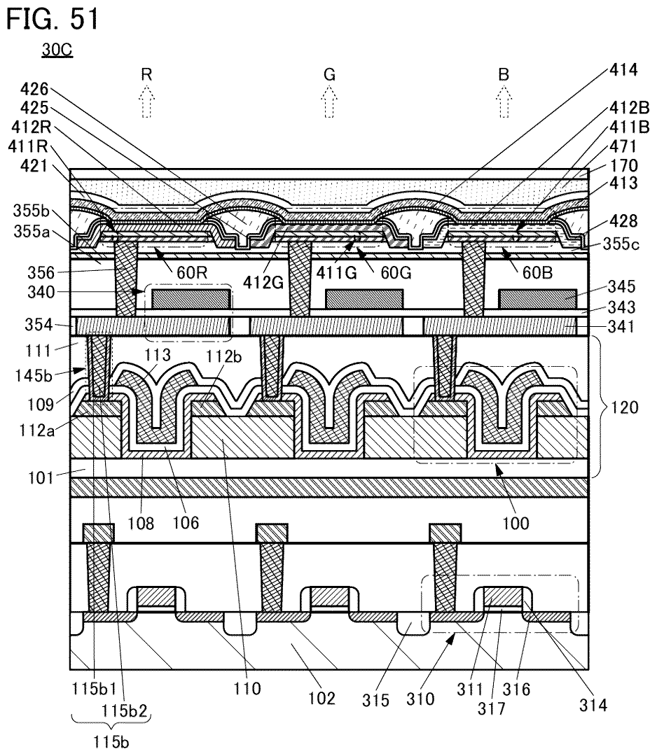

The display device 30C illustrated in FIG. 51 has a structure where a transistor 310 whose channel is formed in the semiconductor substrate and the transistor 100 in which current flows in both the vertical direction and the lateral direction are stacked.

The transistor 310 includes a channel formation region in the substrate 102. As the substrate 102 included in the display device 30C, a semiconductor substrate such as a single crystal silicon substrate can be used, for example. The transistor 310 includes part of the substrate 102, a conductive layer 311, a low-resistance region 316, an insulating layer 317, and an insulating layer 314. The conductive layer 311 functions as a gate electrode. The insulating layer 317 is positioned between the substrate 102 and the conductive layer 311 and functions as a gate insulating layer. The low-resistance region 316 is a region where the substrate 102 is doped with an impurity, and functions as one of a source and a drain. The insulating layer 314 is provided to cover the side surface of the conductive layer 311.

An element isolation layer 315 is provided between two adjacent transistors 310 to be embedded in the substrate 102.

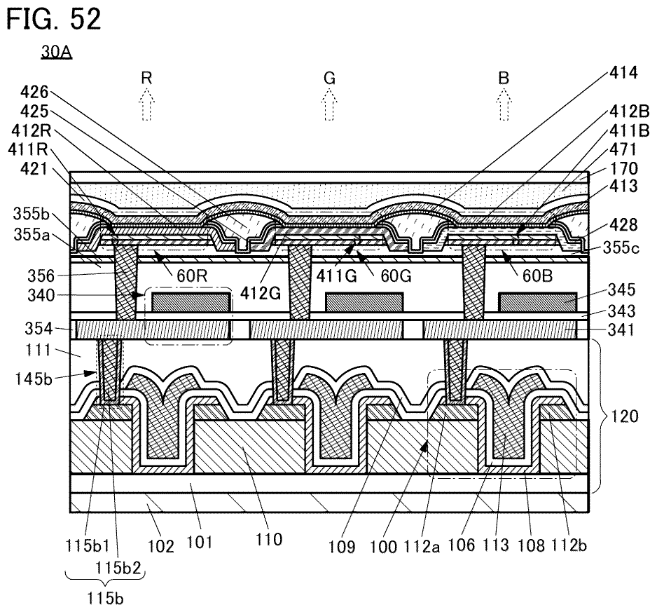

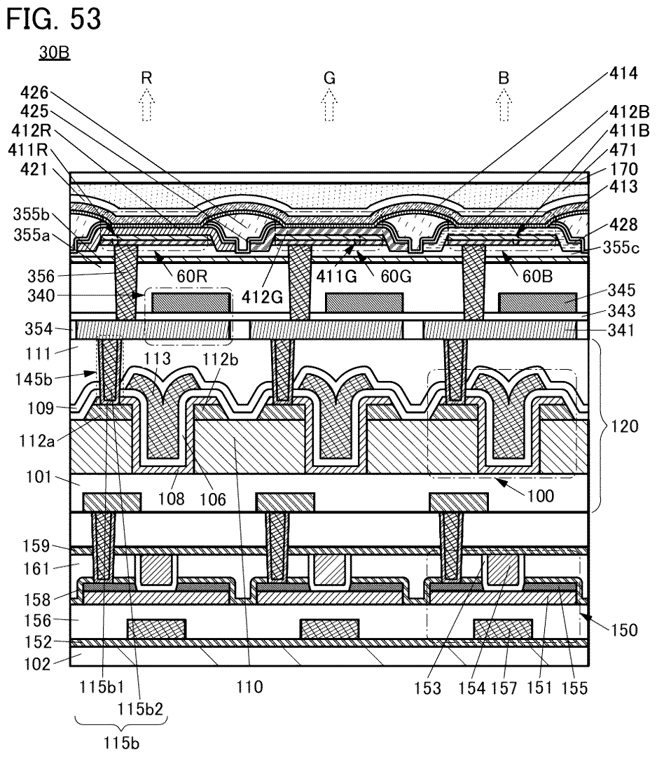

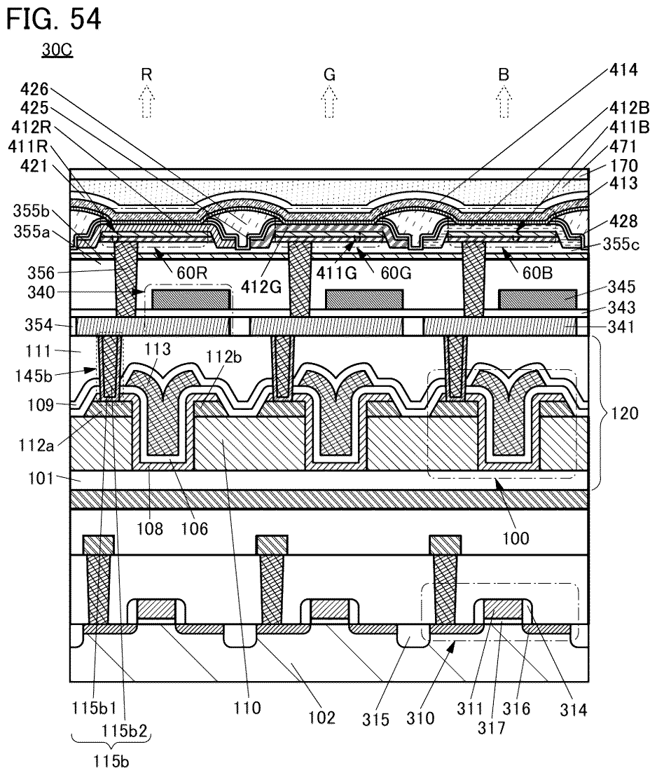

Although FIG. 49, FIG. 50, and FIG. 51 illustrate examples where the transistor 100 has the structure illustrated in FIG. 3A, for example, one embodiment of the present invention is not limited thereto. FIG. 52, FIG. 53, and FIG. 54 each illustrate an example in which the transistor 100 illustrated in FIG. 49, FIG. 50, and FIG. 51 has a structure illustrated in FIG. 8A, for example.

Structure examples of the light-emitting element 60R, the light-emitting element 60G, and the light-emitting element 60B that are different from those in FIG. 49 to FIG. 54 are described below.

As described above, one embodiment of the present invention is a display device including a light-emitting element. The display device includes two or more pixels of different emission colors. The pixels include light-emitting elements. For example, three kinds of light-emitting elements emitting red (R), green (G), and blue (B) light are included, whereby a full-color display device can be obtained.

In the case of manufacturing a display device including a plurality of light-emitting elements of different emission colors, at least layers (light-emitting layers) containing light-emitting materials each need to be formed in an island shape. In the case of separately forming part or the whole of an EL layer, a method for forming an island-shaped organic film by an evaporation method using a shadow mask such as a metal mask is known. However, this method causes a deviation from the designed shape and position of the island-shaped organic film due to various effects such as the accuracy of the metal mask, the positional deviation between the metal mask and a substrate, a warp of the metal mask, and expansion of the outline of a formed film due to vapor scattering, for example; accordingly, it is difficult to achieve a high resolution and a high aperture ratio of the display device. In addition, the outline of the film might blur during evaporation, so that the thickness of an end portion might be reduced. That is, the thickness of an island-shaped light-emitting layer might vary from place to place. In addition, in the case of manufacturing a display device with a large size, high definition, or high resolution, a manufacturing yield might be reduced because of low dimensional accuracy of the metal mask and deformation due to heat or the like. Thus, a measure has been taken for a pseudo increase in resolution (also referred to as pixel density) by employing a unique pixel arrangement such as PenTile arrangement, for example.

In one embodiment of the present invention, fine patterning of EL layers is performed by a photolithography method and an etching method without using a shadow mask such as a fine metal mask (an FMM). Accordingly, it is possible to obtain a display device with high resolution and a high aperture ratio, which has been difficult to obtain. Moreover, since the EL layers can be formed separately, it is possible to obtain a display device that performs extremely clear display with high contrast and high display quality. Note that the EL layer may be processed into a fine pattern by both a method using a metal mask and a method using a photolithography method and an etching method, for example.

In addition, part or the whole of an EL layer can be physically divided. This can inhibit leakage current flowing between adjacent light-emitting elements through a layer (also referred to as a common layer) shared by the light-emitting elements. This can prevent crosstalk due to unintended light emission, so that a display device with extremely high contrast can be obtained. Specifically, a display device having high current efficiency at low luminance can be obtained.

In one embodiment of the present invention, the display device can also be obtained by combining a light-emitting element emitting white light with a color filter. In that case, light-emitting elements having the same structure can be used as light-emitting elements provided in pixels (subpixels) that emit light of different colors, which allows all the layers to be common layers. In addition, part or the whole of each EL layer may be divided by a photolithography method and an etching method. Thus, leakage current through the common layer is inhibited; accordingly, a high-contrast display device can be obtained. In particular, when an element has a tandem structure where a plurality of light-emitting layers are stacked with a highly conductive intermediate layer therebetween, leakage current through the intermediate layer can be effectively prevented, so that a display device with high luminance, high resolution, and high contrast can be obtained.

In the case where the EL layer is processed by a photolithography method and an etching method, part of the light-emitting layer is sometimes exposed to cause deterioration. Thus, an insulating layer covering at least the side surface of the island-shaped light-emitting layer is preferably provided. The insulating layer may cover part of the upper surface of the island-shaped EL layer. For the insulating layer, a material having a barrier property against water and oxygen is preferably used. For example, an inorganic insulating film that is less likely to diffuse water or oxygen can be used. This can inhibit deterioration of the EL layer, so that a highly reliable display device can be obtained.

Moreover, between two adjacent light-emitting elements, there is a region (a depressed portion) where none of the EL layers of the light-emitting elements is provided. In the case where a common electrode or a common electrode and a common layer are formed to cover the depressed portion, a phenomenon where the common electrode is divided by a step at an end portion of the EL layer (such a phenomenon is also referred to as disconnection) might occur, which might cause insulation of the common electrode over the EL layer. In view of this, a structure is preferably employed where a local gap positioned between two adjacent light-emitting elements is filled with a resin layer functioning as a planarization film (also referred to as LFP: Local Filling Planarization). The resin layer has a function of the planarization film. This structure can inhibit disconnection of the common layer or the common electrode, so that a highly reliable display device can be obtained.

More specific structure examples of the display device of one embodiment of the present invention will be described below with reference to drawings.

### Structure Example 1

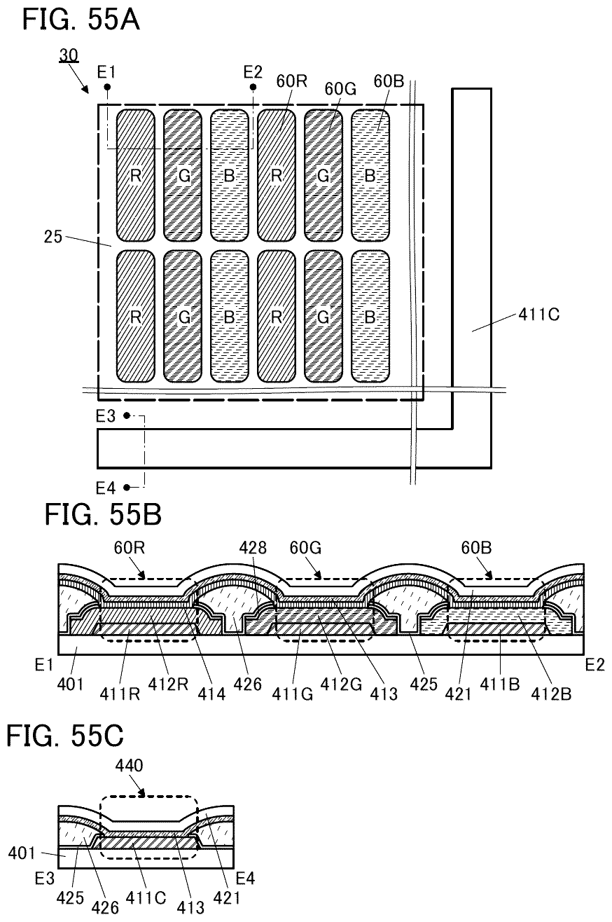

FIG. 55A illustrates a schematic top view of the display device 30 of one embodiment of the present invention. As described above, the display device 30 includes the display portion 25. The display device 30 includes, over a layer 401, a plurality of light-emitting elements 60R emitting red light, a plurality of light-emitting elements 60G emitting green light, and a plurality of light-emitting elements 60B emitting blue light. In FIG. 55A, light-emitting regions of the light-emitting elements are denoted by R, G, and B to easily differentiate the light-emitting elements. Here, the components from the substrate 102 to the insulating layer 355c illustrated in FIG. 49 to FIG. 54 can be included in the layer 401.

The light-emitting elements 60R, the light-emitting elements 60G, and the light-emitting elements 60B are arranged in a matrix in the display portion 25. FIG. 55A illustrates what is called stripe arrangement, in which the light-emitting elements of the same color are arranged in one direction. Note that an arrangement method of the light-emitting elements is not limited thereto; an arrangement method such as S-stripe arrangement, delta arrangement, Bayer arrangement, or zigzag arrangement may be employed, or PenTile arrangement, diamond arrangement, or the like can be also used.

FIG. 55A illustrates a connection electrode 411C electrically connected to the common electrode 413. The connection electrode 411C is supplied with a potential (e.g., an anode potential or a cathode potential) that is to be supplied to the common electrode 413. The connection electrode 411C is provided outside a display region where the light-emitting elements 60R, the light-emitting elements 60G, the light-emitting elements 60B, and the like are arranged.

The connection electrode 411C can be provided along the outer periphery of the display region. For example, the connection electrode 411C may be provided along one side of the outer periphery of the display region or may be provided along two or more sides of the outer periphery of the display region. In other words, in the case where the shape seen from above (also referred to as upper surface shape) of the display region is rectangular, the upper surface shape of the connection electrode 411C can be a band shape (a rectangle), an L-like shape, a U-like shape (a square bracket shape), a quadrangle, or the like.

FIG. 55B is a cross-sectional view of a cut plane along the dashed-dotted line E1-E2 in FIG. 55A. FIG. 55C is a cross-sectional view of a cut plane along the dashed-dotted line E3-E4 in FIG. 55A. FIG. 55B illustrates a schematic cross-sectional view of the light-emitting element 60R, the light-emitting element 60G, and the light-emitting element 60B, and FIG. 55C illustrates a schematic cross-sectional view of a connection portion 440 where the connection electrode 411C and the common electrode 413 are connected to each other.

As described above, the light-emitting element 60R includes the pixel electrode 411R, the organic layer 412R, the common layer 414, and the common electrode 413. The light-emitting element 60G includes a pixel electrode 411G, an organic layer 412G, the common layer 414, and the common electrode 413. The light-emitting element 60B includes a pixel electrode 411B, an organic layer 412B, the common layer 414, and the common electrode 413. The common layer 414 and the common electrode 413 are provided to be shared by the light-emitting element 60R, the light-emitting element 60G, and the light-emitting element 60B.

Each of the organic layer 412 and the common layer 414 can independently include one or more of an electron-injection layer, an electron-transport layer, a hole-injection layer, and a hole-transport layer. For example, it is possible to employ a structure where the organic layer 412 includes a stacked-layer structure of a hole-injection layer, a hole-transport layer, a light-emitting layer, and an electron-transport layer from the pixel electrode 411 side and the common layer 414 includes an electron-injection layer.

The protective layer 421 is provided over the common electrode 413 to cover the light-emitting element 60R, the light-emitting element 60G, and the light-emitting element 60B. The protective layer 421 has a function of preventing diffusion of impurities such as water into each light-emitting element from the above.

An end portion of the pixel electrode 411 preferably has a tapered shape. In the case where the pixel electrode 411 has an end portion with a tapered shape, the organic layer 412 that is provided along the end portion of the pixel electrode 411 can also have a tapered shape. When the end portion of the pixel electrode 411 has a tapered shape, coverage with the organic layer 412 provided beyond the end portion of the pixel electrode 411 can be increased. Furthermore, when the side surface of the pixel electrode 411 has a tapered shape, a foreign substance (for example, also referred to as dust or particles) in a manufacturing step is easily removed by processing such as cleaning, which is preferable.

In this specification and the like, a tapered shape refers to a shape such that at least part of a side surface of a component is inclined with respect to a substrate surface. For example, the tapered shape preferably includes a region where an angle formed between the inclined side surface and the substrate surface (the angle is also referred to as a taper angle) is less than 90°.

The organic layer 412 is processed into an island shape by a photolithography method and an etching method. Thus, an angle formed between an upper surface and a side surface of an end portion of the organic layer 412 is approximately 90°. In contrast, an organic film formed using an FMM (Fine Metal Mask) or the like tends to be gradually thinner in a portion closer to its end portion, and has a sloped upper surface in the range greater than or equal to 1 μm and less than or equal to 10 μm, for example; thus, such a shape is difficult to distinguish the upper surface and the side surface from each other.

As described above, in a region between adjacent light-emitting elements, the insulating layer 425, the resin layer 426, and the layer 428 are provided.

Between two adjacent light-emitting elements, side surfaces of the organic layers 412 are provided to face each other with the resin layer 426 interposed therebetween. The resin layer 426 is positioned between the two adjacent light-emitting elements and is provided to fill end portions of the organic layers 412 and a region between the two organic layers 412. The resin layer 426 has an upper surface with a smooth projecting shape, and the common layer 414 and the common electrode 413 are provided to cover the upper surface of the resin layer 426.

The resin layer 426 functions as a planarization film that fills a step positioned between two adjacent light-emitting elements. Providing the resin layer 426 can prevent a phenomenon in which the common electrode 413 is divided by a step at an end portion of the organic layer 412 (such a phenomenon is also referred to as disconnection) from occurring and the common electrode over the organic layer 412 from being insulated. The resin layer 426 can also be referred to as an LFP (Local Filling Planarization) layer.

An insulating layer containing an organic material can be suitably used as the resin layer 426. For the resin layer 426, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of these resins, or the like can be used, for example. For the resin layer 426, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin may be used.

Alternatively, a photosensitive resin can be used for the resin layer 426. A photoresist may be used as the photosensitive resin. As the photosensitive resin, a positive material or a negative material can be used.

The resin layer 426 may contain a material absorbing visible light. For example, the resin layer 426 itself may be made of a material absorbing visible light, or the resin layer 426 may contain a pigment absorbing visible light. For example, for the resin layer 426, it is possible to use a resin that can be used for a color filter transmitting red, blue, or green light and absorbing other light, a resin that contains carbon black as a pigment and functions as a black matrix, or the like.

The insulating layer 425 is provided in contact with the side surfaces of the organic layers 412. In addition, the insulating layer 425 is provided to cover an end portion of the upper surface of the organic layer 412. Furthermore, part of the insulating layer 425 is provided in contact with the upper surface of the layer 401.

The insulating layer 425 is positioned between the resin layer 426 and the organic layer 412 and functions as a protective film for preventing contact between the resin layer 426 and the organic layer 412. When the organic layer 412 and the resin layer 426 are in contact with each other, the organic layer 412 might be dissolved by an organic solvent used at the time of forming the resin layer 426, for example. Therefore, a structure can be employed where the insulating layer 425 is provided between the organic layer 412 and the resin layer 426 to protect the side surface of the organic layer 412.

An insulating layer containing an inorganic material can be used as the insulating layer 425. For the insulating layer 425, an inorganic insulating film such as an oxide insulating film, a nitride insulating film, an oxynitride insulating film, or a nitride oxide insulating film can be used, for example. The insulating layer 425 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, when a metal oxide film such as an aluminum oxide film or a hafnium oxide film or an inorganic insulating film such as a silicon oxide film that is formed by an ALD method is employed for the insulating layer 425, it is possible to form the insulating layer 425 having few of pinholes and an excellent function of protecting the EL layer.

The insulating layer 425 can be formed by a sputtering method, a CVD method, a PLD method, an ALD method, or the like. The insulating layer 425 is preferably formed by an ALD method offering good coverage.

In addition, a structure may be employed where a reflective film (e.g., a metal film containing one or more selected from silver, palladium, copper, titanium, aluminum, and the like) is provided between the insulating layer 425 and the resin layer 426 so that light emitted from the light-emitting layer is reflected by the reflective film. This can improve light extraction efficiency.

The layer 428 is a remaining part of a protective layer (also referred to as a mask layer or a sacrificial layer) for protecting the organic layer 412 during etching of the organic layer 412. For the layer 428, a material that can be used for the insulating layer 425 can be used. It is particularly preferable to use the same material for the layer 428 and the insulating layer 425 because an apparatus for processing, for example, can be used in common.

In particular, since a metal oxide film such as an aluminum oxide film or a hafnium oxide film or an inorganic insulating film such as a silicon oxide film that is formed by an ALD method has few pinholes, such a film has an excellent function of protecting the EL layer and can be suitably used for the insulating layer 425 and the layer 428.

The protective layer 421 can have, for example, a single-layer structure or a stacked-layer structure including at least an inorganic insulating film. Examples of the inorganic insulating film include an oxide film and a nitride film, such as a silicon oxide film, a silicon oxynitride film, a silicon nitride oxide film, a silicon nitride film, an aluminum oxide film, an aluminum oxynitride film, and a hafnium oxide film. Alternatively, a semiconductor material or a conductive material such as an indium gallium oxide, an indium zinc oxide, an indium tin oxide, or an indium gallium zinc oxide may be used for the protective layer 421.

For the protective layer 421, a stacked-layer film of an inorganic insulating film and an organic insulating film can also be used. For example, a structure where an organic insulating film is interposed between a pair of inorganic insulating films is preferable. Furthermore, the organic insulating film preferably functions as a planarization film. This enables the upper surface of the organic insulating film to be flat, which results in improved coverage with the inorganic insulating film thereover and a higher barrier property. Moreover, the upper surface of the protective layer 421 is flat, which is preferable because the influence of an uneven shape due to a lower structure can be reduced in the case where a component (e.g., a color filter, an electrode of a touch sensor, a lens array, or the like) is provided above the protective layer 421.

FIG. 55C illustrates the connection portion 440 where the connection electrode 411C and the common electrode 413 are electrically connected to each other. In the connection portion 440, an opening portion is provided in the insulating layer 425 and the resin layer 426 over the connection electrode 411C. The connection electrode 411C and the common electrode 413 are electrically connected to each other in the opening portion.

Note that although FIG. 55C illustrates the connection portion 440 where the connection electrode 411C and the common electrode 413 are electrically connected to each other, the common electrode 413 may be provided over the connection electrode 411C with the common layer 414 therebetween. For example, in the case where a carrier-injection layer is used as the common layer 414, a material used for the common layer 414 has sufficiently low electrical resistivity and the common layer 414 can be formed to be thin; thus, problems do not arise in many cases even when the common layer 414 is positioned in the connection portion 440. Accordingly, the common electrode 413 and the common layer 414 can be formed using the same shielding mask, so that manufacturing cost can be reduced.

### Structure Example 2

A display device whose structure is partly different from that in the above-described structure example 1 is described below. Note that the above description is referred to for portions common to those in the above-described structure example 1, and the description is omitted in some cases.

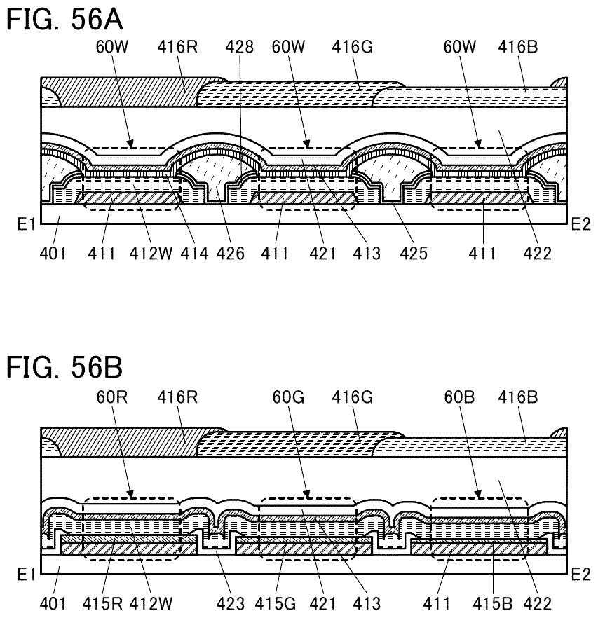

FIG. 56A shows a modification example of the structure illustrated in FIG. 55B, in which the light-emitting element has a different structure and a coloring layer is included.

In the example illustrated in FIG. 56A, the display device 30 includes a light-emitting element 60W emitting white light. The light-emitting element 60W includes the pixel electrode 411, an organic layer 412W, the common layer 414, and the common electrode 413. The organic layer 412W emits white light. For example, the organic layer 412W can have a structure containing two or more kinds of light-emitting materials whose emission colors have a relationship of complementary colors. For example, the organic layer 412W can have a structure containing a light-emitting organic compound emitting red light, a light-emitting organic compound emitting green light, and a light-emitting organic compound emitting blue light. Alternatively, the organic layer 412W may have a structure containing a light-emitting organic compound emitting blue light and a light-emitting organic compound emitting yellow light.

The organic layer 412W is divided between two adjacent light-emitting elements 60W. Thus, leakage current flowing between the adjacent light-emitting elements 60W through the organic layer 412W can be inhibited and crosstalk due to the leakage current can be inhibited. Accordingly, the display device can have high contrast and high color reproducibility.

An insulating layer 422 functioning as a planarization film is provided over the protective layer 421, and a coloring layer 416R, a coloring layer 416G, and a coloring layer 416B are provided over the insulating layer 422. Hereinafter, the term “coloring layer 416” is sometimes used to describe matters common to the coloring layer 416R, the coloring layer 416G, and the coloring layer 416B.

In the coloring layer 416, the transmittance of light with a specific wavelength is higher than that of light with other wavelengths. Thus, the coloring layer 416 has a function of transmitting light of a specific color. For example, the coloring layer 416R has a function of transmitting red light, the coloring layer 416G has a function of transmitting green light, and the coloring layer 416B has a function of transmitting blue light. Here, one light-emitting element 60W includes a region overlapping with one of the coloring layer 416R, the coloring layer 416G, and the coloring layer 416B. Thus, even when light emitted from the light-emitting element 60W is white light, for example, the display portion 25 can emit red light, green light, and blue light to perform full-color display, for example.

Examples of a material that can be used for the coloring layer 416 include a metal material, a resin material, and a resin material containing a pigment or dye. The coloring layer 416 can be formed by an inkjet method, for example.

An organic resin film or an inorganic insulating film with a flat upper surface can be used for the insulating layer 422. Since the insulating layer 422 serves as the formation surface of the coloring layer 416R, the coloring layer 416G, and the coloring layer 416B, the flat upper surface of the insulating layer 422 can inhibit formation of unevenness on the upper surfaces of the coloring layer 416R, the coloring layer 416G, and the coloring layer 416B. In that case, the thickness of the coloring layer 416R can be uniform, the thickness of the coloring layer 416G can be uniform, and the thickness of the coloring layer 416B can be uniform. Accordingly, the color purity of an image displayed on the display portion 25 can be increased. Note that when the thickness of the coloring layer 416 is non-uniform, the amount of light absorption varies from place to place in the coloring layer 416, which might decrease the color purity.

FIG. 56A illustrates an example where the coloring layers 416 that transmit light of different wavelengths overlap with each other over the resin layer 426. This can inhibit, for example, light emitted from the light-emitting element 60W overlapping with the coloring layer 416G from being transmitted through the adjacent coloring layer 416R or the adjacent coloring layer 416B and emitted to the outside of the display device. In that case, the contrast of an image displayed on the display portion 25 can be increased as compared with the case where the coloring layers 416 that transmit light of different wavelengths do not overlap with each other.

### Structure Example 3

FIG. 56B illustrates a modification example of the structure illustrated in FIG. 55B. In the case where the display device 30 has the structure illustrated in FIG. 56B, the light-emitting element 60R includes the pixel electrode 411, a conductive layer 415R, the organic layer 412W, and the common electrode 413. The light-emitting element 60G includes the pixel electrode 411, a conductive layer 415G, the organic layer 412W, and the common electrode 413. The light-emitting element 60B includes the pixel electrode 411, a conductive layer 415B, the organic layer 412W, and the common electrode 413. The conductive layer 415R, the conductive layer 415G, and the conductive layer 415B each have a light-transmitting property and function as an optical adjustment layer.

A film reflecting visible light is used for the pixel electrode 411 and a film having both properties of reflecting and transmitting visible light is used for the common electrode 413, so that a micro resonator (microcavity) structure can be obtained. In that case, by adjusting the thicknesses of the conductive layer 415R, the conductive layer 415G, and the conductive layer 415B to obtain an optimal optical path length, light of different wavelengths and increased intensities can be obtained from the light-emitting element 60R, the light-emitting element 60G, and the light-emitting element 60B even when the organic layer 412 emitting white light is used.

Furthermore, the coloring layer 416R, the coloring layer 416G, and the coloring layer 416B are provided on the optical paths of the light-emitting element 60R, the light-emitting element 60G, and the light-emitting element 60B, respectively, whereby light with high color purity can be obtained. When the coloring layers 416 that transmit light of different wavelengths overlap with each other over an insulating layer 423, the contrast of an image displayed on the display portion 25 can be increased.

In addition, the insulating layer 423 covering an end portion of the pixel electrode 411, an end portion of the conductive layer 415R, an end portion of the conductive layer 415G, and an end portion of the conductive layer 415B is provided. An end portion of the insulating layer 423 preferably has a tapered shape. When the insulating layer 423 is provided, coverage with the organic layer 412W, the common electrode 413, the protective layer 421, and the like formed over the insulating layer 423 can be increased.

The organic layer 412W and the common electrode 413 are each provided as one continuous film shared by the light-emitting elements. Such a structure is preferable because the manufacturing process of the display device can be greatly simplified.

Here, the end portion of the pixel electrode 411 preferably has a substantially vertical shape. Accordingly, a steep portion can be formed on the surface of the insulating layer 423, and thus a thin portion can be formed in part of the organic layer 412W covering the steep portion or part of the organic layer 412W can be divided. Accordingly, leakage current generated between adjacent light-emitting elements through the organic layer 412W can be inhibited without processing the organic layer 412W by a photolithography method and an etching method, for example.

### Display Device 70

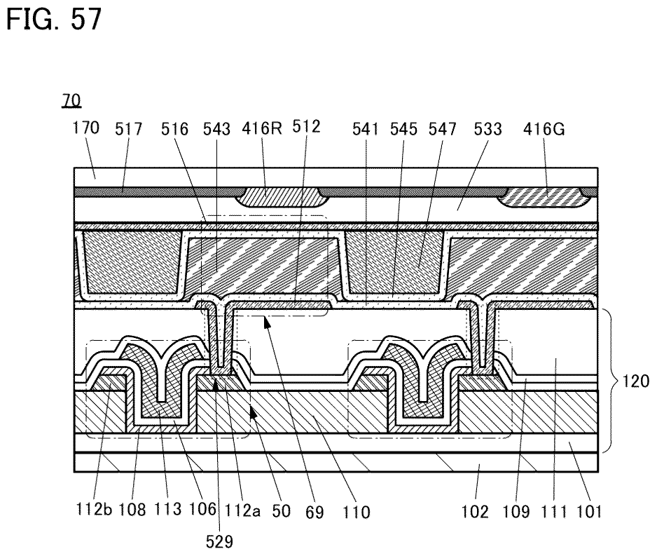

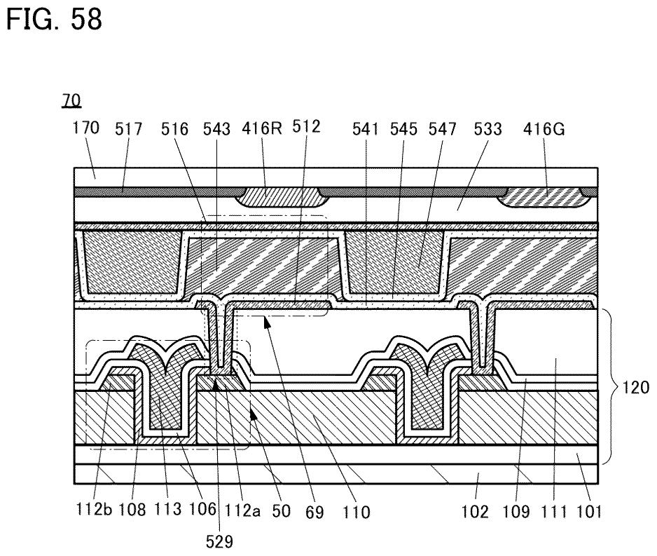

FIG. 57 and FIG. 58 are cross-sectional views illustrating a structure example of a display device 70. The display device 70 includes the liquid crystal element 69 illustrated in FIG. 20D of Embodiment 1 as a display element. The above-described structure of the display device 30 can be employed for the display device 70 as appropriate.

The display device 70 includes the transistor 50 in addition to the liquid crystal element 69. The insulating layer 109 is provided to cover the transistor 50, and the insulating layer 111 is provided over the insulating layer 109. The liquid crystal element 69 is provided over the insulating layer 111.

As the insulating layer 111 included in the display device 70, an insulating layer containing an organic material can be favorably used. As the organic material, a photosensitive organic resin is preferably used, and for example, a photosensitive resin composite including an acrylic resin is preferably used. In this specification and the like, an acrylic resin refers to not only a polymethacrylic acid ester or a methacrylic resin but also all the acrylic polymer in a broad sense in some cases.

The insulating layer 111 may be formed using an acrylic resin, a polyimide resin, an epoxy resin, an imide resin, a poly amide resin, a polyimide-amide resin, a silicone resin, a siloxane resin, a benzocyclobutene-based resin, a phenol resin, precursors of these resins, or the like. Alternatively, the insulating layer 111 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used for the photosensitive resin. As the photosensitive organic resin, either a positive-type material or a negative-type material may be used.

The insulating layer 111 may have a stacked-layer structure of an organic insulating layer and an inorganic insulating layer. For example, the insulating layer 111 can have a stacked-layer structure of an organic insulating layer and an inorganic insulating layer over the organic insulating layer. In the case where an inorganic insulating layer is provided as the outermost surface of the insulating layer 111, the inorganic insulating layer can function as an etching protective layer. This can inhibit poor flatness of the insulating layer 111 due to etching of part of the insulating layer 111 at the time of forming the pixel electrode 512.

Note that a material similar to the material that can be used for the insulating layer 111 included in the display device 70 may be used for the insulating layer 111 included in the display device 30. A material similar to the material that can be used for the insulating layer 111 included in the display device 30 may be used for the insulating layer 111 included in the display device 70.

As described above, the transistor 50 can have a structure similar to that of the transistor 100 or the transistor 200 described in this specification and the like. FIG. 57 illustrates an example where the transistor 50 has a structure similar to that of the transistor 100 illustrated in FIG. 3A, for example. FIG. 58 illustrates an example where the transistor 50 has a structure similar to that of the transistor 100 illustrated in FIG. 8A, for example. Note that the display device 70 may include the capacitor 57.

The liquid crystal element 69 includes a pixel electrode 512 and a common electrode 516, and a liquid crystal 543 is provided between the pixel electrode 512 and the common electrode 516. An opening portion 529 reaching the conductive layer 112a is provided in the semiconductor layer 108, the insulating layer 106, the insulating layer 109, and the insulating layer 111. The pixel electrode 512 is electrically connected to the conductive layer 112a of the transistor 50 in the opening portion 529.

In the example illustrated in FIG. 57 and FIG. 58, a vertical electric field mode is employed for the liquid crystal element 69, and the liquid crystal 543 is provided between the pixel electrode 512 and the common electrode 516. The pixel electrode 512 is provided separately for each liquid crystal element 69, and the common electrode 516 is shared by a plurality of liquid crystal elements 69. Note that in the case where a vertical electric field mode is employed for the liquid crystal element 69, the common electrode can also be referred to as a counter electrode.

On the surface of the substrate 170 on the substrate 102 side, a light-blocking layer 517, the coloring layer 416, an insulating layer 533, the common electrode 516, and an insulating layer 547 are provided in this order. That is, in FIG. 57 and FIG. 58, the pixel electrode 512 and layers therebelow are provided on the substrate 102 side, and the insulating layer 547 and layers thereabove are provided on the substrate 170 side. Here, FIG. 57 and FIG. 58 illustrate the coloring layer 416R and the coloring layer 416G as the coloring layers 416.

In manufacture of the display device 70, first, the pixel electrode 512 and the layers therebelow are formed over the substrate 102, and the insulating layer 547 and the layers thereabove are formed over the substrate 170. Then, the substrate 102 and the substrate 170, specifically, the insulating layer 111 and the insulating layer 533 are attached to each other with an adhesive layer (not illustrated). The liquid crystal 543 is placed between the pixel electrode 512 and the common electrode 516 by a liquid crystal injection method, a liquid crystal dropping method, or the like, for example. Through the above steps, the display device 70 can be manufactured.

In the case where the display device 70 is a transmissive liquid crystal display device, a backlight emitting white light is provided on the outer side of the substrate 102 (the side opposite to the substrate 170), for example. Then, light emitted from the backlight and transmitted through the liquid crystal element 69 is extracted through the substrate 170, whereby an image can be displayed on the display portion of the display device 70. Therefore, in the display device 70, a material having a high light-transmitting property is preferably used for the substrate 102 and the substrate 170. For the pixel electrode 512 and the common electrode 516, a conductive material having a high light-transmitting property, e.g., a conductive material having a high visible-light-transmitting property, is preferably used. Examples of the conductive material having a high light-transmitting property include indium oxide, an indium tin oxide, an indium zinc oxide, and zinc oxide. A conductive oxide such as zinc oxide to which gallium is added can be used as the conductive material having a high light-transmitting property. Furthermore, graphene may be used as the conductive material having a high light-transmitting property. Graphene can be formed by reducing graphene oxide. For example, graphene can be formed by application of heat to graphene oxide.

Alternatively, a metal or an alloy that is thin enough to have a light-transmitting property can be used for the pixel electrode 512 and the common electrode 516. For example, a metal such as gold, silver, platinum, magnesium, nickel, tungsten, chromium, molybdenum, iron, cobalt, copper, palladium, or titanium, or an alloy containing the metal can be used. Alternatively, a nitride of the metal, a nitride of the alloy, or the like may be used; for example, titanium nitride may be used. Alternatively, two or more conductive layers each containing the above material may be stacked.

Note that in the case where the display device 70 is a reflective liquid crystal display device, for example, a conductive material having a high reflecting property, e.g., a conductive material having a high visible-light-reflecting property, is preferably used for the pixel electrode 512. Examples of the material having a high reflecting property include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material having a high reflecting property include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC).

Note that a variety of optical members such as polarizing plates can be provided on the outer side of the substrate 102 (the side opposite to the substrate 170) and the outer side of the substrate 170 (the side opposite to the substrate 102). In this case, a backlight can be provided on the outer side of any of a variety of optical members, for example.

The insulating layer 547 functions as a spacer, and a structure can be employed where the liquid crystal 543 does not overlap with the insulating layer 547, for example. The insulating layer 547 has a function of controlling the distance between the substrate 102 and the substrate 170 to control the thickness of the liquid crystal 543. The insulating layer 547 is preferably provided to overlap with the transistor 50, in which case a reduction in the aperture ratio due to the insulating layer 547 can be inhibited.

Although FIG. 57 and FIG. 58 illustrate an example where the insulating layer 547 does not overlap with the pixel electrode 512, the insulating layer 547 may overlap with part of the pixel electrode 512. For example, the insulating layer 547 and the pixel electrode 512 may overlap with each other in the opening portion 529. In the case where the insulating layer 547 overlaps with part of the pixel electrode 512, the insulating layer 547 is provided between the pixel electrode 512 and the common electrode 516.

An alignment layer 541 can be provided on the substrate 102 side to cover the pixel electrode 512, and an alignment layer 545 can be provided on the substrate 170 side to cover the common electrode 516 and the insulating layer 547. In the case where the alignment layer 541 and the alignment layer 545 are provided in the display device 70, the liquid crystal 543 is provided between the alignment layer 541 and the alignment layer 545. The liquid crystal 543 includes a region in contact with the alignment layer 541 and a region in contact with the alignment layer 545. The alignment layer 545 can include a region in contact with the alignment layer 541 in a region overlapping with the insulating layer 547.

The alignment layer 541 and the alignment layer 545 each have a function of controlling alignment of the liquid crystal 543. Note that the alignment layer 541 and the alignment layer 545 are not necessarily provided.

In the case where the alignment layer 541 and the alignment layer 545 are provided in the display device 70, first, the pixel electrode 512 and the layers therebelow are formed over the substrate 102, and then the alignment layer 541 is formed to cover the pixel electrode 512. After the insulating layer 547 and the layers thereabove are formed over the substrate 170, the alignment layer 545 is formed to cover the common electrode 516 and the insulating layer 547. Then, the substrate 102 and the substrate 170, specifically, the insulating layer 111 and the insulating layer 533 are attached to each other with an adhesive layer (not illustrated). The liquid crystal 543 is placed between the alignment layer 541 and the alignment layer 545. Through the above steps, the display device 70 including the alignment layer 541 and the alignment layer 545 can be manufactured.

As described above, the coloring layer 416R transmits red light, the coloring layer 416G transmits green light, and the coloring layer 416B transmits blue light, for example. Thus, even when light emitted from the backlight is white light, for example, the display portion included in the display device 70 can emit red light, green light, and blue light to perform full-color display, for example.

Alternatively, a structure may be employed where the backlight emits blue or violet light, and a color conversion material converting the blue or violet light to light of another color (e.g., red or green) is used for the coloring layer 416. As the color conversion material, a fluorescent material, a phosphorescent material, a resin material where quantum dots are dispersed, or the like can be used. In this case, the coloring layer 416 preferably has a stacked-layer structure of the color conversion material and a color filter from the backlight side.

The light-blocking layer 517 is provided between adjacent coloring layers 416. A portion where the light-blocking layer 517 is provided serves as a non-display region. The light-blocking layer 517 is provided to include a region overlapping with the insulating layer 547. The light-blocking layer 517 can be provided to include a region overlapping with the opening portion 529. For example, when the light-blocking layer 517 is provided such that the end portion of the coloring layer 416 overlaps with the light-blocking layer 517, the coloring layer 416 and the light-blocking layer 517 can be provided without any space therebetween.

Providing the light-blocking layer 517 can inhibit light transmitted through the liquid crystal element 69 overlapping with the coloring layer 416R from being transmitted through the adjacent coloring layer 416G or the adjacent coloring layer 416B, for example. In addition, providing the light-blocking layer 517 can inhibit reflection of external light, for example. Accordingly, the contrast of an image displayed on the display portion of the display device 70 can be increased. Note that a structure without the light-blocking layer 517 may be employed. Thus, light emitted from the backlight can be efficiently extracted to the outside of the display device 70, specifically, the outside of the substrate 170, for example.

The insulating layer 533 functions as an overcoat inhibiting diffusion of components contained in the coloring layer 416 into the liquid crystal element 69, for example. Here, the insulating layer 533 is preferably planarized, in which case the common electrode 516 is easily formed over the insulating layer 533. Note that the insulating layer 533 is not necessarily planarized. For the insulating layer 533, a material similar to the material that can be used for the insulating layer 111 can be used, for example.

Although FIG. 57 and FIG. 58 illustrate an example of a display device including a liquid crystal element with a vertical electric field mode, one embodiment of the present invention is not limited thereto and may be a display device including a liquid crystal element with a horizontal electric field mode, for example. In the case of employing a horizontal electric field mode, a liquid crystal exhibiting a blue phase for which an alignment film is not used may be used. A blue phase is one of liquid crystal phases, which appears just before a cholesteric phase changes into an isotropic phase while the temperature of a cholesteric liquid crystal is increased. Since the blue phase appears only in a narrow temperature range, a liquid crystal composition in which a chiral material is mixed at 5 weight % or more is used for the liquid crystal 543 in order to improve the temperature range. A liquid crystal composition that contains a liquid crystal exhibiting a blue phase and a chiral material has a short response time and exhibits optical isotropy. In addition, the liquid crystal composition that contains a liquid crystal exhibiting a blue phase and a chiral material does not need alignment treatment and has small viewing angle dependence. Since an alignment film is not necessarily provided, rubbing treatment is unnecessary. Accordingly, electrostatic breakdown caused by the rubbing treatment can be inhibited, and defects or damage of the display device in the manufacturing process can be reduced.

At least part of the structure examples, the drawings corresponding thereto, and the like described in this embodiment can be combined with the other structure examples, the other drawings, and the like as appropriate.

### Embodiment 3

In this embodiment, electronic devices of embodiments of the present invention will be described.

Electronic devices in this embodiment each include a display panel (display device) employing the semiconductor device of one embodiment of the present invention in a display portion. The display device of one embodiment of the present invention can have higher resolution and higher definition easily and can achieve high reliability and high display quality. Thus, the display device of one embodiment of the present invention can be used for display portions of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and notebook personal computers, a monitor of a computer and the like, digital signage, and a large game machine such as a pachinko machine.

In particular, the display panel of one embodiment of the present invention can have high resolution, and thus can be suitably used for an electronic device having a relatively small display portion. Examples of such an electronic device include a watch-type or a bracelet-type information terminal device (wearable device), and a wearable device worn on a head, such as a device for VR such as a head mounted display, a glasses-type device for AR, and a device for MR.

The definition of the display panel of one embodiment of the present invention is preferably as high as HD (number of pixels: 1280×720), FHD (number of pixels: 1920×1080), WQHD (number of pixels: 256×1440), WQXGA (number of pixels: 2560×1600), 4K (number of pixels: 3840×2160), or 8K (number of pixels: 7680×4320). In particular, definition of 4K, 8K, or higher is preferable. The pixel density (resolution) of the display panel of one embodiment of the present invention is preferably higher than or equal to 100 ppi, further preferably higher than or equal to 300 ppi, still further preferably higher than or equal to 500 ppi, yet further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. The use of such a display panel having one or both of high definition and high resolution can further increase realistic sensation, sense of depth, and the like. There is no particular limitation on the screen ratio (aspect ratio) of the display panel of one embodiment of the present invention. For example, the display panel is compatible with a variety of screen ratios such as 1:1 (square), 4:3, 16:9, and 16:10.

The electronic device of this embodiment may include a sensor (a sensor having a function of sensing, detecting, or measuring force, displacement, a position, speed, acceleration, angular velocity, rotational frequency, distance, light, liquid, magnetism, temperature, a chemical substance, sound, time, hardness, an electric field, current, voltage, power, radiation, a flow rate, humidity, a gradient, oscillation, odor, or infrared rays).

The electronic device in this embodiment can have a variety of functions. For example, the electronic device can have a function of displaying a variety of information (e.g., a still image, a moving image, and a text image) on the display portion, a touch panel function, a function of displaying a calendar, date, time, or the like, a function of executing a variety of software (programs), a wireless communication function, or a function of reading out a program or data stored in a recording medium.

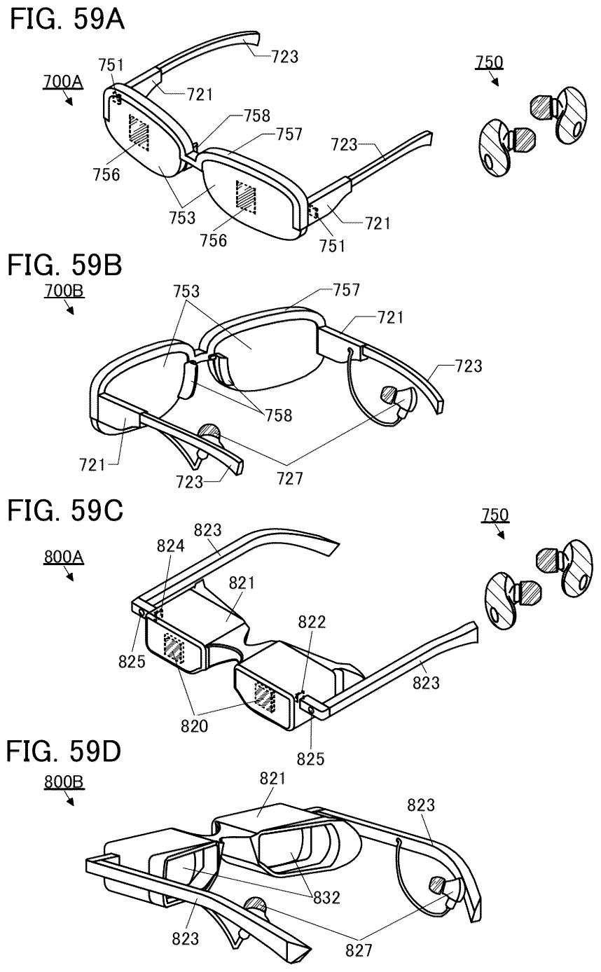

Examples of a wearable device that can be worn on a head are described with reference to FIG. 59A to FIG. 59D. These wearable devices have one or both of a function of displaying AR content and a function of displaying VR content. Note that these wearable devices may have a function of displaying SR or MR content, in addition to AR and VR content. The electronic device having a function of displaying content of at least one of AR, VR, SR, MR, and the like enables the user to feel a higher sense of immersion.

An electronic device 700A illustrated in FIG. 59A and an electronic device 700B illustrated in FIG. 59B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display panel of one embodiment of the present invention can be used for the display panels 751. Thus, the electronic device 700A and the electronic device 700B can be highly reliable electronic devices that can display images with extremely high resolution. The electronic device 700A and the electronic device 700B can display images with extremely high-resolution and thus enables the user to feel a high sense of immersion.

The electronic device 700A and the electronic device 700B can each project an image displayed on the display panel 751 onto display regions 756 of the optical members 753. Since the optical members 753 have a light-transmitting property, the user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be sensed and an image corresponding to the orientation can be displayed on the display region 756.

The communication portion includes a wireless communication device, and a video signal, for example, can be supplied by the wireless communication device. Instead of the wireless communication device or in addition to the wireless communication device, a connector that can be connected to a cable for supplying a video signal and a power supply potential may be provided.

The electronic device 700A and the electronic device 700B are provided with a battery so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion device (also referred to as a photoelectric conversion element) can be used as a light-receiving device (also referred to as a light-receiving element). One or both of an inorganic semiconductor and an organic semiconductor can be used for an active layer of the photoelectric conversion device.

An electronic device 800A illustrated in FIG. 59C and an electronic device 800B illustrated in FIG. 59D each include a pair of display portions 820, a housing 821, a communication portion 822, a pair of wearing portions 823, a control portion 824, a pair of image capturing portions 825, and a pair of lenses 832.

The display panel of one embodiment of the present invention can be used for the display portions 820. Thus, the electronic device 800A and the electronic device 800B can be highly reliable electronic devices that can display images with extremely high resolution. The electronic device 800A and the electronic device 800B can display images with extremely high-resolution and thus enables the user to feel a high sense of immersion.

The display portions 820 are positioned inside the housing 821 so as to be seen through the lenses 832. When the pair of display portions 820 display different images, three-dimensional display using parallax can be performed.

The electronic device 800A and the electronic device 800B can be regarded as electronic devices for VR. The user wearing the electronic device 800A or the electronic device 800B can see images displayed on the display portions 820 through the lenses 832.

The electronic device 800A and the electronic device 800B preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B preferably include a mechanism for adjusting focus by changing the distance between the lenses 832 and the display portions 820.

The electronic device 800A or the electronic device 800B can be mounted on the user's head with the wearing portions 823. FIG. 59C, for instance, illustrates an example where the wearing portion 823 has a shape like a temple (also referred to as a joint or the like) of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided to cover a plurality of fields of view, such as a telescope field of view and a wide field of view.

Although an example where the image capturing portions 825 are provided is illustrated here, a range sensor (hereinafter also referred to as a sensing portion) capable of measuring a distance from an object just needs to be provided. In other words, the image capturing portion 825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic device 800A may include a vibration mechanism functioning as bone-conduction earphones. For example, at least one of the display portion 820, the housing 821, and the wearing portion 823 can include the vibration mechanism. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, for example, a cable supplying a video signal from a video output device, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 59A has a function of transmitting information to the earphones 750 with the wireless communication function. As another example, the electronic device 800A illustrated in FIG. 59C has a function of transmitting information to the earphones 750 with the wireless communication function.

The electronic device may include an earphone portion. The electronic device 700B illustrated in FIG. 59B includes earphone portions 727. For example, a structure where the earphone portions 727 and the control portion are connected to each other by wire can be employed. Part of a wiring that connects the earphone portions 727 and the control portion may be placed inside the housing 721 or the wearing portion 723.

Similarly, the electronic device 800B illustrated in FIG. 59D includes earphone portions 827. For example, a structure where the earphone portions 827 and the control portion 824 are connected to each other by wire can be employed. Part of a wiring that connects the earphone portions 827 and the control portion 824 may be placed inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

Note that the electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

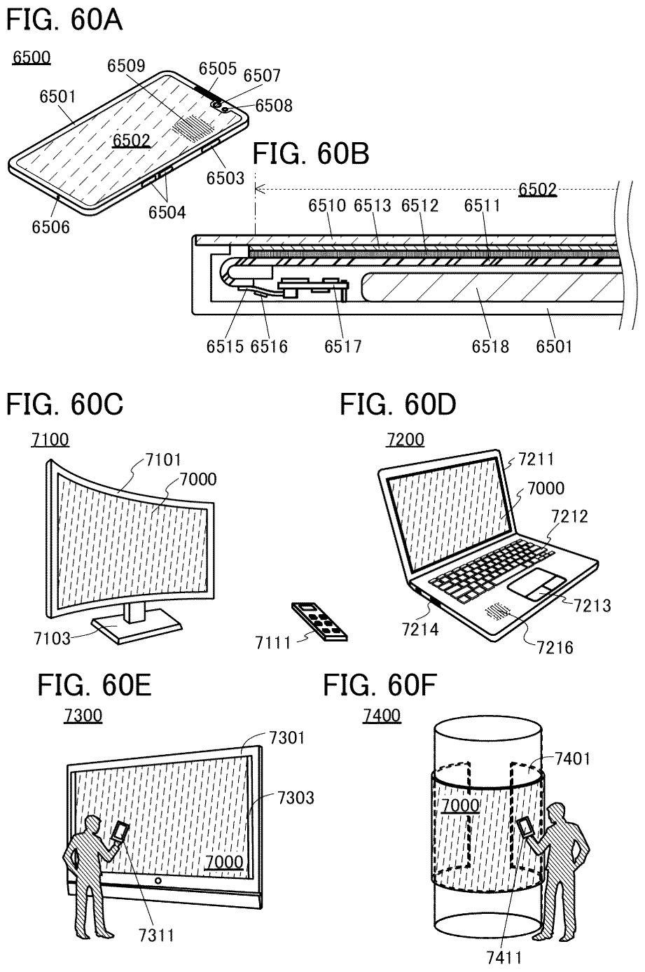

An electronic device 6500 illustrated in FIG. 60A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, a control device 6509, and the like. The display portion 6502 has a touch panel function. Note that as the control device 6509, for example, one or more selected from a CPU, a GPU, and a memory device are included. The semiconductor device of one embodiment of the present invention can be employed for the display portion 6502, the control device 6509, or the like. The semiconductor device of one embodiment of the present invention is preferably used for the control device 6509, in which case power consumption can be reduced.

The display panel of one embodiment of the present invention can be used for the display portion 6502. Thus, the electronic device 6500 can be a highly reliable electronic device that can display images with extremely high resolution.

FIG. 60B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used in the display panel 6511. Thus, an extremely lightweight electronic device can be obtained. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby an electronic device with a narrow bezel can be achieved.

FIG. 60C illustrates an example of a television device. In a television device 7100, a display portion 7000 is incorporated in a housing 7101. Here, the housing 7101 is supported by a stand 7103.

Operation of the television device 7100 illustrated in FIG. 60C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may include a display portion for displaying information output from the remote control 7111. With operation keys or a touch panel provided in the remote control 7111, channels and volume can be controlled and videos displayed on the display portion 7000 can be controlled.

Note that the television device 7100 includes a receiver, a modem, and the like. A general television broadcast can be received with the receiver. When the television device is connected to a communication network with or without wires via the modem, one-way (from a transmitter to a receiver) or two-way (between a transmitter and a receiver or between receivers, for example) data communication can be performed.

FIG. 60D illustrates an example of a laptop personal computer. A laptop personal computer 7200 includes a housing 7211, a keyboard 7212, a pointing device 7213, an external connection port 7214, a control device 7216, and the like. The display portion 7000 is incorporated in the housing 7211. As the control device 7216, for example, one or more selected from a CPU, a GPU, and a memory device are included. The semiconductor device of one embodiment of the present invention can be used for the display portion 7000, the control device 7216, and the like. The semiconductor device of one embodiment of the present invention is preferably used for the control device 7216, in which case power consumption can be reduced.

FIG. 60E and FIG. 60F illustrate examples of digital signage.

Digital signage 7300 illustrated in FIG. 60E includes a housing 7301, the display portion 7000, a speaker 7303, and the like. The digital signage 7300 can also include an LED lamp, operation keys (including a power switch or an operation switch), a connection terminal, a variety of sensors, a microphone, and the like.

FIG. 60F is digital signage 7400 attached to a cylindrical pillar 7401. The digital signage 7400 includes the display portion 7000 provided along a curved surface of the pillar 7401.

A larger area of the display portion 7000 can increase the amount of information that can be provided at a time. The display portion 7000 having a larger area attracts more attention, so that the effectiveness of the advertisement can be increased, for example.

The touch panel is preferably used in the display portion 7000, in which case in addition to display of still or moving images on the display portion 7000, intuitive operation by a user is possible. Moreover, in the case of an application for providing information such as route information or traffic information, usability can be enhanced by intuitive operation.

As illustrated in FIG. 60E and FIG. 60F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, a displayed image on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

The display panel of one embodiment of the present invention can be used for the display portions 7000 of the electronic devices illustrated in FIG. 60C to FIG. 60F. Thus, a highly reliable electronic device that can display an image with extremely high resolution can be obtained.

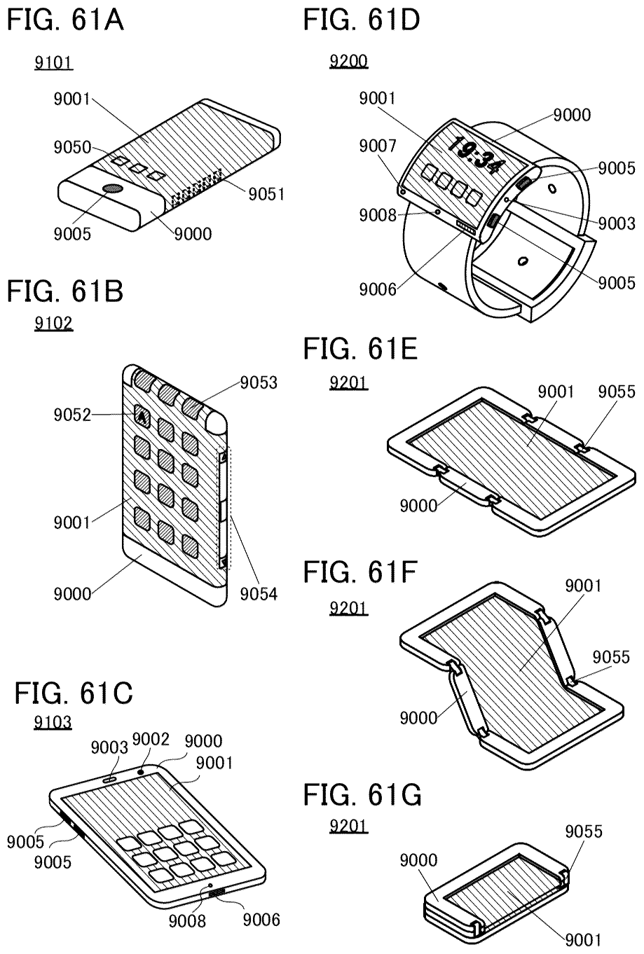

Electronic devices illustrated in FIG. 61A to FIG. 61G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The electronic devices illustrated in FIG. 61A to FIG. 61G have a variety of functions. For example, the electronic devices can have a function of displaying a variety of information (e.g., a still image, a moving image, and a text image) on the display portion, a touch panel function, a function of displaying a calendar, date, time, or the like, a function of controlling processing with the use of a variety of software (programs), a wireless communication function, or a function of reading out and processing a program or data stored in a recording medium. Note that the functions of the electronic devices are not limited thereto, and the electronic devices can have a variety of functions. The electronic devices may include a plurality of display portions. The electronic devices may be provided with, for example, a camera and have a function of capturing a still image or a moving image, a function of storing the captured image in a storage medium (an external storage medium or a storage medium incorporated in the camera), a function of displaying the captured image on the display portion, and the like.

The electronic devices illustrated in FIG. 61A to FIG. 61G are described in detail below.

FIG. 61A is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. The portable information terminal 9101 can display characters and image information on its plurality of surfaces. FIG. 61A illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 61B is a perspective view illustrating a portable information terminal 9102. The portable information terminal 9102 has a function of displaying information on three or more surfaces of the display portion 9001. In the example illustrated here, information 9052, information 9053, and information 9054 are displayed on different surfaces. For example, a user can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 61C is a perspective view illustrating a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 61D is a perspective view illustrating a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIG. 61E to FIG. 61G are perspective views illustrating a foldable portable information terminal 9201. FIG. 61E is a perspective view of an opened state of the portable information terminal 9201, FIG. 61G is a perspective view of a folded state thereof, and FIG. 61F is a perspective view of a state in the middle of change from one of FIG. 61E and FIG. 61G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature of greater than or equal to 0.1 mm and less than or equal to 150 mm, for example.

The display panel of one embodiment of the present invention can be used for the display portions 9001 of the electronic devices illustrated in FIG. 61A to FIG. 61G. Thus, a highly reliable electronic device that can display an image with extremely high resolution can be obtained.

At least part of the structure examples, the drawings corresponding thereto, and the like described in this embodiment can be combined with the other structure examples, the other drawings, and the like as appropriate.

### REFERENCE NUMERALS

20: semiconductor device, 20A: semiconductor device, 20B: semiconductor device, 20C: semiconductor device, 20D: semiconductor device, 20E: semiconductor device, 21: pixel, 23: subpixel, 23B: subpixel, 23G: subpixel, 23R: subpixel, 25: display portion, 30: display device, 30A: display device, 30B: display device, 30C: display device, 31: scan line driver circuit, 33: signal line driver circuit, 35: power supply circuit, 37: reference potential generation circuit, 40: pixel circuit, 40A: pixel circuit, 40B: pixel circuit, 40C: pixel circuit, 41: wiring, 41a: wiring, 41b: wiring, 43: wiring, 45: wiring, 47: wiring, 48: wiring, 50: transistor, 51: transistor, 57: capacitor, 60: light-emitting element, 60B: light-emitting element, 60G: light-emitting element, 60R: light-emitting element, 60W: light-emitting element, 69: liquid crystal element, 70: display device, 100: transistor, 101: insulating layer, 102: substrate, 103: conductive layer, 105: insulating layer, 106: insulating layer, 106a: insulating layer, 106b: insulating layer, 108: semiconductor layer, 108f: semiconductor film, 108i: region, 108na: region, 108nb: region, 109: insulating layer, 110: insulating layer, 110a: insulating layer, 110b: insulating layer, 110c: insulating layer, 111: insulating layer, 112: conductive layer, 112a: conductive layer, 112b: conductive layer, 112c: conductive layer, 112f: conductive film, 113: conductive layer, 115: plug, 115a: plug, 115b: plug, 115c: plug, 117: conductive layer, 117a: conductive layer, 117b: conductive layer, 117c: conductive layer, 120: layer, 122a: terminal portion, 122b: terminal portion, 123: resist mask, 125: flat portion, 126: upper surface, 127: portion, 141[1]: opening portion, 141[2]: opening portion, 141: opening portion, 143: opening portion, 145: opening portion, 145a: opening portion, 145b: opening portion, 145c: opening portion, 150: transistor, 151: semiconductor layer, 152: insulating layer, 153: insulating layer, 154: conductive layer, 155: conductive layer, 156: insulating layer, 157: conductive layer, 158: insulating layer, 159: insulating layer, 161: insulating layer, 170: substrate, 200: transistor, 208: semiconductor layer, 208i: region, 208na: region, 208nb: region, 212a: conductive layer, 212b: conductive layer, 213: conductive layer, 225: flat portion, 226: upper surface, 227: portion, 241: opening portion, 243: opening portion, 308: semiconductor layer, 310: transistor, 311: conductive layer, 312: conductive layer, 313: conductive layer, 314: insulating layer, 315: element isolation layer, 316: low-resistance region, 317: insulating layer, 340: capacitor, 341: conductive layer, 343: insulating layer, 345: conductive layer, 354: insulating layer, 355a: insulating layer, 355b: insulating layer, 355c: insulating layer, 356: plug, 380: display module, 382: circuit portion, 383: pixel circuit portion, 384: pixel portion, 385: terminal portion, 386: wiring portion, 390: FPC, 401: layer, 411: pixel electrode, 411B: pixel electrode, 411C: connection electrode, 411G: pixel electrode, 411R: pixel electrode, 412: organic layer, 412B: organic layer, 412G: organic layer, 412R: organic layer, 412W: organic layer, 413: common electrode, 414: common layer, 415B: conductive layer, 415G: conductive layer, 415R: conductive layer, 416: coloring layer, 416B: coloring layer, 416G: coloring layer, 416R: coloring layer, 421: protective layer, 422: insulating layer, 423: insulating layer, 425: insulating layer, 426: resin layer, 428: layer, 440: connection portion, 471: adhesive layer, 512: pixel electrode, 516: common electrode, 517: light-blocking layer, 529: opening portion, 533: insulating layer, 541: alignment layer, 543: liquid crystal, 545: alignment layer, 547: insulating layer, 700A: electronic device, 700B: electronic device, 721: housing, 723: wearing portion, 727: earphone portion, 750: earphone, 751: display panel, 753: optical member, 756: display region, 757: frame, 758: nose pad, 800A: electronic device, 800B: electronic device, 820: display portion, 821: housing, 822: communication portion, 823: wearing portion, 824: control portion, 825: image capturing portion, 827: earphone portion, 832: lens, 6500: electronic device, 6501: housing, 6502: display portion, 6503: power button, 6504: button, 6505: speaker, 6506: microphone, 6507: camera, 6508: light source, 6509: control device, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote control, 7200: laptop personal computer, 7211: housing, 7212: keyboard, 7213: pointing device, 7214: external connection port, 7216: control device, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A semiconductor device comprising:
a first insulating layer; and
a second insulating layer and a transistor over the first insulating layer,
wherein the transistor comprises a first conductive layer, a second conductive layer, a third conductive layer, a semiconductor layer, and a third insulating layer,
wherein the second insulating layer comprises a first opening portion reaching the first insulating layer,
wherein the first conductive layer and the second conductive layer are provided over the second insulating layer,
wherein in a cross-sectional view, a first side surface of the first conductive layer and a first side surface of the second conductive layer face each other with the first opening portion therebetween,
wherein the semiconductor layer comprises a region positioned in the first opening portion and being in contact with a first side surface of the second insulating layer, a part of an upper surface of the first insulating layer, and a second side surface of the second insulating layer facing the first side surface of the second insulating layer,
wherein the region of the semiconductor layer is configured to be a channel formation region of the transistor,
wherein in the cross-sectional view, a first side surface of the semiconductor layer outside the first opening portion is aligned or substantially aligned with a second side surface of the first conductive layer, and a second side surface of the semiconductor layer outside the first opening portion is aligned or substantially aligned with a second side surface of the second conductive layer,
wherein the third insulating layer is provided over the semiconductor layer to comprise a region positioned in the first opening portion, and
wherein the third conductive layer is provided over the third insulating layer to comprise a region positioned in the first opening portion.

2. The semiconductor device according to claim 1,
wherein the semiconductor layer and the third insulating layer comprise a second opening portion reaching the second conductive layer, and
wherein a plug is provided to be embedded in the second opening portion.

3. The semiconductor device according to claim 1,
wherein in the cross-sectional view, the first side surface of the second insulating layer is aligned or substantially aligned with the first side surface of the first conductive layer, and the second side surface of the second insulating layer is aligned or substantially aligned with the first side surface of the second conductive layer.

4. The semiconductor device according to claim 1,
wherein the semiconductor layer comprises a metal oxide comprising indium.

5. The semiconductor device according to claim 4,
wherein the metal oxide further comprises an element M, and zinc, and
wherein the element Mis one or more kinds selected from aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony.

6. A semiconductor device comprising:
a first insulating layer; and
a second insulating layer, a first transistor, and a second transistor over the first insulating layer,
wherein the first transistor comprises a first conductive layer, a second conductive layer, a third conductive layer, a first semiconductor layer, and a third insulating layer,
wherein the second transistor comprises a fourth conductive layer, a fifth conductive layer, a sixth conductive layer, a second semiconductor layer, and the third insulating layer,
wherein the fourth conductive layer is provided over the first insulating layer,
wherein the second insulating layer is provided over the fourth conductive layer,
wherein the second insulating layer comprises a first opening portion reaching the first insulating layer and a second opening portion reaching the fourth conductive layer,
wherein the first conductive layer and the second conductive layer are provided over the second insulating layer,
wherein in a cross-sectional view, a first side surface of the first conductive layer and a first side surface of the second conductive layer face each other with the first opening portion therebetween,
wherein the fifth conductive layer is provided over the second insulating layer and comprises a third opening portion comprising a region overlapping with the second opening portion,
wherein the first semiconductor layer comprises a region positioned in the first opening portion and being in contact with a first side surface of the second insulating layer, a part of an upper surface of the first insulating layer, and a second side surface of the second insulating layer facing the first side surface of the second insulating layer,
wherein the region of the first semiconductor layer is configured to be a channel formation region of the first transistor,
wherein in the cross-sectional view, a first side surface of the first semiconductor layer outside the first opening portion is aligned or substantially aligned with a second side surface of the first conductive layer, and a second side surface of the first semiconductor layer outside the first opening portion is aligned or substantially aligned with a second side surface of the second conductive layer,
wherein the second semiconductor layer a region positioned in the second opening portion, a region positioned in the third opening portion, and a region in contact with a part of an upper surface of the fourth conductive layer,
wherein in the cross-sectional view, a first side surface of the second semiconductor layer outside the third opening portion is aligned or substantially aligned with a first side surface of the fifth conductive layer,
wherein the third insulating layer is provided over the first semiconductor layer and the second semiconductor layer to comprise a region positioned in the first opening portion, a region positioned in the second opening portion, and a region positioned in the third opening portion,
wherein the third conductive layer is provided over the third insulating layer to comprise a region positioned in the first opening portion, and
wherein the sixth conductive layer is provided over the third insulating layer to comprise a region positioned in the second opening portion and a region positioned in the third opening portion.

7. The semiconductor device according to claim 6,
wherein the first semiconductor layer and the third insulating layer comprise a fourth opening portion reaching the second conductive layer, and
wherein a plug is provided to be embedded in the fourth opening portion.

8. The semiconductor device according to claim 6,
wherein in a channel length direction of the first transistor, a length of a portion of the first semiconductor layer being in contact with the part of the upper surface of the first insulating layer is greater than or equal to a thickness of the second insulating layer.

9. The semiconductor device according to claim 6,
wherein in the cross-sectional view, the first side surface of the second insulating layer is aligned or substantially aligned with the first side surface of the first conductive layer, the second side surface of the second insulating layer is aligned or substantially aligned with the first side surface of the second conductive layer.

10. The semiconductor device according to claim 6,
wherein the first semiconductor layer and the second semiconductor layer each comprise a metal oxide comprising indium.

11. The semiconductor device according to claim 10,
wherein the metal oxide further comprises an element M and zinc, and
wherein the element Mis one or more kinds selected from aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony.

12. A method for manufacturing a semiconductor device, comprising:
forming a first insulating layer;
forming a first conductive layer over the first insulating layer;
forming a second insulating layer over the first insulating layer and the first conductive layer;
forming a conductive film over the second insulating layer;
forming, in the conductive film, a first opening portion and a second opening portion comprising a region overlapping with the first conductive layer;
forming, in the second insulating layer, a third opening portion that comprises a region overlapping with the first opening portion and reaches the first insulating layer and a fourth opening portion that comprises a region overlapping with the second opening portion and reaches the first conductive layer;
forming a semiconductor film covering the first opening portion, the second opening portion, the third opening portion, and the fourth opening portion;
processing the semiconductor film, thereby forming a first semiconductor layer comprising a region in contact with the conductive film and a region positioned in the third opening portion and a second semiconductor layer comprising a region in contact with the first conductive layer, a region in contact with the conductive film, a region positioned in the second opening portion, and a region positioned in the fourth opening portion;
processing the conductive film after the processing of the semiconductor film, thereby forming a second conductive layer and a third conductive layer facing each other with the third opening portion therebetween in a plan view and a fourth conductive layer comprising the second opening portion;
forming a third insulating layer over the first semiconductor layer, the second semiconductor layer, and the second insulating layer to comprise regions positioned in the second opening portion, the third opening portion, and the fourth opening portion; and
forming, over the third insulating layer, a fifth conductive layer comprising a region positioned in the third opening portion and a sixth conductive layer comprising a region positioned in the second opening portion and a region positioned in the fourth opening portion.

13. The method for manufacturing a semiconductor device, according to claim 12,
wherein a resist mask is formed after the semiconductor film is formed,
wherein the semiconductor film and the conductive film are processed after the resist mask is formed, and
wherein the resist mask is removed after the conductive film is processed.

14. The method for manufacturing a semiconductor device, according to claim 12,
wherein a seventh conductive layer is formed over the first insulating layer in the same step as formation of the first conductive layer,
wherein an eighth conductive layer over the second insulating layer and a third semiconductor layer over the eighth conductive layer are formed by processing the semiconductor film and the conductive film,
wherein a ninth conductive layer is formed over the third insulating layer in the same step as formation of the fifth conductive layer and the sixth conductive layer,
wherein a fourth insulating layer is formed over the fifth conductive layer, the sixth conductive layer, the seventh conductive layer, and the ninth conductive layer after the fifth conductive layer, the sixth conductive layer, and the ninth conductive layer are formed,
wherein forming a fifth opening portion reaching the seventh conductive layer in the second insulating layer, the third insulating layer, and the fourth insulating layer, forming a sixth opening portion reaching the eighth conductive layer in the fourth insulating layer, the third insulating layer, and the third semiconductor layer, and forming a seventh opening portion in the fourth insulating layer are performed in parallel, and
wherein a first plug embedded in the fifth opening portion, a second plug embedded in the sixth opening portion, and a third plug embedded in the seventh opening portion are formed.
